(19) United States
(12) Patent Application Publication
(10) Pub. No.: US 2025/0333548 A1
(43) Pub. Date: Oct. 30, 2025

(54) COMPOSITION AND PHOTOSENSITIVE COMPOSITION

(71) Applicant: TOKYO OHKA KOGYO CO., LTD., Kanagawa (JP)

(72) Inventors: Kazuki URAKAWA, Kanagawa (JP); Dai SHIOTA, Kanagawa (JP)

(21) Appl. No.: 18/857,664

(22) PCT Filed: Feb. 10, 2023
(86) PCT No.: PCT/JP2023/004534

§ 371 Date: Jul. 14, 2025

(30) Foreign Application Priority Data
Apr. 18, 2022 (JP) 2022-068514

(51) Int. Cl. C08F 2/44; C08F 20/10; C08F 292/00; G03F 7/039

(52) U.S. Cl. CPC C08F 2/44; C08F 20/10; C08F 292/00; G03F 7/039

(57) ABSTRACT

A photopolymerizable compound (A) and inorganic particles (B), and exhibiting good curability in a case that an initiator is added; a photosensitive composition including a photopolymerizable compound (A), inorganic particles (B), and an initiator (C), and exhibiting good curability; and a cured product of the photosensitive composition are provided. A compound having a specific structure including a radically polymerizable group-containing group is used as a photopolymerizable compound (A) in a composition including the photopolymerizable compound (A) and metal oxide particles (B), or a photosensitive composition including the photopolymerizable compound (A), metal oxide particles (B), and an initiator.

### TECHNICAL FIELD

The present invention relates to a composition and a photosensitive composition including a photopolymerizable compound (A) and metal oxide particles (B), and a cured product of the photosensitive composition.

### BACKGROUND ART

Heretofore, various inorganic microparticles are blended into compositions used to form materials with various functionalities for the purpose of imparting functionality to the materials. For example, for forming optical materials, highly refractive materials are used. A composition in which metal oxide particles such as titanium dioxide particles and zirconium oxide particles are dispersed is used as highly refractive material, for example. As a composition for forming such a highly refractive material, an energy beam curable composition including a metal oxide (A) with a specific particle size, (meth)acrylate (B), and a photoinitiator (C) has been proposed (see Patent Document 1).

### CITATION LIST

### Patent Document

Patent Document 1: Japanese Unexamined Patent Application, Publication No. 2017-214465

### DISCLOSURE OF THE INVENTION

### Problems to be Solved by the Invention

As described above, a cured product with high refractive index can be formed by using a photosensitive composition described in the Patent Document 1. However, in case that a cured product is formed by using a photosensitive composition such that Patent Document 1 discloses, the photosensitive composition is often difficult to cure depending on its composition.

In light of the above problems, the present invention has been made and an object thereof is to provide a composition including a photopolymerizable compound (A) and inorganic particles (B), and exhibiting good curability in a case that an initiator is added; a photosensitive composition including a photopolymerizable compound (A), inorganic particles (B), and an initiator (C), and exhibiting good curability; and a cured product of the photosensitive composition.

### Means for Solving the Problems

The present inventors have found that the above problems can be solved by using a compound having a specific structure including a radically polymerizable group-containing group as a photopolymerizable compound (A) in a composition including the photopolymerizable compound (A) and metal oxide particles (B), or a photosensitive composition including the photopolymerizable compound (A), metal oxide particles (B), and an initiator. Thus, the present invention has been completed. Specifically, the present invention provides the followings.

A first aspect of the present invention is directed to a photosensitive composition including a photopolymerizable compound (A) and metal oxide particles (B), in which the photopolymerizable compound (A) includes a compound represented by following formula (A1);

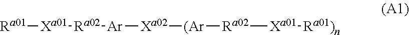

in which, in the formula (A1), R^{a01}s are each independently a radically polymerizable group-containing group,
R^{a02}s are each independently an alkylene group having 1 or more and 3 or less carbon atoms,
X^{a01}s are each independently oxygen atom or sulfur atom,
X^{a02} is an organic group having 1 or more and 3 or less carbon atoms and a valence of n+1, oxygen atom, or sulfur atom,
Ars are each independently an optionally substituted aromatic hydrocarbon group having 6 or more and 12 or less carbon atoms,
n is 1 or 2, and
when X^{a02} is oxygen atom or sulfur atom, n is 1.

A second aspect of the present invention is directed to a photosensitive composition including a photopolymerizable compound (A), metal oxide particles (B), and an initiator (C), in which the photopolymerizable compound (A) includes a compound represented by following formula (A1):

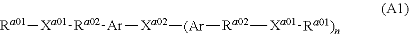

in which, in the formula (A1), R^{a01}s are each independently a radically polymerizable group-containing group, R^{a02}s are each independently an alkylene group having 1 or more and 3 or less carbon atoms,
X^{a01}s are each independently oxygen atom or sulfur atom,
X^{a02} is an organic group having 1 or more and 3 or less carbon atoms and a valence of n+1, oxygen atom, or sulfur atom,
Ars are each independently an optionally substituted aromatic hydrocarbon group having 6 or more and 12 or less carbon atoms,
n is 1 or 2, and
when X^{a02} is oxygen atom or sulfur atom, n is 1.

A third aspect of the present invention is directed to a cured product of the photosensitive composition according to the second aspect.

### Effects of the Invention

According to the present invention, it is possible to provide a composition including a photopolymerizable compound (A) and inorganic particles (B), and exhibiting good curability in a case that an initiator is added; a photosensitive composition including a photopolymerizable compound (A), inorganic particles (B), and an initiator (C), and exhibiting good curability; and a cured product of the photosensitive composition.

### PREFERRED MODE FOR CARRYING OUT THE INVENTION

### <<Composition>>

A composition includes a photopolymerizable compound (A), and metal oxide particles (B). The composition is substantially a metal oxide particles dispersion composition, and used for formation of a functional material having a property corresponding to a type of the metal oxide particles (B) after being appropriately blended with an initiator to cure the photopolymerizable compound (A). The photopolymerizable compound (A) includes a compound represented by following formula (A1).

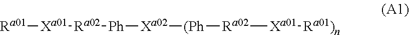

In the formula (A1), R^{a01}s are each independently a radically polymerizable group-containing group. R^{a02}s are each independently an alkylene group having 1 or more and 3 or less carbon atoms. X^{a01}s are each independently oxygen atom or sulfur atom. X^{a02} is an organic group having 1 or more and 3 or less carbon atoms and a valence of n+1, oxygen atom, or sulfur atom. Ars are each independently an optionally substituted aromatic hydrocarbon group having 6 or more and 12 or less carbon atoms. n is 1 or 2. When X^{a02} is oxygen atom or sulfur atom, n is 1. When an initiator (C) is added to the composition, the composition has good curability by inclusion of the compound represented by the above formula (A1) in the composition. The composition may include other photopolymerizable compound (A2) than the compound (A1) with the compound (A1). In view of curability when the initiator (C) is added, the photopolymerizable compound (A) preferably includes other photopolymerizable compound (A2) other than the compound (A1) with the compound (A1).

Hereinafter, essential or optional components that may be included in the composition will be described below.

### <Photopolymerizable Compound (A)>

The composition includes a photopolymerizable compound (A). The photopolymerizable compound (A) is a compound having a radically polymerizable group-containing group.

As the radically polymerizable group-containing group, typically, a group having an ethylenically unsaturated double bond is exemplified. As the ethylenically unsaturated double bond-containing group, an alkenyl group-containing group containing an alkenyl group such as a vinyl group or an allyl group is preferred, and a (meth)acryloyl group is more preferred.

In the present specification and the present claims, (meth)acrylic means both acrylic and methacrylic. (meth)acryloyl means both acryloyl and methacryloyl. (meth)acrylate means both acrylate and methacrylate.

### [Compound (A1)]

As described above, the photopolymerizable compound (A) includes a compound represented by following formula (A1).

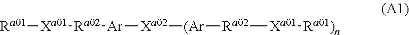

In the formula (A1), R^{a01}s are each independently a radically polymerizable group-containing group. R^{a02}s are each independently an alkylene group having 1 or more and 3 or less carbon atoms. X^{a01}s are each independently oxygen atom or sulfur atom. X^{a02} is an organic group having 1 or more and 3 or less carbon atoms and a valence of n+1, oxygen atom, or sulfur atom. Ars are each independently an optionally substituted aromatic hydrocarbon group having 6 or more and 12 or less carbon atoms. n is 1 or 2. When X^{a02} is oxygen atom or sulfur atom, n is 1. In the present specification, the compound represented by the formula (A1) is referred to as “compound (A1)”

In the formula (A1), R^{a01} is a radically polymerizable group-containing group. As described above, as the radically polymerizable group-containing group, typically, a group having an ethylenically unsaturated double bond is exemplified. As the ethylenically unsaturated double bond-containing group, an alkenyl group-containing group containing an alkenyl group such as a vinyl group or an allyl group is preferred, and a (meth)acryloyl group is more preferred. Suitable examples of the alkenyl group-containing group include an alkenyl group having 3 or more and 10 or less carbon atoms, and an alkenylcarbonyl group having 3 or more and 10 or less carbon atoms. These alkenyl groups and alkenylcarbonyl groups may be linear or branched. Suitable examples of the alkenyl group include allyl group, but-3-ene-1-yl group, pent-4-ene-1-yl group, hex-5-ene-1-yl group, hept-6-ene-1-yl group, oct-7-ene-1-yl group, non-8-ene-1-yl group, and dec-9-ene-1-yl group. Suitable examples of the alkenylcarbonyl group include acryloyl group, methacryloyl group, but-3-ene-1-ylcarbonyl group, pent-4-ene-1-ylcarbonyl group, hex-5-ene-1-ylcarbonyl group, hept-6-ene-1-ylcarbonyl group, oct-7-ene-1-ylcarbonyl group, and non-8-ene-1-ylcarbonyl group. Among these radically polymerizable group-containing group, allyl group, acryloyl group, and methacryloyl group are preferred, and acryloyl group, and methacryloyl group are particularly preferred. That is, among radically polymerizable group-containing group, (meth)acryloyl group is particularly preferred.

In the formula (A1), there are multiple R^{a01}s. Plurality of R^{a01}s may be the same of different. Plurality of R^{a01}s is preferably the same.

In the formula (A1), R^{a2}s are each independently an alkylene group having 1 or more and 3 or less carbon atoms. Specific examples of the alkylene group include methylene group, ethane-1,2-diyl group (ethylene group), ethane-1,1-diyl group, propane-1,3-diyl group, propane-1,2-diyl group, propane-1,1-diyl group, and propane-1,3-diyl group. Among these alkylene groups, methylene group, ethane-1,2-diyl group (ethylene group), propane-1,3-diyl group, and propane-1,2-diyl group are preferred, and methylene group is more preferred. In the formula (A1), there are multiple R^{a02}s. Plurality of R^{a02}s may be the same of different. Plurality of R^{a02}s is preferably the same.

In the formula (A1), X^{a01} is oxygen atom or sulfur atom, and preferably oxygen atom. In the formula (A1), there are multiple X^{a01}s. Plurality of X^{a01}s may be the same of different. Plurality of X^{a01}s is preferably the same.

In the formula (A1), X^{a02} is an organic group having 1 or more and 3 or less carbon atoms and a valence of n+1, oxygen atom, or sulfur atom. In addition, n is 1 or 2, and preferably 1. When X^{a02} is oxygen atom or sulfur atom, n is 1.

When n is 1, the organic group as X^{a02} is a divalent organic group. As the divalent organic group, an alkylene group having 1 or more and 3 or less carbon atoms, —CH₂—CO—, —CH₂—CH₂—CO—, —CH₂—CO—CH₂—, —CH₂—O—, —CH₂—CH₂—O—, —CH₂—CH₂—CH₂—O—, —O—CH₂—O—, —O—CH₂—CH₂—O—, —O—CH₂—CH₂—CH₂—O—, —CH₂—O—CH₂—, —CH₂—O—CH₂—CH₂—, —CH₂—NH—, —CH₂—CH₂—NH—, —CH₂—CH₂—CH₂—NH—, —NH—CH₂—NH—, —NH—CH₂—CH₂—NH—, —NH—CH₂—CH₂—CH₂—NH—, —CH₂—NH—CH₂—, and —CH₂—NH—CH₂—CH₂— are exemplified. Specific examples of the alkylene group having 1 or more and 3 or less carbon atoms as X^{a02} are the same as the specific examples of the alkylene group having 1 or more and 3 or less carbon atoms as R^{a02}. As the alkylene group having 1 or more and 3 or less carbon atoms as X^{a02}, methylene group, ethane-1,2-diyl group (ethylene group), propane-1,3-diyl group, and propane-1,2-diyl group are preferred, and methylene group is more preferred.

When n is 1, X^{a02} is preferably methylene group, oxygen atom, or sulfur atom.

When n is 2, the organic group as X^{a02} is a trivalent organic group. As the trivalent organic group, an alkanetriyl group having 1 or more and 3 or less carbon atoms is preferred. Specific examples of the alkanetriyl group include methanetriyl group, ethane-1,1,1-triyl group, ethane-1,1,2-triyl group, propane-1,1,1-triyl group, propane-1,1,2-triyl group, propane-1,1,3-triyl group, propane-1,2,2-triyl group, and propane-1,2,3-triyl group. Among these groups, methanetriyl is preferred.

In the formula (A1), Ar is an optionally substituted aromatic hydrocarbon group having 6 or more and 12 or less carbon atoms. As the aromatic hydrocarbon group, phenylene group, naphthalenediyl group, and biphenyldiyl group are exemplified. More specifically, as the aromatic hydrocarbon group, o-phenylene group, m-phenylene group, p-phenylene group, naphthalen-1,2-diyl group, naphthalen-1,3-diyl group, naphthalen-1,4-diyl group, naphthalen-1,5-diyl group, naphthalen-1,6-diyl group, naphthalen-1,7-diyl group, naphthalen-1,8-diyl group, naphthalen-2,3-diyl group, naphthalen-2,6-diyl group, naphthalen-2,7-diyl group, biphenyl-4,4′-diyl group, biphenyl-3,3′-diyl group, and biphenyl-3,4′-diyl group are exemplified. Among these aromatic hydrocarbon groups, m-phenylene group, p-phenylene group, naphthalen-1,4-diyl group, naphthalen-2,6-diyl group, naphthalen-2,7-diyl group, biphenyl-4,4′-diyl group, and biphenyl-3,3′-diyl group are preferred, p-phenylene group, naphthalen-2,6-diyl group, and biphenyl-4,4′-diyl group are more preferred, and p-phenylene group is particularly preferred.

The aromatic hydrocarbon group as Ar may have a substituent. Type of the substituent is not particularly limited as long as the desired effect is not impaired. Examples of the substituent include a halogen atom, hydroxy group, mercapto group, cyano group, nitro group, and a monovalent organic group. Examples of the halogen atom as the substituent include fluorine atom, chlorine atom, bromine atom, and iodine atom. Examples of the monovalent organic group include an alkyl group, an alkoxy group, an alkoxyalkyl group, an aliphatic acryl group, an aliphatic acyloxy group, an alkoxycarbonyl group, an alkylthio group, an aliphatic acylthio group, and the like.

A number of carbon atoms in the monovalent organic group as the substituent is not particularly limited as long as the desired effect is not impaired. For example, the number of carbon atoms in the monovalent organic group as the substituent is preferably 1 or more and 20 or less, more preferably 1 or more and 12 or less, and further preferably 1 or more and 8 or less. In the alkoxyalkyl group, the aliphatic acyl group, the aliphatic acyloxy group, the alkoxycarbonyl group, the alkoxyalkylthio group, and the aliphatic acylthio group, lower limit of the number of carbon atoms is 2.

Suitable specific examples of the alkyl group as the substituent include methyl group, ethyl group, n-propyl group, isopropyl group, n-butyl group, isobutyl group, sec-butyl group, tert-butyl group, n-pentyl group, n-hexyl group, n-heptyl group, and n-octyl group.

Suitable specific examples of the alkoxy group as the substituent include methoxy group, ethoxy group, n-propyloxy group, isopropyl oxy group, n-butyloxy group, isobutyloxy group, sec-butyloxy group, tert-butyloxy group, n-pentyloxy group, n-hexyloxy group, n-heptyloxy group, and n-octyloxy group.

Suitable specific examples of the alkoxyalkyl group include methoxymethyl group, ethoxymethyl group, n-propyloxymethyl group, n-butyloxymethyl group, 2-methoxyethyl group, 2-ethoxyethyl group, 2-n-propyloxymethyl group, 2-n-butyloxyethyl group, 3-methoxy-n-propyl group, 3-ethoxy-n-propyl group, 3-n-propyloxy-n-propyl group, 3-n-butyloxy-n-propyl group, 4-methoxy-n-bnutyl group, 4-ethoxy-n-butyl group, 4-n-propyloxy-n-butyl group, and 4-n-butyloxy-n-butyl group.

Suitable specific examples of the aliphatic acyl group include acetyl group, propionyl group, butanoyl group, pentanoyl group, hexanoyl group, heptanoyl group, and octanoyl group.

Suitable specific examples of the aliphatic acyloxy group as the substituent include acetoxy group, propionyloxy group, butanoyloxy group, pentanoyloxy group, hexanoyloxy group, heptanoyloxy group, and octanoyloxy group.

Suitable specific examples of the alkoxycarbonyl group as the substituent include methoxycarbonyl group, ethoxycarbonyl group, n-propyloxycarbonyl group, isopropyloxycarbonyl group, n-butyloxycarbonyl group, isobutyloxycarbonyl group, sec-butyloxycarbonyl group, tert-butyloxycarbonyl group, n-pentyloxycarbonyl group, n-hexyloxycarbonyl group, n-heptyloxycarbonyl group, and n-octyloxycarbonyl group.

Suitable specific examples of the alkylthio group as the substituent include methylthio group, ethylthio group, n-propylthio group, isopropylthio group, n-butylthio group, isobutylthio group, sec-butylthio group, tert-butylthio group, n-pentylthio group, n-hexylthio group, n-heptylthio group, and n-octylthio group.

Suitable specific examples of the aliphatic acylthio group as the substituent include acetylthio group, propionylthio group, butanoylthio group, pentanoylthio group, hexanoylthio group, heptanoylthio group, and ocatnoylthio group.

When the aromatic hydrocarbon group as Ar has the substituent, a number of the substituent is not particularly limited as long as the desired effect is not impaired. When the aromatic hydrocarbon group as Ar has the substituent, the number of the substituent is preferably 1 or more and 4 or less, more preferably 1 or 2, and particularly preferably 1. When the aromatic hydrocarbon group has a plurality of substituents, the plurality of substituents may be the same or different.

Suitable specific examples of the compound (A1) include following compounds.

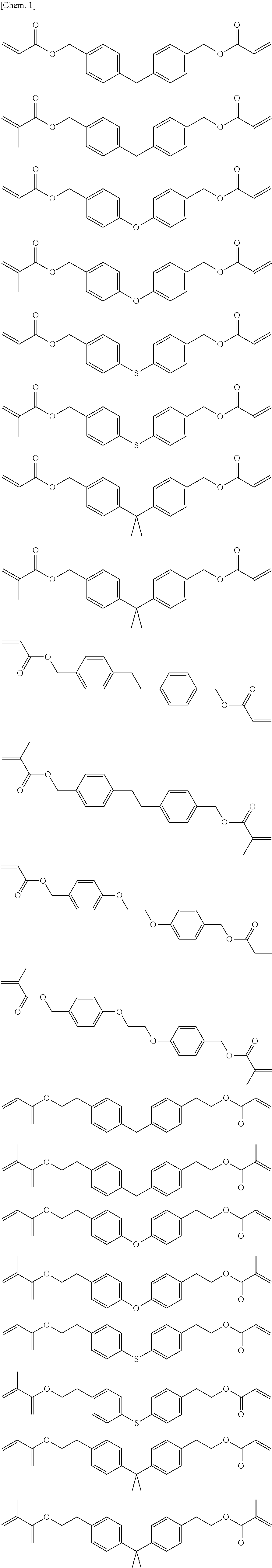

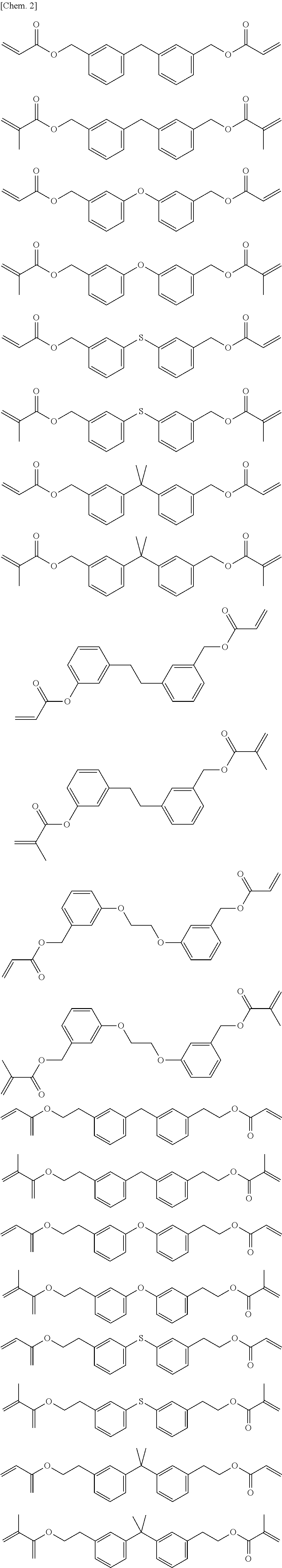

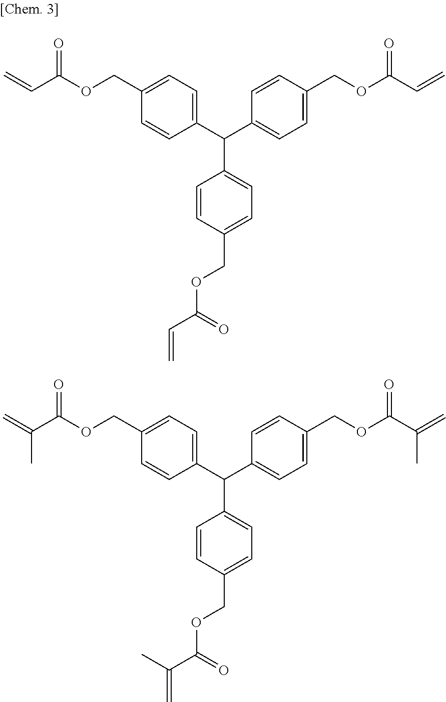

### [Other Photopolymerizable Compound (A2)]

As described above, the composition can include other photopolymerizable compound (A2) than the compound (A1) with the compound (A1). Since the compound (A1) has the radically polymerizable group-containing group, other photopolymerizable compound (A2) also has the radically polymerizable group-containing group.

When the photopolymerizable compound (A) includes the compound (A1) and other photopolymerizable compounds (A2), a preferred ratio of the mass of other photopolymerizable compounds (A2) to the mass of the photopolymerizable compound (A) depends on the type of other photopolymerizable compound (A2). Typically, the ratio of the mass of the other photopolymerizable compound (A2) to the mass of the photopolymerizable compound (A) is preferably 10% by mass or more and 90% by mass or less, more preferably 20% by mass or more and 80% by mass or less, and further preferably 30% by mass or more and 70% by mass or less.

Other photopolymerizable compound (A2) may be a monofunctional compound having one radically polymerizable group-containing group, or polyfunctional compound having two or more radically polymerizable group-containing group, and is preferably the polyfunctional compound. As other photopolymerizable compound (A2) having the radically polymerizable group-containing group, a compound having one or more (meth)acryloyl groups such as (meth)acrylate compound and (meth)acrylic amide compound is preferred, and the (meth)acrylate compound having one or more (meth)acryloyloxy groups is more preferred.

Examples of the monofunctional compound having the radically polymerizable group-containing group include (meth)acrylamide, methylol (meth)acrylamide, methoxymethyl (meth)acrylamide, ethoxymethyl (meth)acrylamide, propoxymethyl (meth)acrylamide, butoxymethoxymethyl (meth)acrylamide, N-methylol (meth)acrylamide, N-hydroxymethyl (meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamidesulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, dimethylamino (meth)acrylate, glycidyl (meth)acrylate, 2,2,2-trifluoroethyl (meth)acrylate, 2,2,3,3-tetrafluoropropyl (meth)acrylate, a half (meth)acrylate of phthalic acid derivatives, and the like. These monofunctional compounds may be used alone, or in combination of two or more types thereof.

Examples of the polyfunctional compound having the radically polymerizable group-containing group include ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerin di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, diallyl phthalate, diallyl isophthalate, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylate (i.e., tolylene diisocyanate, trimethylhexamethylene diisocyanate, or a reaction product of hexamethylene diisocyanate and 2-hydroxyethyl (meth)acrylate), methylenebis(meth)acrylamide, (meth)acrylamide methylene ether, a polyfunctional compound such as a fused product of polyhydric alcohol and N-methylol(meth)acrylamide, triacryl formal, and the like. Since the cured product can be formed having particularly high refractive index, diallyl phthalate and diallyl isophthalate are preferred among these polyfunctional compounds. These polyfunctional compounds may be used alone, or in combination of two or more types thereof.

Among these other photopolymerizable compounds (A2) having the radically polymerizable group-containing group, a trifunctional or higher polyfunctional compound is preferred, a tetrafunctional or higher polyfunctional compound is more preferred, and a pentafunctional or higher polyfunctional compound is further preferred, in view of tendency to increase the strength of the material formed by using the composition.

When the photopolymerizable compound (A) includes the monofunctional compound as other photopolymerizable compound (A2), a ratio of a mass of the monofunctional compound is preferably less than 20% by mass, and more preferably 10% by mass or less relative to a mass of the photopolymerizable compound (A).

From the viewpoint of high curability, the composition preferably includes a compound represented by following formula (A-2a) or a compound represented by following formula (A-2b) as the photopolymerizable compound (A).

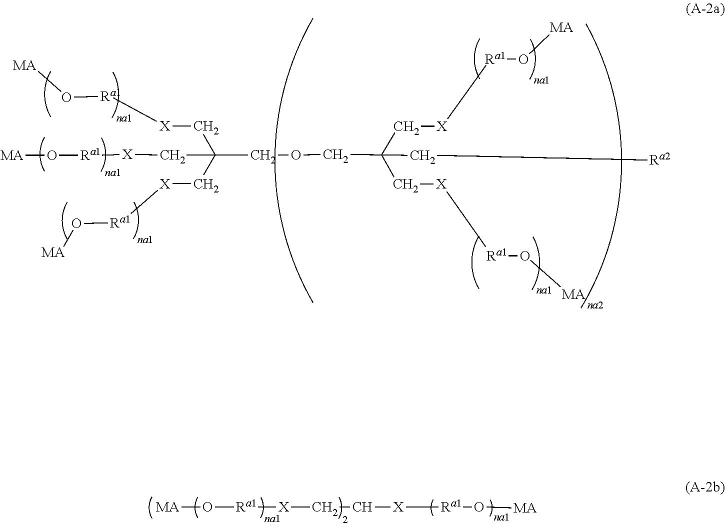

In the formula (A-2a) and the formula (A-2b), MAs are each independently a (meth)acryloyl group. Xs are each independently oxygen atom, —NH—, or —N(CH₃)—. R^{a1}s are each independently ethane-1,2-diyl group, propane-1,2-diyl group, or propane-1,3-diyl group. R^{a2} is a hydroxy group, an alkyl group having 1 or more and 4 or less carbon atoms, or a group represented by —X—(R^{a1}—O)ₙₐ₁-MA. X is the same as above. na1 and na2 are each independently 0 or 1.

In the formula (A-2a), examples of the alkyl group having 1 or more and 4 or less carbon atoms as R^{a2} include methyl group, ethyl group, n-propyl group, isopropyl group, n-butyl group, isobutyl group, sec-butyl group, and tert-butyl group. Among these alkyl groups, methyl group and ethyl group are preferred.

Suitable examples of the compound represented by the formula (A-2a), and the compound represented by the formula (A-2b) include pentaerythritol tetra(meth)acrylate, dipentaerythritol hexa(meth)acrylate, trimethylolpropane tri(meth)acrylate, glycerin tri(meth)acrylate, and the following compounds of 1) to 32). In following compounds of 1) to 32), MA is (meth)acryloyl group.
1) (MA-NH—CH₂)₄—C
2) (MA-N(CH₃)—CH₂)₄—C
3) (MA-O—CH₂CH₂CH₂—O—CH₂)₄—C
4) (MA-O—CH₂CH₂—O—CH₂)₄—C
5) (MA-O—CH₂CH₂CH₂—NH—CH₂)₄—C
6) (MA-O—CH₂CH₂—NH—CH₂)₄—C
7) (MA-O—CH₂CH₂CH₂—N(CH₃)—CH₂)₄—C
8) (MA-O—CH₂CH₂—N(CH₃)—CH₂)₄—C
9) (MA-NH—CH₂)₃—C—CH₂—O—CH₂—C—(CH₂—NH-MA)₃
10) (MA-N(CH₃)—CH₂)₃—C—CH₂—O—CH₂—C—(CH₂—N(CH₃)-MA)₃
11) (MA-O—CH₂CH₂CH₂—O—CH₂)₃—C—CH₂—O—CH₂—C—(CH₂—O—CH₂CH₂CH₂—O-MA)₃
12) (MA-O—CH₂CH₂—O—CH₂)₃—C—CH₂—O—CH₂—C—(CH₂—O—CH₂CH₂—O-MA)₃
13) (MA-O—CH₂CH₂CH₂—NH—CH₂)₃—C—CH₂—O—CH₂—C—(CH₂—NH—CH₂CH₂CH₂—O-MA)₃
14) (MA-O—CH₂CH₂—NH—CH₂)₃—C—CH₂—O—CH₂—C—(CH₂—NH—CH₂CH₂—O-MA)₃
15) (MA-O—CH₂CH₂CH₂—N(CH₃)—CH₂)₃—C—CH₂—O—CH₂—C—(CH₂—N(CH₃)—CH₂CH₂CH₂—O-MA)₃
16) (MA-O—CH₂CH₂—N(CH₃)—CH₂)₃—C—CH₂—O—CH₂—C—(CH₂—N(CH₃)—CH₂CH₂—O-MA)₃
17) (MA-NH—CH₂)₂—CH—NH-MA
18) (MA-N(CH₃)—CH₂)₂—CH—N(CH₃)-MA
19) (MA-O—CH₂CH₂CH₂—O—CH₂)₂—CH—O—CH₂CH₂CH₂—O-MA
20) (MA-O—CH₂CH₂—O—CH₂)₂—CH—C—O—CH₂CH₂—O-MA
21) (MA-O—CH₂CH₂CH₂—NH—CH₂)₂—CH—NH—CH₂CH₂CH₂—O-MA
22) (MA-O—CH₂CH₂—NH—CH₂)₂—CH—NH—CH₂CH₂—O-MA
23) (MA-O—CH₂CH₂CH₂—N(CH₃)—CH₂)₂—CH—N(CH₃)—CH₂CH₂CH₂—O-MA.
24) (MA-O—CH₂CH₂—N(CH₃)—CH₂)₂—CH—N(CH₃)—CH₂CH₂—O-MA
25) (MA-NH—CH₂)₃—C—CH₂CH₃
26) (MA-N(CH₃)—CH₂)₃—C—CH₂CH₃
27) (MA-O—CH₂CH₂CH₂—O—CH₂)₃—C—CH₂CH₃
28) (MA-O—CH₂CH₂—O—CH₂)₃—C—CH₂CH₃
29) (MA-O—CH₂CH₂CH₂—NH—CH₂)₃—C—CH₂CH₃
30) (MA-O—CH₂CH₂—NH—CH₂)₃—C—CH₂CH₃
31) (MA-O—CH₂CH₂CH₂—N(CH₃)—CH₂)₃—C—CH₂CH₃
32) (MA-O—CH₂CH₂—N(CH₃)—CH₂)₃—C—CH₂CH₃

In view of curability of the photopolymerizable compound (A), a ratio of sum of a mass of the compound represented by the formula (A-2a) and a mass of the compound represented by the formula (A-2b) is preferably 20% by mass or more and 50% by mass or less, more preferably 30% by mass or more and 50% by mass or less, and further preferably 40% by mass or more and 50% by mass or less relative to a mass of the photopolymerizable compound (A).

From the viewpoint of ease of forming a material with high refractive index by using the composition, the composition preferably includes other photopolymerizable compound (A2) having the radically polymerizable group-containing group. The photopolymerizable compound (A2) preferably includes a diarylsulfide compound in which two aryl groups substituted with the radically polymerizable group are bonded via —S—. Such diarylsulfide compounds may have a substituent other than the radically polymerizable group-containing group on the aryl group. The substituent other than the radically polymerizable group-containing group is same as the substituent which the aromatic hydrocarbon group as Ar may have. For example, as the aryl group, phenyl group, naphthalen-1-yl group, naphthalen-2-yl group, 4-phenylphenyl group, 3-phenylphenyl group, and 2-phenylphenyl group are exemplified. Among these, phenyl group is preferred. As the diarylsulfide compound described above, for example, a compound represented by following formula (A-2c) is preferred.

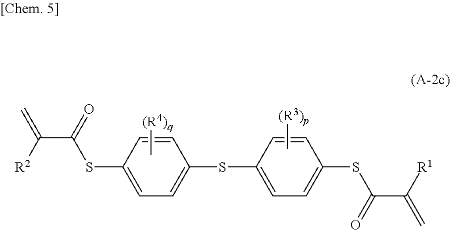

In the formula (A-2c), R¹ and R² are each independently hydrogen atom or methyl group. R³ and R⁴ are each independently an alkyl group having 1 or more and 5 or less carbon atoms. p and q are each independently 0 or 1.

R¹ and R² are each independently hydrogen atom or methyl group. R¹ and R² may be different or may be the same. Since the compound represented by the formula (A-2c) is easily synthesized and available, R¹ and R² are preferably the same.

R³ and R⁴ are each independently an alkyl group having 1 or more and 5 or less carbon atoms. R³ and R⁴ may be different or may be the same. Since the compound represented by the formula (A-2c) is easily synthesized and available, R¹ and R⁴ are preferably the same.

The alkyl group having 1 or more and 5 or less carbon atoms as R³ and R⁴ may be linear or branched. Examples of the alkyl group having 1 or more and 5 or less carbon atoms as R³ and R⁴ include methyl group, ethyl group, n-propyl group, isopropyl group, n-butyl group, isobutyl group, sec-butyl group, tert-butyl group, n-pentyl group, isopentyl group, and tert-pentyl group.

Suitable specific examples of the compound represented by the formula (A-2c) include following compounds.

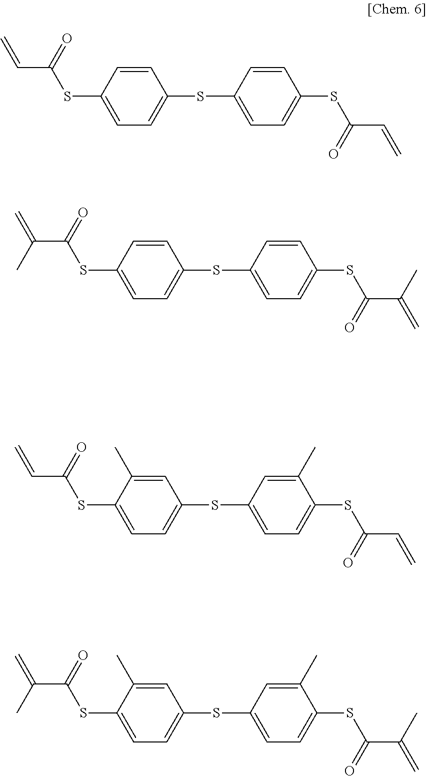

When the composition includes the compound represented by the formula (A-2c) as other photopolymerizable compound (A2), a ratio of a mass of the compound represented by the formula (A-2c) is preferably 10% by mass or more and 50% by mass or less, and more preferably 30% by mass or more and 50% by mass or less relative to the mass of the photopolymerizable compound (A).

As the above-described diarylsulfide compound, a compound represented by following formula 8A-2d) is preferred.

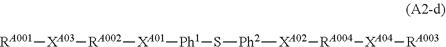

In the formula (A2-d), R^{A001} and R^{A002} are each independently a radically polymerizable group-containing group, or a cationically polymerizable group-containing group. R^{A002} and R^{A004} are each independently an alkylene group optionally interrupted by one or more oxygen atom and/or sulfur atom. X^{A01}, X^{A02}, X^{A03}, and X^{A04} are each independently oxygen atom or sulfur atom. Ph¹ and Ph² are each independently phenylene group optionally substituted with an alkyl group having 1 or more and 5 or less carbon atoms. Sum of a number of oxygen atoms and/or sulfur atoms included in the alkylene group as R^{A002} and a number of oxygen atoms and/or sulfur atoms included in the alkylene group as R^{A004} is 2 or more. The compound represented by the formula (A2-d) does not simultaneously have the radically polymerizable group-containing group and the cationically polymerizable group-containing group.

In the formula (A-2d), Ph¹ and Ph² are each independently a phenylene group optionally substituted with an alkylene group having 1 or more and 5 or less carbon atoms. The Phenylene group as Ph¹ and Ph² may be any one of o-phenylene group, m-phenylene group, and p-phenylene group. Among these, the phenylene group is preferably p-phenylene group.

A number of alkyl groups as substituent bonding to the phenylene group as Ph¹ and Ph² is not particularly limited. Examples of the alkyl group having 1 or more and 5 or less carbon atoms include methyl group, ethyl group, n-propyl group, isopropyl group, n-butyl group, isobutyl group, sec-butyl group, tert-butyl group, n-pentyl group, isopentyl group, neopentyl group, sec-pentyl group and tert-pentyl group. Among these group, methyl group and ethyl group are preferred.

R^{A001} and R^{A003} are each independently the radically polymerizable group-containing group. The radically polymerizable group-containing group is as described above. As the radically polymerizable group-containing group as R^{A001} and R^{A003}, (meth)acryloyl group-containing group is preferred, and (meth)acryloyl group is more preferred.

R^{A002} and R^{A004} are each independently an alkylene group which may be interrupted by one or more oxygen atoms and/or one or more sulfur atoms. R^{A002} and R^{A004} are preferably an alkylene group interrupted by one or more oxygen atoms and/or one or more sulfur atoms. Number of carbon atoms in the alkylene group which may be interrupted by one or more oxygen atoms and/or one or more sulfur atoms as R^{A002}, and R^{A004} is not particularly limited as long as the desired effect is not impaired

The alkylene group which may be interrupted by one or more oxygen atoms and/or one or more sulfur atoms as R^{A002} and R^{A004} is preferably a group consisting of: ma aliphatic chain saturated hydrocarbon groups selected form an alkylene group having 1 or more and 4 or less carbon atoms, an alkanetriyl group having 1 or more and 4 or less carbon atoms, and an alkyl group having 1 or more and 4 or less carbon atoms; and (ma-1) oxygen atoms and/or sulfur atoms bridging the ma aliphatic chain saturated hydrocarbon groups. Herein, ma is an integer of 2 or more and 6 or less.

Suitable examples of the alkylene group having 1 or more and 4 or less carbon atoms include methylene group, ethane-1,2-diyl group (ethylene group), propae-1,2-diyl group, propane-1,3-diyl group, butane-1,2-diyl group, butane-1,3-diyl group, and butane-1,4-diyl group. Among these groups, ethane-1,2-diyl group (ethylene group), propane-1,2-diyl group and propane-1,3-diyl group are preferred. Suitable examples of the alkanetriyl group having 1 or more and 4 or less carbon atoms include propane-1,2,3-triyl group, butane-1,2,3-triyl group, and butane-1,2,4-triyl group. Among these groups, propane-1,2,3-triyl group is preferred. Suitable examples of the alkyl group having 1 or more and 4 or less carbon atoms include methyl group, ethyl group, n-propyl group, isopropyl group, n-butyl group, isobutyl group, sec-butyl group, and tert-butyl group. Among these groups, methyl group and ethyl group are preferred.

The alkylene group which may be interrupted by one or more oxygen atoms and/or one or more sulfur atoms as R^{A002} and R^{A004} is preferably a group consisting of ma alkylene groups having 1 or more 4 or less carbon atoms, and (ma-1) oxygen atoms and/or sulfur atoms bridging the ma alkylene groups. Herein, ma is an integer of 2 or more and 6 or less.

Suitable specific examples of the alkylene group which may be interrupted by one or more oxygen atoms and/or one or more sulfur atoms as R^{A002} and R^{A004} include following groups.
—CH₂CH₂—O—CH₂CH₂—
—(CH₂CH₂O—)₂—CH₂CH₂—
—(CH₂CH₂O—)₃—CH₂CH₂—
—(CH₂CH₂O—)₄—CH₂CH₂—
—(CH₂CH₂—O)₅—CH₂CH₂—
—C(CH₃)HCH₂—O—C(CH₃)HCH₂—
—(C(CH₃)HCH₂—O)₂—C(CH₃)HCH₂—
—(C(CH₃)HCH₂—O)₃—C(CH₃)HCH₂—
—(C(CH₃)HCH₂—O)₄—C(CH₃)HCH₂—
—(C(CH₃)HCH₂—O)₂—C(CH₃)HCH₂—
—CH₂CH₂CH₂—O—CH₂CH₂CH₂—
—(CH₂CH₂CH₂—O)₂—CH₂CH₂CH₂—
—(CH₂CH₂CH—O)₃—CH₂CH₂CH₂—
—(CH₂CH₂CH₂—O)₄—CH₂CH₂CH₂—
—(CH₂CH₂CH₂—O)—CH₂CH₂CH₂—
—CH₂C(OCH₃)HCH₂—
—CH₂C(OCH₂CH₃)HCH₂—
—CH₂C(OCH₂CH₂CH₃)HCH₂—
—CH₂C(OCH₂CH₂CH₂CH₃)HCH₂—
—CH₂CH₂—S—CH₂CH₂—
—(CH₂CH₂—S)₂—CH₂CH₂—
—(CH₂—CH₂—S)₃—CH₂CH₂—
—(CH₂—CH₂—S)₄—CH₂CH₂—
—(CH₂—CH₂—S)₅—CH₂CH₂—
—C(CH₃)HCH₂—S—C(CH₃HCH₂—
—(C(CH₃)HCH₂—S)₂—C(CH₂)HCH₂—
—(C(CH₃)HCH₂—S)₃—C(CH₃)HCH₂—
—(C(CH₃)HCH₂—S)₄—C(CH₃)HCH₂—
—(C(CH₃)HCH₂—S)₅—C(CH₃)HCH₂—
—CH₂CH₂CH₂—S—CH₂CH₂CH₂—
—(CH₂CH₂CH₂—S)₂—CH₂CH₂CH₂—
—(CH₂CH₂CH₂—S)₃—CH₂CH₂CH₂—
—(CH₂CH₂CH₂—S)₄—CH₂CH₂CH₂—
—(CH₂CH₂CH₂—S)₅—CH₂CH₂CH₂—
—CH₂C(SCH₃)HCH₂—
—CH₂C(SCH₂CH₃)HCH₂—
—CH₂C(SCH₂CH₂CH₃)HCH₂—
—CH₂C(SCH₂CH₂CH₂CH₃)HCH₂—

Among these groups,
—CH₂CH₂O—CH₂CH₂—,
—(CH₂CH₂—O)₂CH₂CH₂—,
—(CH₂CH₂—O)₃—CH₂CH₂—,
—CH₂CH₂CH₂—O—CH₂CH₂CH₂—,
—CH₂CH₂—S—CH₂CH₂—,
—(CH₂CH₂—S)₂—CH₂CH₂—, and
—(CH₂CH₂—S)₃—CH₂CH₂— are preferred, and
—(CH₂—CH₂—O)₃—CH₂CH₂—,
—(CH₂—CH₂—O)₂—CH₂CH₂—,
—(CH₂CH₂—S)₃—CH₂CH₂—, and
—(CH₂CH₂—S)₃—CH₂CH₂— are more preferred.

In the formula (A2-d), X^{A01}, X^{A02}, X^{A03}, and X^{A04} are each independently oxygen atom or sulfur atom.

In the formula (A2-d), sum of the number of oxygen atoms and/or sulfur atoms included in the alkylene group as R^{A002} and the number of oxygen atoms and/or sulfur atoms is 2 or more. By inclusion of specific amount or more of oxygen atom or sulfur atom at a specific position in the compound represented by the formula (A2-d), excessive loss of mass of the component other than the solvent is suppressed when the composition is heated, and dispersion of the metal oxide particles (B) in the composition can be stabilized. Upper limit of the sum of the number of oxygen atoms and/or sulfur atoms included in the alkylene group as R^{A002} and the number of oxygen atoms and/or sulfur atoms included in the alkylene group as R^{A004} is not particularly limited as long as the desired effect is not impaired. For example, the sum of the number of oxygen atoms and/or sulfur atoms included in the alkylene group as R^{A002} and the number of oxygen atoms and/or sulfur atoms included in the alkylene group as R^{A004} is preferably 2 or more and 10 or less, more preferably 2 or more and 8 or less, and further preferably 2 or more and 6 or less.

Suitable specific examples of the compound represented by the formula (A2-d) include following compounds. Compounds which a bridging group bridging acryloyloxy group or methacryloyloxy group and aryloxy group, arylthio group, heteroaryloxy group, or heteroarylthio group is replaced with —CH₂CH₂—O—CH₂CH₂—, —(CH₂CH₂—O)₂—CH₂CH₂—, —(CH₂CH₂—O)₂—CH₂CH₂—, —CH₂CH₂CH₂—O—CH₂CH₂CH₂—, —CH₂CH₂—S—CH₂CH₂—, —(CH₂CH₂—S)₂—CH₂CH₂—, and —(CH₂CH₂—S)₃—CH₂CH₂— in following compounds are also preferred.

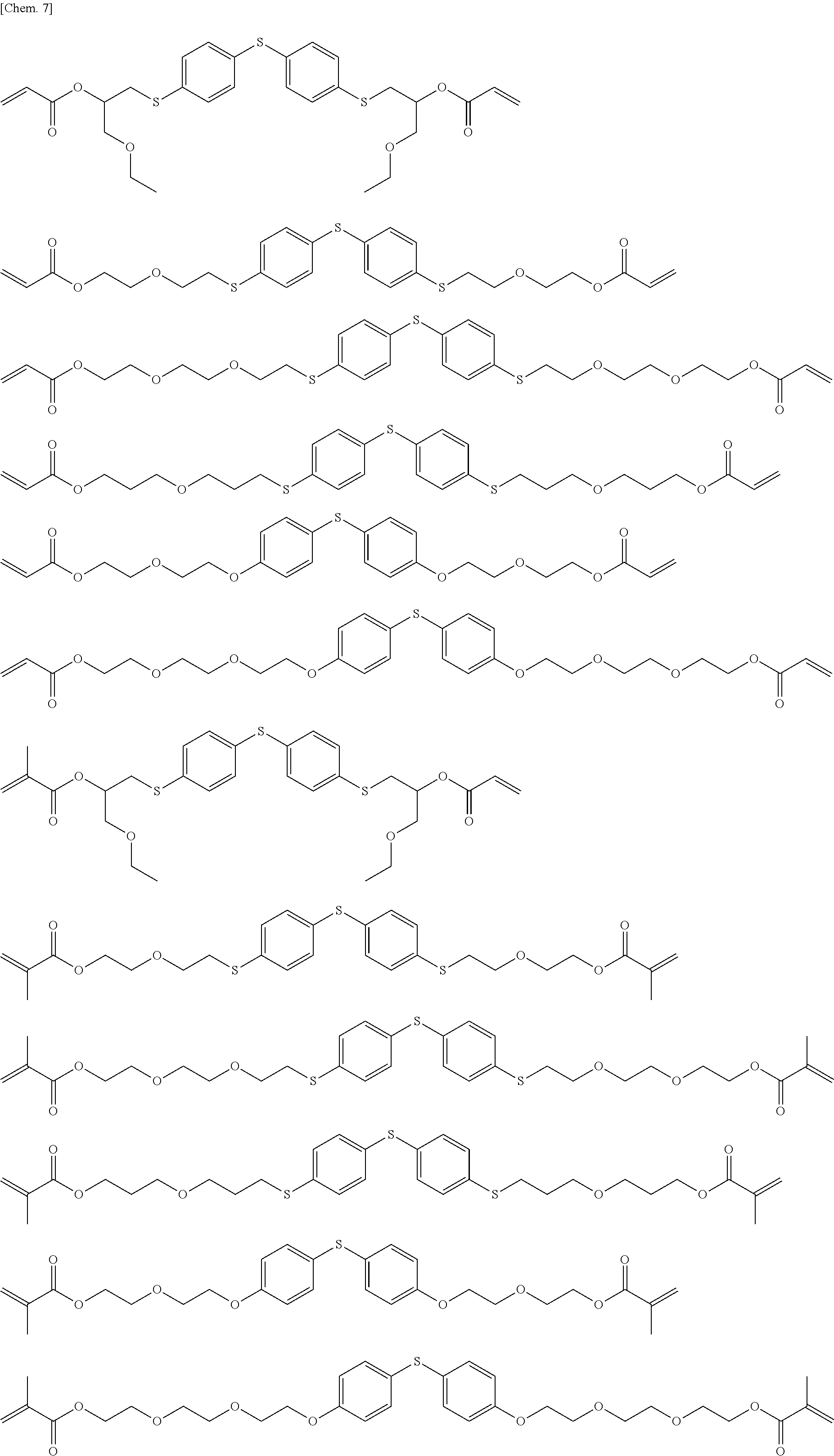

In a case that the composition includes the compound represented by the formula (A-2d) as other photopolymerizable compound (A2) having the radically polymerizable group-containing group, a ratio of a mass of the compound represented by the formula (A-2d) is preferably 10% by mass or more and 50% by mass or less, and more preferably 30% by mass or more and 50% by mass or less relative to a mass of the photopolymerizable compound (A).

From the viewpoint of good curability of the photopolymerizable compound (A), the composition preferably includes a sulfur-containing (meth)acrylate represented by following formula (A-2e) as other photopolymerizable compound (A2) having the radically polymerizable group-containing group.

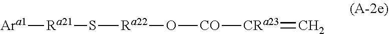

In the formula (A-2e), Ar^{a1} is phenyl group optionally substituted with a halogen atom. R^{a21} is a single bond or an alkylene group having 1 or more and 6 or less carbon atoms. R^{a22} is an alkylene group having 1 or more and 6 or less carbon atoms. R^{a23} is hydrogen atom or methyl group.

Ar^{a1} is the phenyl group optionally substituted with the halogen atom. When the phenyl group is substituted with the halogen atom, a number of halogen atoms bonding to the phenyl group is not particularly limited. A number of halogen atoms bonding to the phenyl group is preferably 1 or 2, and more preferably 1. When two or more halogen atoms bond to the phenyl group, a plurality of halogen atoms bonding to the phenyl group may consist of only halogen atoms of the same species or halogen atoms of two or more species. As the halogen atom which may bond to the phenyl group, fluorine atom, chlorine atom, bromine atom, and iodine atom are exemplified. Among these, as the halogen atom, fluorine atom, chlorine atom, and bromine atom are preferred. Unsubstituted phenyl group is preferred as Are.

R^{a21} is a single bond or an alkylene group having 1 or more and 6 or less carbon atoms. Examples of the alkylene group having 1 or more and 6 or less carbon atoms include methylene group, ethane-1,2-diyl group, propane-1,2-diyl group, propane-1,3-diyl group, butane-1,4-diyl group, pentane-1,5-diyl group, and hexane-1,6-diyl group. R^{a21} is preferably single bond or methylene group, and more preferably single bond.

R^{a22} is an alkylene group having 1 or more and 6 or less carbon atoms. Examples of the alkylene group having 1 or more and 6 or less carbon atoms include methylene group, ethane-1,2-diyl group, propane-1,2-diyl group, propane-1,3-diyl group, butane-1,4-diyl group, pentane-1,5-diyl group, and hexane-1,6-diyl group. R^{a22} is preferably methylene group, ethane-1,2-diyl group, and propane-1,3-diyl group, and more preferably ethane-1,2-diyl group, and propane-1,3-diyl group.

In view of easy availability of the sulfur-containing (meth)acrylate, and good curability of the photopolymerizable compound (A), in the formula (A-2e) it is particularly preferred that Ar^{a1} is phenyl group and R^{a21} is single bond.

Specific examples of the sulfur-containing (meth)acrylate represented by the formula (A-2e) include 2-phenylthioethyl (meth)acrylate, 3-phenylthiopropyl (meth)acrylate, 2-benzylthioethyl (meth)acrylate, 3-benzylthiopropyl (meth)acrylate, 2-(2-chlorophenyl)ethyl (meth)acrylate, 2-(3-chlorophenyl)ethyl (meth)acrylate, 2-(4-chlorophenyl)ethyl (meth)acrylate, 3-(2-chlorophenyl)propyl (meth)acrylate, 3-(3-chlorophenyl)propyl (meth)acrylate, 3-(4-chlorophenyl)propyl (meth)acrylate, 2-(2-fluorophenyl)ethyl (meth)acrylate, 2-(3-fluorophenyl)ethyl (meth)acrylate, 2-(4-fluorophenyl)ethyl (meth)acrylate, 3-(2-fluorophenyl)propyl (meth)acrylate, 3-(3-fluorophenyl)propyl (meth)acrylate, 3-(4-fluorophenyl)propyl (meth)acrylate, 2-(2-bromophenyl)ethyl (meth)acrylate, 2-(3-bromophenyl)ethyl (meth)acrylate, 2-(4-bromophenyl)ethyl (meth)acrylate, 3-(2-bromophenyl)propyl (meth)acrylate, 3-(3-bromophenyl)propyl (meth)acrylate, and 3-(4-bromophenyl)propyl (meth)acrylate.

When the composition includes the sulfur-containing (meth)acrylate represented by the formula (A-2e) as other radically polymerizable compound (A2) having the radically polymerizable group-containing group, a ratio of a mass of the sulfur-containing (meth)acrylate represented by the formula (A-2e) is preferably 40% by mass or more and 50% by mass or less relative to the mass of the photopolymerizable compound (A).

In view of easily obtaining the cured product with high refractive index by using the composition, the composition preferably includes a compound represented by following formula (A-2f) as other photopolymerizable compound (A2).

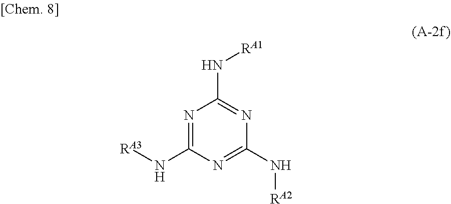

In the formula (A-2f), R^{A1}, R^{A2}, and R^{A3} are each independently an organic group. At least two of the organic group as R^{A1}, the organic group as R^{A2}, and the organic group as R^{A3} have the radically polymerizable group-containing group.

Suitable examples of the compound represented by the formula (A-2f) include a compound represented by following formula (A-2f-a).

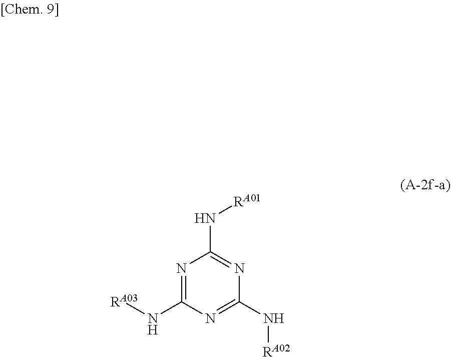

In the formula (A-2f-ad), R^{A01} is an optionally substituted quinolinyl group, an optionally substituted isoquinolinyl group, or an optionally substituted 2-substituted benzothiazolyl group. The 2-substituted benzothiazolyl group has a group represented by —S—R^{A0} at 2-position. R^{A0} is hydrogen atom or a radically polymerizable group-containing group. Both of R^{A02} and R^{A03} are aromatic ring-containing group having the radically polymerizable group-containing group. —NH— group bonding to triazine ring bonds to the aromatic rings in R^{A02} and R^{A03}.

All of the optionally substituted quinolinyl group, the optionally substituted isoquinolinyl group, and the optionally substituted 2-substituted benzothiazolyl group have large polarizability and small volume as a functional group. Therefore, it is thought that the optionally substituted quinolinyl group, the optionally substituted isoquinolinyl group, and the optionally substituted 2-substituted benzothiazolyl group give high refractive index to the material formed by using the composition.

The quinolinyl group as R^{A01} may be any one of quinolin-2-yl group, quinolin-3-yl group, quinolin-4-yl group, quinolin-5-yl group, quinolin-6-yl group, quinolin-7-yl group, and quinolin-8-yl group. Among these groups, quinolin-3-yl group and quinolin-4-yl group are preferred in view of ease of obtaining raw material compound for the compound represented by the formula (A-2f-a), ease of synthesizing the compound represented by the formula (A-2f-a), and the like.

The isoquinolinyl group as R^{A01} may be any one of isoquinolin-1-yl group, isoquinolin-3-yl group, isoquinolin-4-yl group, isoquinolin-5-yl group, isoquinolin-6-yl group, isoquinolin-7-yl group, and isoquinolin-8-yl group.

The substituent which quinolinyl group and isoquinolinyl group as R^{A01} may have is not particularly limited as long as the desired effect is not impaired. Examples of the substituent include a halogen atom, hydroxy group, mercapto group, cyano group, nitro group, and a monovalent organic group. Examples of the halogen atom as the substituent include fluorine atom, chlorine atom, bromine atom, and iodine atom. Examples of the monovalent organic group include an alkyl group, an alkoxy group, an alkoxyalkyl group, an aliphatic acryl group, an aliphatic acyloxy group, an alkoxycarbonyl group, an alkylthio group, an aliphatic acylthio group, and the like. In addition, the radically polymerizable group-containing group is preferred as the monovalent organic group.

A number of carbon atoms in the monovalent organic group as the substituent is not particularly limited as long as the desired effect is not impaired. For example, the number of carbon atoms in the monovalent organic group as the substituent is preferably 1 or more and 20 or less, more preferably 1 or more and 12 or less, and further preferably 1 or more and 8 or less. In the alkoxyalkyl group, the aliphatic acyl group, the aliphatic acyloxy group, the alkoxycarbonyl group, the alkoxyalkylthio group, and the aliphatic acylthio group, lower limit of the number of carbon atoms is 2.

Suitable specific examples of the alkyl group as the substituent include methyl group, ethyl group, n-propyl group, isopropyl group, n-butyl group, isobutyl group, sec-butyl group, tert-butyl group, n-pentyl group, n-hexyl group, n-heptyl group, and n-octyl group.

Suitable specific examples of the alkoxy group as the substituent include methoxy group, ethoxy group, n-propyloxy group, isopropyl oxy group, n-butyloxy group, isobutyloxy group, sec-butyloxy group, tert-butyloxy group, n-pentyloxy group, n-hexyloxy group, n-heptyloxy group, and n-octyloxy group.

Suitable specific examples of the alkoxyalkyl group include methoxymethyl group, ethoxymethyl group, n-propyloxymethyl group, n-butyloxymethyl group, 2-methoxyethyl group, 2-ethoxyethyl group, 2-n-propyloxyethyl group, 2-n-butyloxyethyl group, 3-methoxy-n-propyl group, 3-ethoxy-n-propyl group, 3-n-propyloxy-n-propyl group, 3-n-butyloxy-n-propyl group, 4-methoxy-n-bnutyl group, 4-ethoxy-n-butyl group, 4-n-propyloxy-n-butyl group, and 4-n-butyloxy-n-butyl group.

Suitable specific examples of the aliphatic acyl group include acetyl group, propionyl group, butanoyl group, pentanoyl group, hexanoyl group, heptanoyl group, and octanoyl group.

Suitable specific examples of the aliphatic acyloxy group as the substituent include acetoxy group, propionyloxy group, butanoyloxy group, pentanoyloxy group, hexanoyloxy group, heptanoyloxy group, and octanoyloxy group.

Suitable specific examples of the alkoxycarbonyl group as the substituent include methoxycarbonyl group, ethoxycarbonyl group, n-propyloxycarbonyl group, isopropyloxycarbonyl group, n-butyloxycarbonyl group, isobutyloxycarbonyl group, sec-butyloxycarbonyl group, tert-butyloxycarbonyl group, n-pentyloxycarbonyl group, n-hexyloxycarbonyl group, n-heptyloxycarbonyl group, and n-octyloxycarbonyl group.

Suitable specific examples of the alkylthio group as the substituent include methylthio group, ethylthio group, n-propylthio group, isopropylthio group, n-butylthio group, isobutylthio group, sec-butylthio group, tert-butylthio group, n-pentylthio group, n-hexylthio group, n-heptylthio group, and n-octylthio group.

Suitable specific examples of the aliphatic acylthio group as the substituent include acetylthio group, propionylthio group, butanoylthio group, pentanoylthio group, hexanoylthio group, heptanoylthio group, and ocatnoylthio group.

When the quinolinyl group and the isoquinolinyl group have the substituent, a number of the substituent is not particularly limited as long as the desired effect is not impaired. When the quinolinyl group and the isoquinolinyl group have the substituent, the number of the substituent is preferably 1 or more and 4 or less, more preferably 1 or 2, and particularly preferably 1. When the quinolinyl group and the isoquinolinyl group have a plurality of the substituents, the plurality of the substituents may be different from each other.

The 2-substituted benzothiazoly group as R^{A01} has the group represented by —S—R^{A0} at 2-position. The 2-substituted benzothiazoly group as R^{A01} may have other substituent than the group represented by —S—R^{A0} at other position than 2-position. R^{A0} is hydrogen atom or a radically polymerizable group-containing group. The radically polymerizable group-containing group will be described later.

Suitable examples of the 2-substituted benzothiazolyl group include the following group.

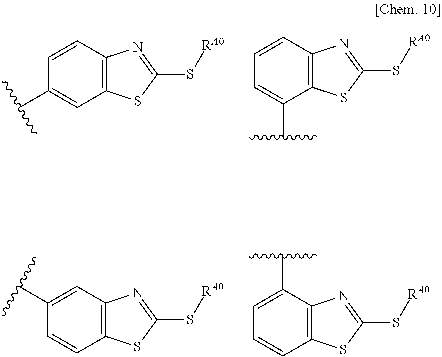

The substituent which the 2-substituted benzothiazolyl group as R^{A01} may have is the same as the substituent which the quinolinyl group and the isoquinolinyl group may have. When the 2-substituted benzothiazolyl group has the substituent, a number of the substituent is not particularly limited as long as the desired effect is not impaired. When the 2-substituted benzothiazolyl group has the substituent, the number of the substituent is preferably 1 or 2, and more preferably 1. When the 2-substituted benzothiazolyl group has a plurality of the substituents, the plurality of the substituents may be different from each other.

Both of R^{A02} and R^{A03} are aromatic ring-containing group having the radically polymerizable group-containing group. It should be noted that —NH— group bonding to triazine ring bonds to the aromatic rings in R^{A02} and R^{A03}. In the aromatic ring-containing group as R^{A02} and R^{A03}, a position to which the radically polymerizable group bonds is not particularly limited.

A number of the radically polymerizable group in the aromatic ring-containing group as R^{A02} and a number of the radically polymerizable group in the aromatic ring-containing group as R^{A03} are not particularly limited. The number of the radically polymerizable group-containing group in the aromatic ring-containing group as R^{A02}, and the number of the radically polymerizable group-containing group in the aromatic ring-containing group as R^{A03} are preferably an integer of 1 or more and 3 or less, more preferably 1 or 2, and particularly preferably 1.

The aromatic ring-containing group as R^{A02} and R^{A03} may include only one monocyclic aromatic ring or only one condensed aromatic ring, or two or more of monocyclic aromatic ring(s) and/or condensed aromatic ring. When the aromatic ring-containing group as R^{A02} and R^{A03} includes two or more of monocyclic aromatic rings and/or condensed aromatic rings, a type of bridging group which bridges monocyclic aromatic rings, condensed aromatic rings, or monocyclic aromatic ring and condensed aromatic ring. The bridging group may be a divalent bridging group or a trivalent bridging group, and is preferably a divalent bridging group.

Examples of the divalent bridging group include a divalent aliphatic hydrocarbon group, a divalent halogenated aliphatic hydrocarbon group, —CONH—, —NH—, —N═N—, —CH═N—, —COO—, —O—, —CO—, —SO—, —SO₂—, —S—, and —S—S—, and a combination of two or more of these.

In addition, a group represented by —CR^{a001}R^{a002}— is preferred as the divalent bridging group. R^{a001} and R^{a002} are each independently a hydrogen atom, an alkyl group having 1 or more and 4 or less carbon atoms, or a halogenated alkyl group having 1 or more and 4 or less carbon atoms. R^{a001} and R^{a002} may be combined with each other to form a ring. Specific examples of the group represented by —CR^{a001}R^{a002}— include methylene group, ethane-1,2-diyl group, propane-2,2-diyl group, butane-2,2-diyl group, 1,1,1,3,3,3-hexafluoropropane-2,2-diyl group, cyclopentylidene group, cyclohexylidene group, and cycloheptylidene group.

The aromatic ring containing-group as R^{A02} and R^{A03} has the radically polymerizable group-containing group. The radically polymerizable group-containing group is as described above.

Suitable examples of the radically polymerizable group-containing group include a group represented by the following formula (A-I) or the following formula (A-II) and not corresponding to vinyloxy group.

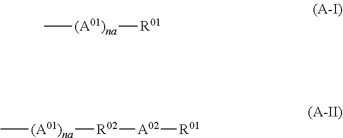

In the formula (A-I) and the formula (A-II), R01 is an alkenyl group having 2 or more and 10 or less carbon atoms. R⁰² is an alkylene group having 1 or more and 10 or less carbon atoms. A⁰¹ is —O—, —S—, —CO—, —CO—O—, —CO—S—, —O—CO—, —S—CO—, —CO—NH—, —NH—CO—, or —NH. A⁰² is —O—, —S—, —CO—, —CO—O—, —CO—S—, —O—CO—, —S—CO—, —CO—NH—, —NH—CO—, or —NH. na is 0 or 1.

Suitable specific examples of the radically polymerizable group-containing group include groups represented by
—O—R⁰³,
—S—R⁰³,
—O—CH₂CH₂—O—R⁰³,
—O—CH₂CH₂CH₂—O—R⁰³,
—O—CH₂CH₂CH₂CH₂—O—R⁰³,
—CO—O—CH₂CH₂—O—R⁰³,
—CO—O—CH₂CH₂CH₂—O—R⁰³,
—CO—O—CH₂CH₂CH₂CH₂—O—R⁰³,
—O—CH₂CH₂—NH—R⁰³,
—O—CH₂CH₂CH₂—NH—R⁰³,
—O—CH₂CH₂CH₂CH2-NH—R⁰³,
—CO—O—CH₂CH₂—NH—R⁰³,
—CO—O—CH₂CH₂CH₂—NH—R⁰³,
—CO—O—CH₂CH₂CH₂—CH₂—R⁰³,
—NH—R⁰³,
—NH—CH₂CH₂—O—R⁰³,
—NH—CH₂CH₂CH₂—O—R⁰³,
—NH—CH₂CH₂CH₂CH₂—O—R⁰³,
—CO—NH—CH₂CH₂—O—R⁰³,
—CO—NH—CH₂CH₂CH₂—O—R⁰³,
—CO—NH—CH₂CH₂CH₂CH₂—O—R⁰³,
—NH—CH₂CH₂—NH—R⁰³,
—NH—CH₂CH₂CH₂—NH—R⁰³,
—NH—CH₂CH₂CH₂CH₂—NH—R⁰³,
—CO—NH—CH₂CH₂—NH—R⁰³,
—CO—NH—CH₂CH₂CH₂—NH—R⁰³, and
—CO—NH—CH₂CH₂CH₂CH₂—NH—R⁰³.

R⁰³ in these groups is ally group or (meth)acryloyl group.

When the aromatic ring-containing group as R^{A02} and R^{A03} has one radically polymerizable group-containing group, suitable examples of the R^{A02} and R^{A03} include following groups. In following formulas, PG is the radically polymerizable group-containing group.

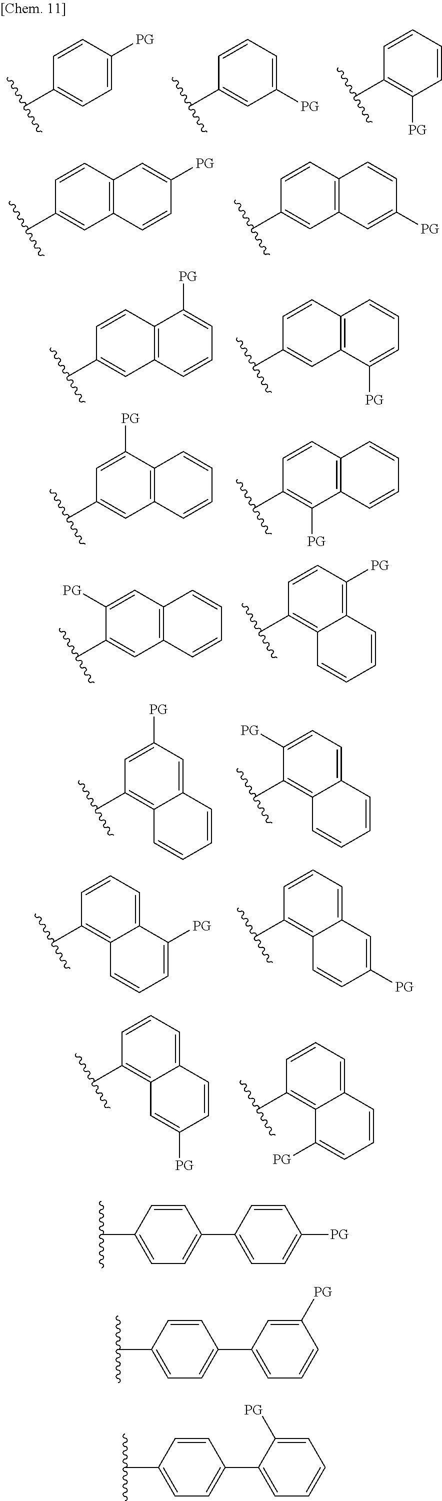

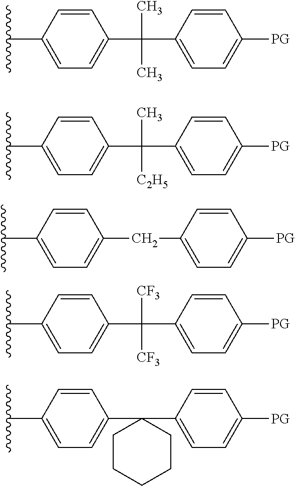

Suitable specific examples of the compound represented by the formula (A-2f) include the following compounds. In following formulas, X^{A} is a group selected from a group consisting of (meth)acryloyloxy group, (meth)acryloylthio group, and 3-(meth)acryloyloxy-2-hydroxy-n-propyloxycarbonyl group.

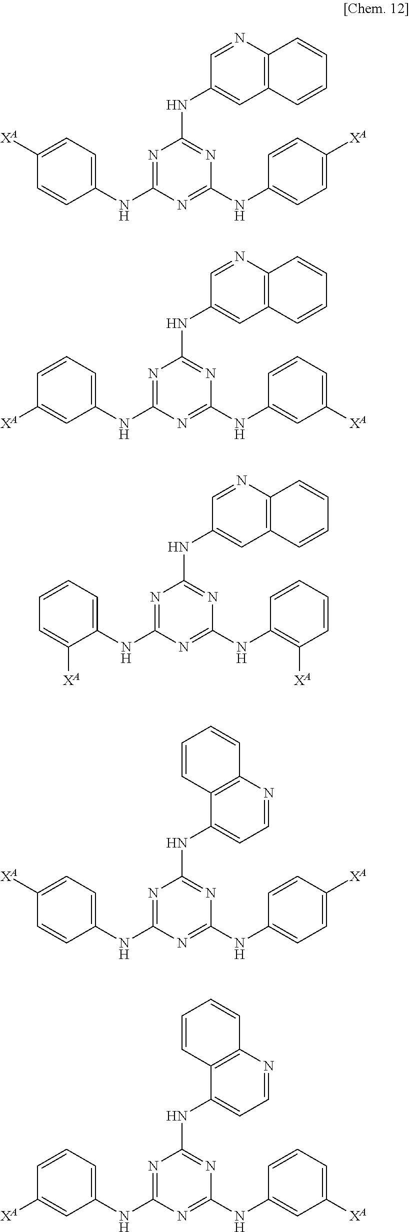

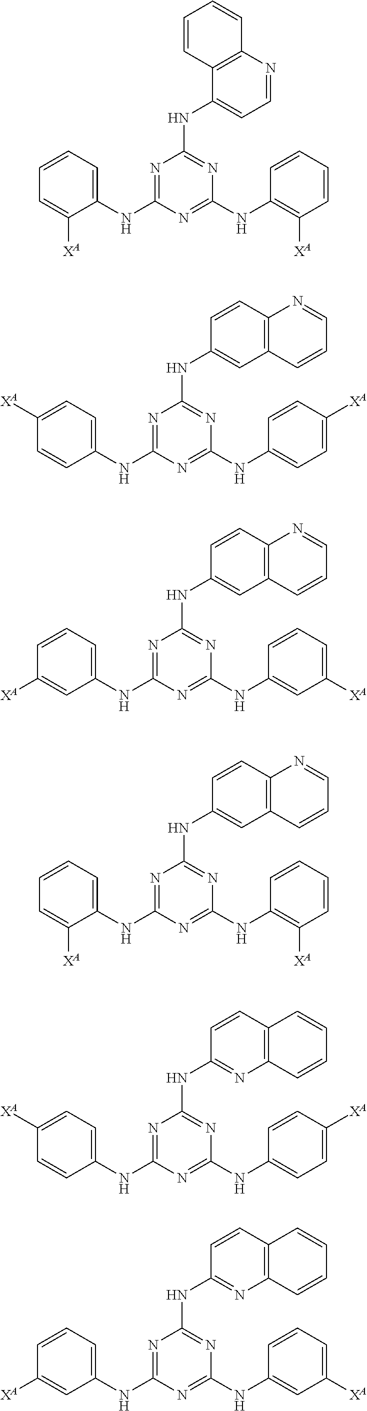

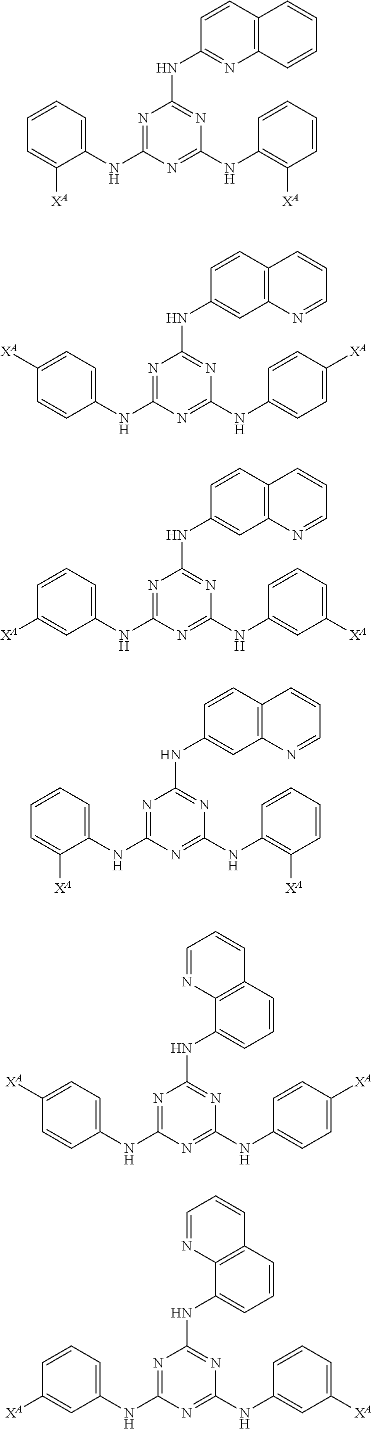

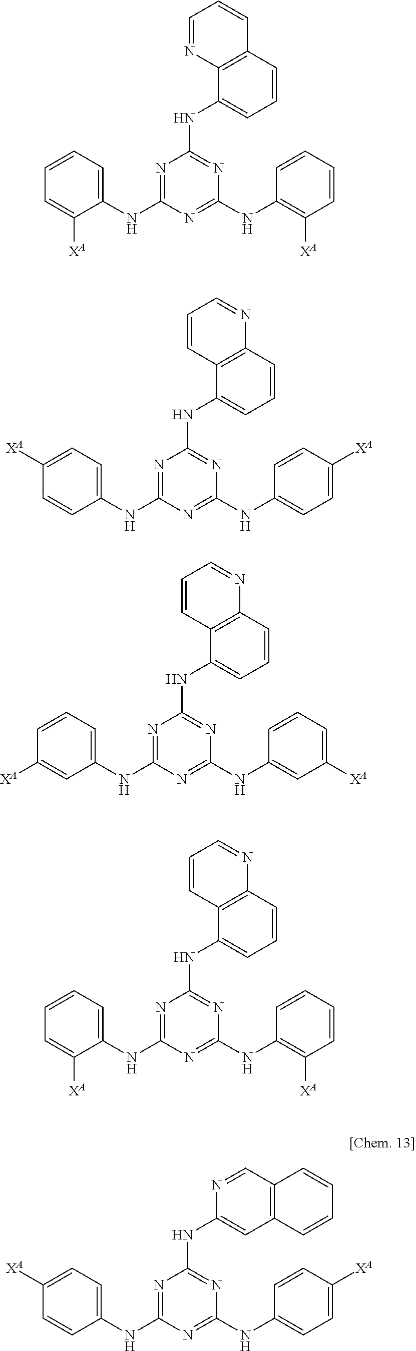

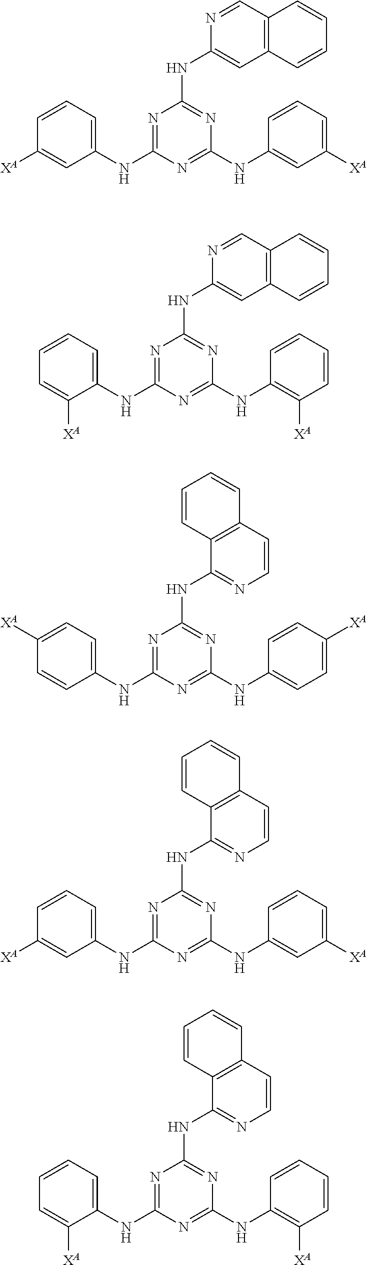

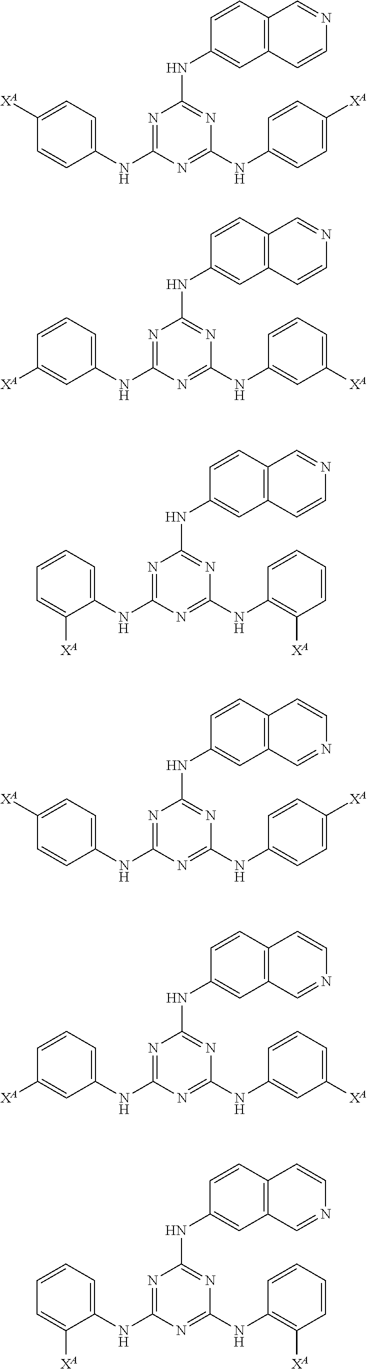

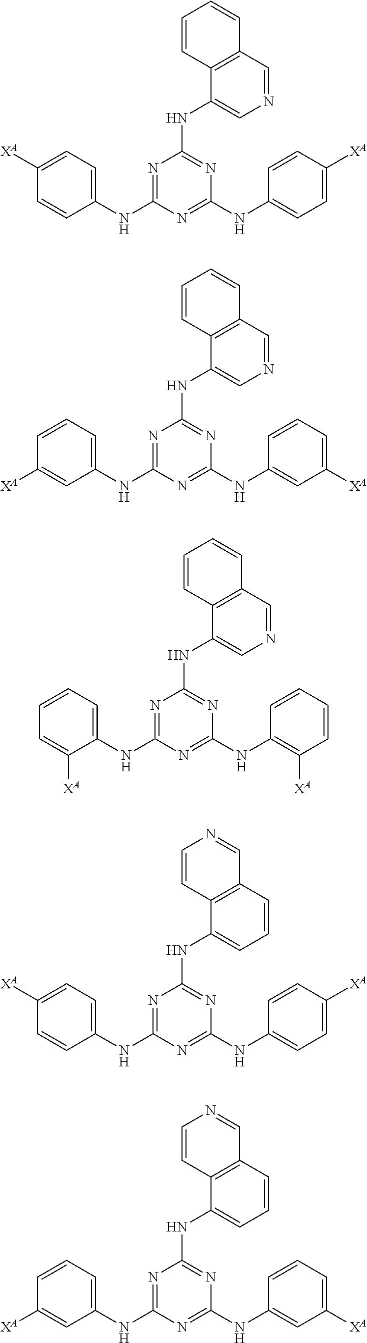

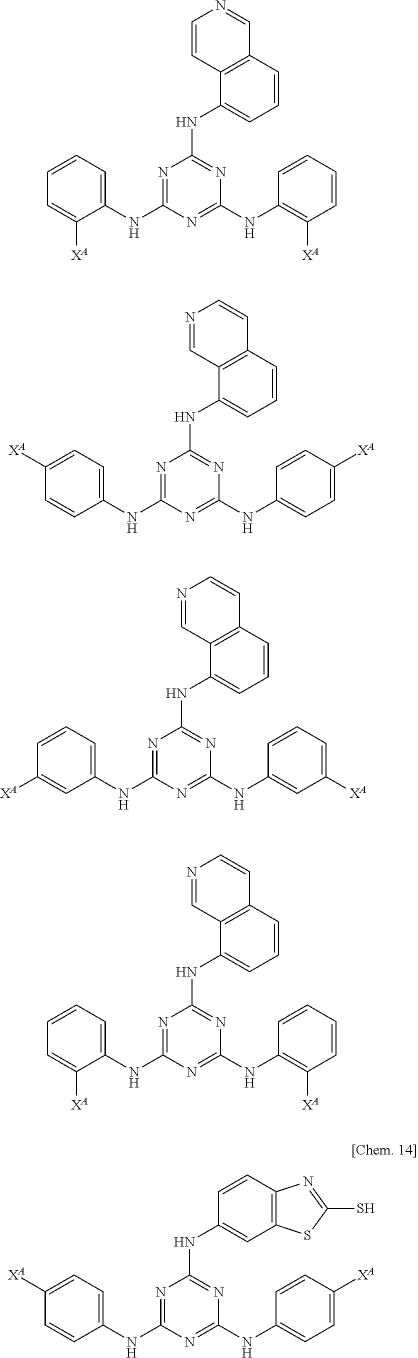

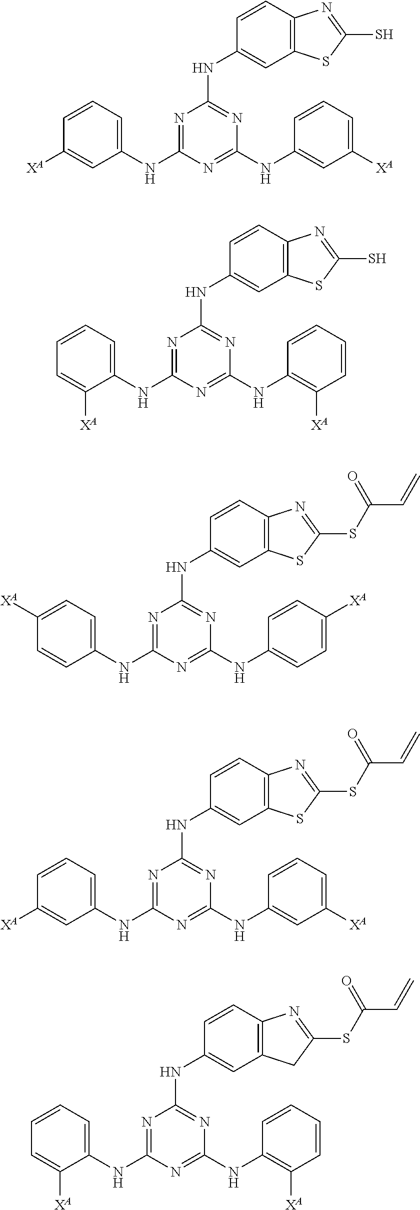

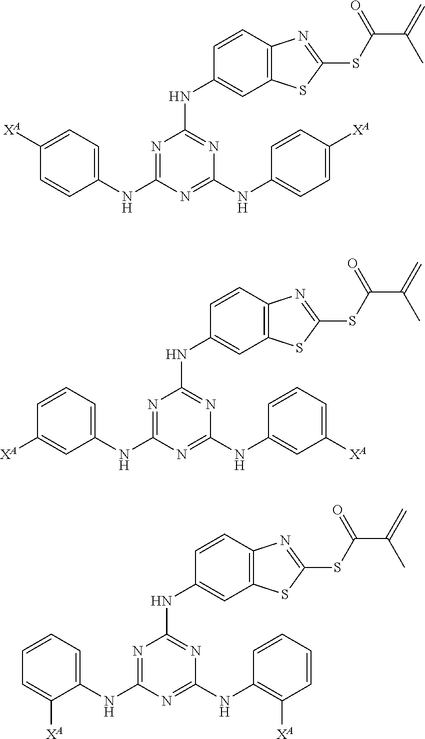

A production method of the compound represented by the formula (A-2f-a) is not particularly limited. Typically, the compound represented by the formula (A-2e-a) can be prepared by reacting cyanuric halide such as cyanuric chloride with aromatic amines represented by R^{A01}—NH₂, R^{A02}—NH₂, and R^{A03}—NH₂. These multiple amines may react with the cyanuric halide simultaneously or sequentially, and preferably sequentially react with the cyanuric halide.

In addition, R^{A02} and R^{A03} in the formula (A-2f-a) can be formed by reacting the cyanuric halide with aromatic amine having a functional group such as hydroxy group, mercapto group, carboxy group, and amino group, and thereafter reacting these functional groups with a compound which gives the radically polymerizable group-containing group. Examples of the compound which gives the radically polymerizable group-containing group includes (meth)acrylic acid, (meth)acrylic acid halide, halogenated olefin, and the like. As a reaction of the functional group such as hydroxy group, mercapto group, carboxy group, and amino group with a compound having a polymerizable group, well-known reaction forming an ether bond, a carboxylic acid ester bond, a carboxylic amid bond, or a thioether bond can be used.

A reaction forming the radically polymerizable group-containing group may be a multi-step reaction. For example, a radically polymerizable group represented by the following formula can be introduced on an aromatic ring by glycidylizing a phenolic hydroxy group by reaction with epichlorohydrin after reacting cyanuric halide with an aromatic amine having phenolic hydroxy group, subsequently, reacting the glycidyl group with acrylic acid.

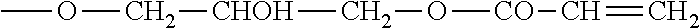

The above reaction is an example, and the radically polymerizable group-containing group can be formed by carrying out various reactions in combination.

The compound represented by the formula (A-2f-a) is usually synthesized in an organic solvent. This organic solvent is not particularly limited as long as the solvent is an inactive solvent which does not react with cyanuric halide, aromatic amine, radically polymerizable group, and the like. As the solvent, solvents exemplified as specific examples of the solvent (S) described below can be used. In the production of the compound represented by the formula (A-2f-a), reaction temperature is not particularly limited when cyanuric halide is reacted with aromatic amines such as aromatic amines represented by R^{A01}—NH₂, R^{A02}—NH₂, and R^{A03}—NH₂. Typically, reaction temperature is preferably 0° C. or higher and 150° C. or lower.

Other suitable examples of the compound represented by the formula (A-2f) include a compound represented by the following formula (A-2f-b).

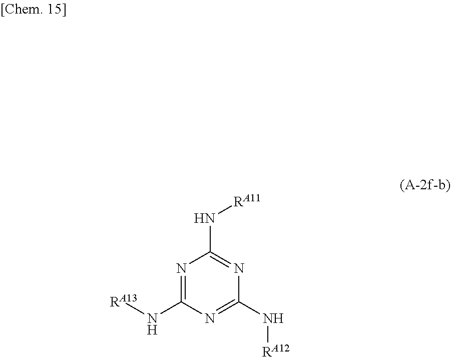

In the formula (A-2f-b), each of R^{A11}, R^{A12}, and R^{A13} is the aromatic ring-containing group. At least one of R^{A12} and R^{A13} is a group represented by following formula (A-2f-b1).

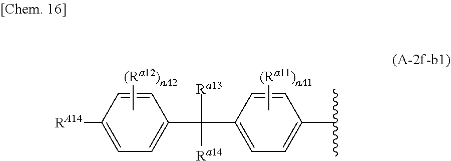

Each of the —NH— groups bonding to the triazine ring bonds to the aromatic ring in R^{A11}, R^{A12}; and R^{A13}. In the formula (A-2f-b1), R^{a11}, and R^{a12} are each independently an alkyl group having 1 or more and 4 or less carbon atoms, an alkoxy group having 1 or more and 4 or less carbon atoms, or a halogen atom.

nA1 and nA2 are each independently an integer of 0 or more and 4 or less. R^{a13} and R^{a14} are each independently an alkyl group having 1 or more and 4 or less carbon atoms, a halogenated alkyl group having 1 or more and 4 or less carbon atoms, or phenyl group. R^{A14} and R^{a14} may be combined with each other to form a ring. R^{A14} is the radically polymerizable group-containing group. When both of R^{A12} and R^{A13} are the group represented by the formula (A-2f-b1), both of R^{A12} and R^{A13} have the radically polymerizable group-containing group.

As described above, in the formula (A-2f-b), each of Rail, R^{A12}, and R^{A13} is the aromatic ring-containing group. Each of —NH— groups bonding to the triazine ring in the formula (A-2f-b) bonds to the aromatic ring in R^{A11}, R^{A12}, and R^{A13}. When the aromatic ring-containing group is a group other than the group represented by the formula (A-2f-b1), the aromatic ring-containing group is not particularly limited as long as the above specific requirements are met.

The aromatic ring-containing group other than the group represented by the formula (A-2f-b1) may have only one monocyclic aromatic ring or one condensed aromatic ring, or may have two or more of monocyclic aromatic ring and/or condensed aromatic ring. When the aromatic ring-containing group includes two or more of monocyclic aromatic rings and/or condensed aromatic rings, a type of bridging group which bridges monocyclic aromatic rings, condensed aromatic rings, or monocyclic aromatic ring and condensed aromatic ring. The bridging group may be a divalent bridging group or a trivalent bridging group, and is preferably a divalent bridging group.

Examples of the divalent bridging group include a divalent aliphatic hydrocarbon group, a divalent halogenated aliphatic hydrocarbon group, —CONH—, —NH—, —N═N—, —CH—N—, —COO—, —O—, —CO—, —SO—, —SO₂—, —S—, and —S—S—, and a combination of two or more of these.

Suitable examples of the aromatic ring-containing group include an optionally substituted quinolinyl group, an optionally substituted isoquinolinyl group, and an optionally substituted 2-substituted benzothiazolyl group. These groups are the same as the optionally substituted quinolinyl group, the optionally substituted isoquinolinyl group, and the optionally substituted 2-substituted benzothiazolyl group described for R^{A01} in the formula (A-2f-a).

Other suitable examples of the aromatic ring-containing group include an optionally substituted phenyl group, an optionally substituted naphthyl group, an optionally substituted biphenylyl group, an optionally substituted phenylthiophenyl group, an optionally substituted phenoxyphenyl group, an optionally substituted phenylsulfonylphenyl group, an optionally substituted benzothiazolyl group, an optionally substituted benzoxazolyl group, and an optionally substituted terphenyl group. When these groups have substituent, the substituent is the same as the substituent which the quinolinyl group and the isoquinolinyl group may have. When these groups have a plurality of the substituents, the plurality of the substituents may be different from each other.

Suitable specific examples of the optionally substituted phenyl group include phenyl group, 4-cyanophenyl group, 3-cyanophenyl group, 2-cyanophenyl group, 2,3-dicyanophenyl group, 2,4-dicyanophenyl group, 2,5-dicyanophenyl group, 2,6-dicyanophenyl group, 3,4-dicyanophenyl group, 3,5-dicyanopohenyl group, 4-nitrophenyl group, 3-nitrophenyl group, 2-nitrophenyl group, 4-chlorophenyl group, 3-chlorophenyl group, 2-chlorophenyl group, 4-bromophenyl group, 3-bromophenyl group, 2-bromophenyl group, 4-iodophenyl group, 3-iodophenyl group, 2-iodophenyl group, 4-methoxyphenyl group, 3-methoxyphenyl group, 2-methoxyphenyl group, 4-methylphenyl group, 3-methylphenyl group, and 2-methylphenyl group.

Suitable specific examples of the optionally substituted naphthyl group include naphthalen-1-yl group, and naphthalen-2-yl group

Suitable examples of the optionally substituted biphenylyl group include 4-phenylphenyl group, 3-phenylphenyl group, 2-phenylphenyl group, 4-(4-nitrophenyl)phenyl group, 3-(4-nitrophenyl)phenyl group, 2-(4-nitrophenyl)phenyl group, 4-(4-cyanophenyl)phenyl group, 3-(4-cyanophenyl)phenyl group, and 2-(4-cyanophenyl)phenyl group.

Suitable specific examples of the optionally substituted phenylthiophenyl group include 4-phenylthiophenyl group, 3-phenylthiophenyl group, and 2-phenylthiophenyl group.

Suitable specific examples of the optionally substituted phenoxyphenyl group include 4-phenoxyphenyl group, 3-phenoxyphenyl group, and 2-phenoxyphenyl group.

Suitable specific examples of the optionally substituted phenylsulfonylphenyl group include 4-phenylsulfonylphenyl group, 3-phenylsulfonylphenyl group, and 2-phenylsulfonylphenyl group.

Suitable specific examples of the optionally substituted benzothiazolyl group include benzothiazol-2-yl group, benzothiazol-4-yl group, benzothiazol-5-yl group, benzothiazol-6-yl group, and benzothiazol-7-yl group.

Suitable specific examples of the optionally substituted benzoxazolyl group include benzoxazol-2-yl group, benzoxazol-4-yl group, benzoxazol-5-yl group, benzoxazol-6-yl group, and benzoxazol-7-yl group.

Suitable examples of the optionally substituted terphenyl group include 4-(4-phenylphenyl)phenyl group, 3-(4-phenylphenyl)phenyl group, 2-(4-phenylphenyl)phenyl group, 4-(3-phenylphenyl)phenyl group, 3-(3-phenylphenyl)phenyl group, 2-(3-phenylphenyl)phenyl group, 4-(2-phenylphenyl)phenyl group, 3-(2-phenylphenyl)phenyl group, and 2-(2-phenylphenyl)phenyl group.

As described above, the aromatic ring-containing group other than the group represented by the formula (A-2f-b1) may have the radically polymerizable group-containing group as substituent. In the aromatic ring-containing group, a position to which the radically polymerizable group-containing group bonds is not particularly limited.

A number of the radically polymerizable group-containing group is not particularly limited. The number of the radically polymerizable group-containing group in the aromatic group-containing group is preferably an integer of 1 or more and 3 or less, more preferably 1 or 2, and particularly preferably 1.

When the aromatic ring-containing group has the one radically polymerizable group-containing group, suitable examples of such group include following groups. In following formulas, PG is the radically polymerizable group-containing group.

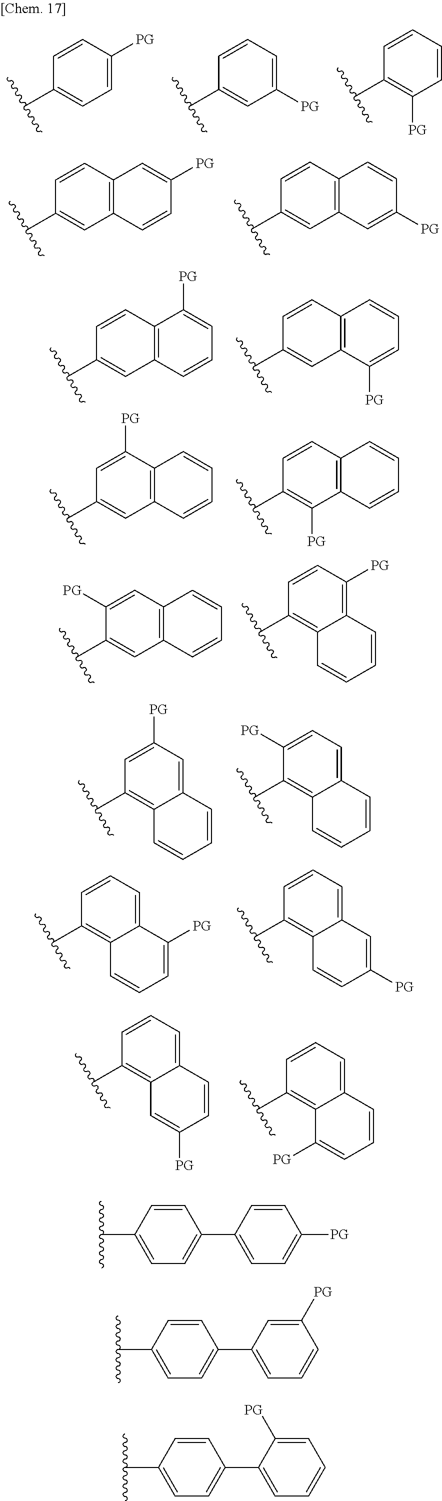

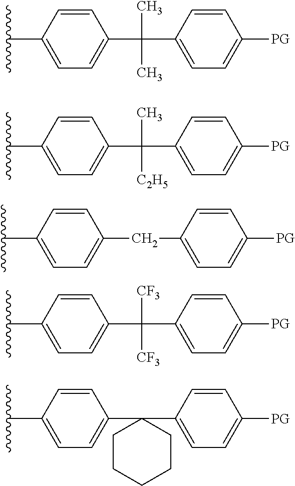

In the formula (A-2f-b), at least one of R^{A12} and R^{A13} is a group represented by following formula (A-2f-b1).

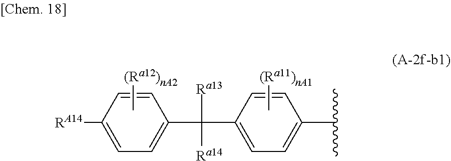

In the formula (A-2f-b1), R^{a11} and R^{a12} are each independently an alkyl group having 1 or more and 4 or less carbon atoms, an alkoxy group having 1 or more and 4 or less carbon atoms, or a halogen atom. nA1 and nA2 are each independently an integer of 0 or more and 4 or less. R^{a13} and R^{a14} are each independently an alkyl group having 1 or more and 4 or less carbon atoms, a halogenated alkyl group having 1 or more and 4 or less carbon atoms, or phenyl group. R^{a13} and R^{a14} may be combined with each other to form a ring. R^{A14} is the radically polymerizable group-containing group. When both of R^{A12} and R^{A13} are the group represented by the formula (A-2f-b1), both of R^{A12} and R^{A13} have the radically polymerizable group-containing group.

Examples of the alkyl group having 1 or more and 4 or less carbon atoms as R^{a11} and R^{a12} include methyl group, ethyl group, n-propyl group, isopropyl group, n-butyl group, isobutyl group, sec-butyl group, and tert-butyl group. Examples of the alkoxy group having 1 or more and 4 or less carbon atoms as R^{a11} and R^{a12} include methoxy group, ethoxy group, n-propyloxy group, isopropyloxy group, n-butyloxy group, isobutyloxy group, sec-butyloxy group, and tert-butyloxy group. Examples of the halogen atom as R^{a1} and R¹² include fluorine atom, chlorine atom, bromine atom, and iodine atom.

Specific examples of the alkyl group having 1 or more and 4 or less carbon atoms as R^{a13} and R^{a14} are the same as the specific examples of the alkyl group having 1 or more and 4 or less carbon atoms as R^{a11} and R^{a12}. Specific examples of the halogenated alkyl group having 1 or more and 4 or less carbon atoms as R^{a13} and R^{a14} include chloromethyl group, dichloromethyl group, trichloromethyl group, bromomethyl group, dibromomethyl group, tribromomethyl group, fluoromethyl group, difluoromethyl group, trifulurormethyl group, 3,3,3-trifluoroethyl group, pentafluoroethyl group, heptafluoropropyl group, and the like.

Suitable examples of the group represented by the formula (A-2f-b1) include the compounds represented by following formulas.

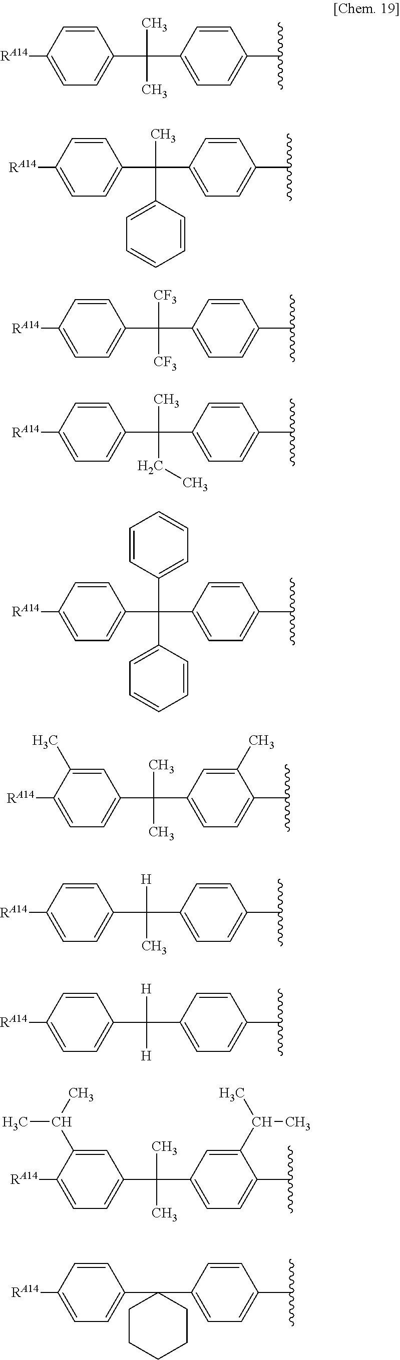

The group represented by the formula (A-2f-b1) has the radically polymerizable group-containing group as R^{A14}. The radically polymerizable group-containing group is as described above. Suitable specific examples of the radically polymerizable group-containing group is the same as the suitable specific examples of the radically polymerizable group-containing group described for the compound represented by the formula (A-2f-a).

Suitable specific examples of the compound represented by the formula (A-2f-b) include the following compounds. In following formulas, X^{A} is a group selected from a group consisting of (meth)acryloyloxy group, (meth)acryloylthio group, 3-(meth)acryloyloxy-2-hydroxy-n-propyloxycarbonyl group and glycidyloxy group. Y^{A} is a group selected from the group consisting of quinolin-3-yl group, phenyl group, 4-cyanophenyl group, 3-cyanophenyl group, 2-cyanophenyl group, 3,4-dicyanophenyl group, 4-nitrophenyl group, 4-methoxyphenyl group, 4-phenylthiophenyl group, 4-phenylsulfonylphenyl, 4-iodophenyl group, benzothiazol-2-yl group, 2-mercaptobenzothiazol-5-yl group, 4-phenylphenyl group, 4-(4-nitrophenyl)phenyl group, 4-(4-cyanophenyl)phenyl group, naphthalen-1-yl group, and 4-(4-phenylphenyl)phenyl group.

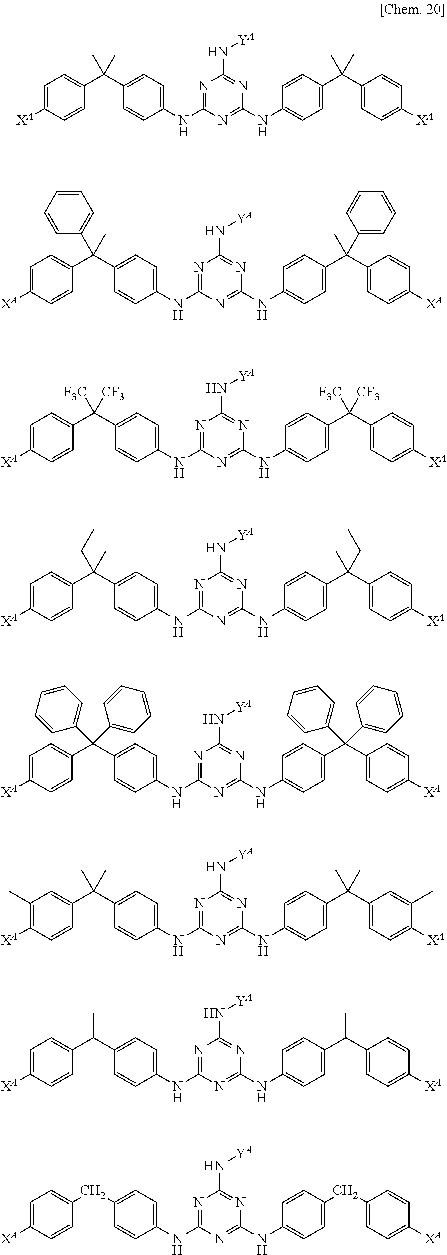

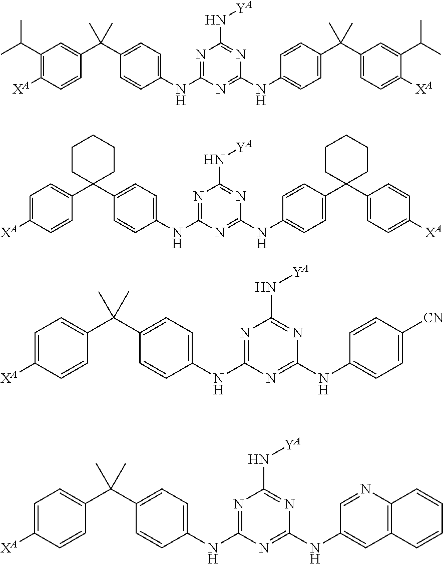

Production method of the compound represented by the formula (A-2f-b) is not particularly limited. Typically, the compound represented by the formula (A-2e-b) can be prepared by reacting cyanuric halide such as cyanuric chloride with aromatic amines represented by R^{A11}—NH₂, R^{A12}—NH₂, and R^{A13}—NH². These multiple amines may react with the cyanuric halide simultaneously or sequentially, and preferably sequentially react with the cyanuric halide.

In addition, when the aromatic ring-containing group bonding to the triazine ring via —NH— has the radically polymerizable group-containing group, an aromatic amine having a functional group such as hydroxy group, mercapto group, carboxy group and amino group is reacted with the cyanuric halide. Thereafter, by reacting these functional groups with a compound which gives the radically polymerizable group-containing group, the radically polymerizable group-containing group can be formed. Examples of the compound which gives the radically polymerizable group-containing group includes (meth)acrylic acid, (meth)acrylic acid halide, halogenated olefin, and the like. As a reaction of the functional group such as hydroxy group, mercapto group, carboxy group, and amino group with a compound having a polymerizable group, well-known reaction forming an ether bond, a carboxylic acid ester bond, a carboxylic amid bond, or a thioether bond can be used.

A reaction forming the radically polymerizable group-containing group may be a multi-step reaction. For example, a cyanuric halide is reacted with an aromatic amine having phenolic hydroxy group. Thereafter, phenolic hydroxy group is glycidylized by reaction with epichlorohydrin. Subsequently, radically polymerizable group-containing group represented by following formula can be introduced on an aromatic ring by reacting glycidyl group with acrylic acid.

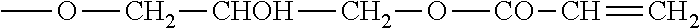

The above reaction is an example, and the radically polymerizable group-containing group can be formed by carrying out various reactions in combination.

The compound represented by the formula (A-2f-b) is usually synthesized in an organic solvent. This organic solvent is not particularly limited as long as the solvent is an inactive solvent which does not react with cyanuric halide, aromatic amine, radically polymerizable group, and the like. Organic solvents exemplified for specific examples of the solvent (S), and the like can be used as the solvent. In the production of the compound represented by the formula (A-2f-b), reaction temperature is not particularly limited when cyanuric halide is reacted with aromatic amines such as aromatic amines represented by R^{A11}—NH₂, R^{A12}—NH₂, and R^{A13}—NH₂. Typically, reaction temperature is preferably 0° C. or higher and 150° C. or lower.

A content of the photopolymerizable compound (A) in the composition is not particularly limited as long as the desired effects are not impaired. When a mass of the composition excluding a mass of the solvent (S) described below is 100 parts by mass, an amount of the photopolymerizable compound (A) included in the composition is preferably 0.1 parts by mass or more and 50 parts by mass or less, more preferably 0.5 parts by mass or more and 40 parts by mass or less, and particularly preferably 1 part by mass or more and 25 parts by mass or less.

### <Metal Oxide Particles (B)>

The composition includes metal oxide particles (B). When the composition includes the metal oxide particles (B), a cured product with high refractive index can be easily formed by using the composition. Type of metal oxide constituting the metal oxide particles (B) is not particularly limited as long as the desired effect is not impaired. Suitable examples of the metal oxide particles (B) include at least one selected from the group consisting of zirconium dioxide particles, titanium dioxide particles, barium titanate particles, cerium dioxide particles, and niobium pentoxide particles. Among these, in view of easy formation of the cured product with high refractive index, at least one selected from the group consisting of titanium dioxide particles, zirconium dioxide particles, and niobium pentoxide particles is preferred.

In view of transparency of the material formed by using the composition, and stable dispersibility of the metal oxide particles (B) in the composition, average particle size of the metal oxide particles (B) is preferably 500 nm or more, and more preferably 2 nm or more and 100 nm or less.

For the metal oxide particles (B), surfaces thereof are preferably modified with an ethylenically unsaturated double bond. Since agglomeration of the metal oxide particles (B) is less likely to occur, it is preferred that the surfaces of the metal oxide particles (B) are modified with the ethylenically unsaturated double bond

For example, the metal oxide particles (B) in which the surfaces thereof are modified with the ethylenically unsaturated double bond can be obtained by reacting a capping agent including ethylenically unsaturated double bond to the surfaces of the metal oxide particles (B).

A method of binding the capping agent including the ethylenically unsaturated double bond to the surface of the metal oxide particles (B) via a chemical bond such as a covalent bond is not particularly limited. Hydroxy groups usually exist on the surface of the metal oxide particles (B). By reacting hydroxy groups and the reactive groups possessed by the capping agent, the caping agent covalently bonds to the surfaces of the metal oxide particles (B). Suitable examples of the reactive group possessed by the capping agent include a trialkoxysilyl group such as trimethoxysilyl group and triethoxysilyl group; a dialkoxysilyl group such as dimethoxysilyl group and diethoxysilyl group; a monoalkoxysilyl group such as monomethoxysilyl group and monoethoxysilyl group; a trihalosilyl group such as trichlorosilyl group; a dihalosilyl group such as dichlorosilyl group; a monohalosilyl group such as monochlorosilyl group; carboxy group; a halocarbonyl group such as chlorocarbonyl group; hydroxy group; phosphono group (—P(═O)(OH)₂); phosphate group (—O—P(═O)(OH)₂).

The trialkoxysilyl group, the dialkoxysilyl group, the monoalkoxysilyl group, the trihalosilyl group, the dihalosilyl group, and the monohalosilyl group can form siloxane bond with the surfaces of the metal oxide particles (B). Carboxy group and the halocarbonyl group can form a bond represented by (metal oxide-O—CO—) with the surfaces of the metal oxide particles (B). Hydroxy group can form a bond represented by (metal oxide-O—) with the surfaces of the metal oxide particles (B). Phosphono group and phosphate group can form a bond represented by (metal oxide-O—P(═O)<) with the surfaces of the metal oxide particles (B).

In the capping agent, hydrogen atom and various organic group are exemplified as a group binding to the above reactive group. The organic group may include a hetero atom such ah O, N, S, P, B, Si, and a halogen atom. As a group bonding to the above reactive group, for example, an alkyl group that may be straight or branched, and may be interrupted by oxygen atom (—O—), an alkenyl group that may be straight or branched, and may be interrupted by oxygen atom (—O—), an alkynyl group that may be straight or branched, and may be interrupted by oxygen atom (—O—),

A cycloalkyl group, an aromatic hydrocarbon group, heterocyclic group, and the like are exemplified. These groups may be substituted with a substituent such as halogen atom, an epoxy group-containing group (e.g. glycidyl group), hydroxy group, amino group, (meth)acrylic group, and isocyanate group. In addition, a number of substituents is not particularly limited.

As a group bonding to the above-described reactive group, a group represented by —(SiR^{b1}R^{b2}—O—)ᵣ—SiR^{b3}R^{b4}—O—ₛ—R^{b5} is also preferred. R^{b1}, R^{b2}, R^{b3}, and R^{b4} each may be the same or different, and an organic group. Suitable examples of the organic group include an alkyl group such as methyl group and ethyl group; an alkenyl group such as vinyl group and allyl group; an aromatic hydrocarbon group such as phenyl group, naphthyl group, and tolyl group; an epoxy group-containing group such as 3-glycidoxypropy group; (meth)acryloyloxy group and the like. As R^{b5} in the above formula, for example, a terminal group such as —Si(CH₃)₃, —Si(CH₃)₂H, —Si(CH₃)₂(CH═CH₂), and —Si(CH₃)₂(CH₂CH₂CH₂CH₃) is exemplified.

r and s in the above formula are each independently an integer of 0 or more and 60 or less. Both r and s in the above formula are never zero.

Suitable specific examples of the capping agent include unsaturated group-containing alkoxysilanes such as vinyltrimethoxysilane, vinyltriethoxysilane, allyltrimethoxysilane, allyltriethoxysilane, 1-hexenyltrimethoxysilane, 1-hexenyltriethoxysilane, 1-octenyltrimethoxysilane, 1-octenyltriethoxysilane, 3-acryloyloxypropyl(trimethoxy)silane, 3-acryloyloxypropyl(triethoxy)silane, 3-methacryloyloxypropyl(trimethoxy)silane, and 3-methacryloyloxypropyl(triethoxy)silane; unsaturated group-containing alcohols such as 2-hydroxyethyl (meth)acrylate, 3-hydroxypropyl (meth)acrylate, allyl alcohol, ethylene glycol monoallyl ether, propylene glycol monoallyl ether, and 3-allyloxypropanol; (meth)acrylic acid; (meth)acrylic acid halides such as (meth)acrylic acid chloride.

When the capping agent is bonded to the surface of the metal oxide particles (B) via a chemical bond such as a covalent bond, an amount of the capping agent is not particularly limited. The capping agent is preferably used in a sufficient amount of to react with almost all hydroxy groups on the surface of the metal oxide particles (B).

A content of the metal oxide particles (B) in the composition is not particularly limited as long as it does not interfere with the object of the present invention. The content of the metal oxide particles (B) in the composition is preferably 5% by mass or more and 95% by mass or less, more preferably 35% by mass or more and 93% by mass or less, and further preferably 40% by mass or more and 90% by mass or less relative to a mass of the composition excluding a mass of the solvent (S). When the content of the metal oxide particles (B) in the composition is within the above range, the composition in which the metal oxide particles (B) are stably dispersed is easily obtained. In addition, the cured product can be easily formed by using the composition. In view of easy formation of the material with particularly high refractive index, a content of the metal oxide particles (B) in the composition is preferably 70% by mass or more relative to the mass of the composition excluding a mass of the solvent (S). The content of the metal oxide particles (B) in the composition may be 75% by mass or more and 98% by mass or less, or 80% by mass or more and 95% by mass or less relative to the mass of the composition excluding a mass of the solvent (S). When the surfaces of the metal oxide microparticles (B1) are modified with the ethylenically unsaturated double bond-containing group, a mass of the capping agent existing on the surfaces of the metal oxide microparticles (B1) and having the ethylenically unsaturated double bond-containing group is included in a mass of the metal oxide microparticles (B1).

### <Plasticizer (D)>

The composition may include a plasticizer (D). The plasticizer (D) is a component which lowers viscosity of the composition without significantly compromising various properties such as high refractive index of the material formed by using the composition.

The plasticizer (D) is preferably a compound represented by following formula (d-1).

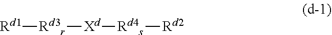

R^{d1} and R^{d2} in the formula (d-1) are each independently a phenyl group optionally substituted with 1 or more and 5 or less substituents. The substituent is a group selected from an alkyl group having 1 or more and 4 or less carbon atoms, an alkoxy group having 1 or more and 4 or less carbon atoms, and a halogen atom. R^{d3} and R^{d4} are each independently methylene group or ethane-1,2-diyl group. r and s are each independently 0 or 1. X^{d} is oxygen atom or sulfur atom.

By inclusion of the plasticizer (D) in the composition, viscosity of the composition is lowered without significantly compromising various properties such as high refractive index of the material formed by using the composition. From the viewpoint of lowering the viscosity of the composition, the viscosity of the plasticizer (D) measured by an E-type viscometer at 25° C. is preferably 10 cP or less, more preferably 8 cP or less, and further preferably 6 cP or less. From the viewpoint that the plasticizer (D) is less likely to volatilize and an effect of lowering the viscosity of the composition can be easily maintained, the boiling point of the plasticizer (D) under atmospheric pressure is preferably 250° C. or higher, and more preferably 260° C. or higher. Upper limit of the boiling point under atmospheric pressure of the plasticizer (D) is not particularly limited, and may be 300° C. or higher, or 350° C. or higher, for example.

R^{d1} and R^{d2} in the formula (d-1) are each independently a phenyl group optionally substituted with 1 or more and 5 or less substituents. The substituent bonding to the phenyl group is a group selected from an alkyl group having 1 or more and 4 or less carbon atoms, an alkoxy group having 1 or more and 4 or less carbon atoms, and a halogen atom. When the phenyl group has the substituent, a number of substituents is not particularly limited. The number of substituents is 1 or more and 5 or less, preferably 1 or 2, and preferably 1 Since the viscosity of the composition is low, R^{d1} and R^{d2} are respectively preferably unsubstituted phenyl group.

Examples of the alkyl group having 1 or more and 4 or less carbon atoms as the substituent include methyl group, ethyl group, n-propyl group, isopropyl group, n-butyl group, isobutyl group, sec-butyl group, and tert-butyl group. Examples of the alkoxy group having 1 or more and 4 or less carbon atoms as the substituent include methoxy group, ethoxy group, n-propyloxy group, isopropyloxy group, n-butyloxy group, isobutyloxy group, sec-butyloxy group, and tert-butyloxy group. Examples of the halogen atom as the substituent include fluorine atom, chlorine atom, bromine atom, and iodine atom.

R^{d3} and R^{d4} in the formula (d-1) are each independently methylene group or ethane-1,2-diyl group. In addition, r and s are each independently 0 or 1. X^{d} in the formula (d-1) is oxygen atom or sulfur atom.

Suitable specific examples of the compound represented by the formula (d-1) described above include diphenyl ether, diphenyl sulfide, dibenzyl ether, dibenzyl sulfide, diphenethyl ether, and diphenethyl sulfide. Among these, diphenyl sulfide and/or dibenzyl ether are preferred.

From the viewpoint of both adjustment of viscosity and dispersibility of the metal oxide particles (B), a content of the plasticizer (D) in the composition is preferably more than 0% by mass and 35% by mass or less, and more preferably 5% by mass or more and 15% by mass or less relative to a mass of the composition.

### <Nitrogen-Containing Compound (E)>

For the purpose of enhancing the curability of the photopolymerizable compound (A) included in the composition, the composition may include an amine compound represented by following formula (e1) and/or an imine compound represented by following formula (e2) as a nitrogen-containing compound (E).

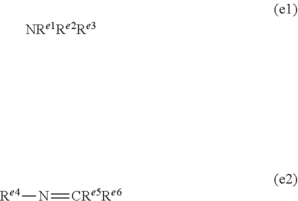

In the formula (e1), R^{e1}, R^{e2}, and R^{e3} are each independently a hydrogen atom or an organic group. In the formula (e2), R^{e4}, R^{e5}, and R^{e6} are each independently hydrogen atom or an organic group.

When R^{e1}, R^{e2}, R^{e3}, R^{e4}, R^{e5}, and R^{e6} in the formula (e1) and the formula (e2) are the organic group, the organic group can be selected from various organic groups as long as the desired effect is not impaired. As the organic group, a carbon atom-containing group is preferred, and a group consisting of one or more carbon atoms, and one or more atoms selected from the group consisting of H, O, S, Se, N, B, P, Si and a halogen atom is more preferred. The number of carbon atoms in the carbon atom-containing group is not particularly limited, and preferably 1 or more and 50 or less, and more preferably 1 or more and 20 or less. Suitable examples of the organic group include an alkyl group, a cycloalkyl group, an optionally substituted phenyl group, an optionally substituted phenylalkyl group, an optionally substituted naphthyl group, an optionally substituted naphthyl alkyl group, an optionally substituted heterocyclyl group, and the like.

A number of carbon atoms in the alkyl group as the organic group is preferably 1 or more and 20 or less, and more preferably 1 or more and 6 or less. Structure of the alkyl group may be straight or branched. Suitable specific examples of the alkyl group include methyl group, ethyl group, n-propyl group, isopropyl group, n-butyl group, isobutyl group, sec-butyl group, tert-butyl group, n-pentyl group, isopentyl group, sec-pentyl group, tert-pentyl group, n-hexyl group, n-heptyl group, n-octyl group, isooctyl group, sec-octyl group, tert-octyl group, n-nonyl group, isononyl group, n-decyl group, isodecyl group, and the like. In addition, the alkyl group may include an ether bond (—O—) in the carbon chain. Examples of the alkyl group having an ether bond in a carbon chain include methoxyethyl group, ethoxyethyl group, methoxyethoxyethyl group, ethoxyethoxyethyl group, propyloxyethoxyethyl group, and methoxypropyl group.

A number of carbon atoms in the cycloalkyl group as the organic group is preferably 3 or more and 10 or less, and more preferably 3 or more and 6 or less. Specific examples of the cycloalkyl group include cyclopropyl group, cyclobutyl group, cyclopentyl group, cyclohexyl group, cycloheptyl group, cyclooctyl group, and the like.

A number of carbon atoms in the phenylalkyl group as the organic group is preferably 7 or more and 20 or less, and more preferably 7 or more and 10 or less. A number of carbon atoms in the naphthylalkyl group as the organic group is preferably 11 or more and 20 or less, and more preferably 11 or more and 14 or less. Specific examples of the phenylalkyl group include benzyl group, 2-phenylethyl group, 3-phenylpropyl group, and 4-phenylbutyl group. Specific examples of the naphthylalkyl group include α-naphthylmethyl group, β-naphthylmethyl group, 2-(α-naphthyl)ethyl group, and 2-(β-naphthyl)ethyl group. The phenylalkyl group or the naphthylalkyl group may have a substituent on phenyl group or naphthyl group.

When the organic group is the heterocyclyl group, the heterocyclyl group is the same as when R^{c4} in the formula (c3) is the heterocyclyl group. The heterocyclyl group may further have a substituent.

The heterocyclyl group as the organic group may be an aliphatic heterocyclic group or an aromatic heterocyclic group. The heterocyclyl group is preferably a heterocyclyl group consisting of 5- or 6-membered single ring including one or more N, S, and O, or a fused ring in which above single rings are fused each other, or a above single ring is fused with a benzene ring. When the heterocyclyl group is a fused ring, the number of rings constituting the fused ring is 3 or less. Examples of the heterocycle constituting the heterocyclyl group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, tetrahydrofuran, and the like.

When phenyl group, naphthyl group, and heterocyclyl group included in the above organic group have substituent, examples of the substituent include an alkyl group having 1 or more and 6 or less carbon atoms, an alkoxy group having 1 or more and 6 or less carbon atoms, a halogenated alkyl group having 1 or more and 6 or less carbon atoms, a halogenated alkoxy group having 1 or more and 6 or less carbon atoms, an aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having 1 or more and 6 or less carbon atoms, a dialkylamino group having an alkyl group having 1 or more and 6 or less carbon atoms, a benzoyl group, a halogen atom, a nitro group, a cyano group, and the like. When a phenyl group, a naphthyl group, and a heterocyclyl group included in the organic group have one or more substituents, a number of the substituents is not particularly limited, and preferably 1 or more and 4 or less. When a phenyl group, naphthyl group, and a heterocyclyl group included in the organic group have a plurality of substituents, the plurality of substituents may be the same or different.

In the formula (e1), R^{e1}, R^{e2}, and R^{e3} are each independently a hydrogen atom or an organic group. At least one of R^{e1}, R^{e2}, and R^{e3} is an aromatic group-containing group. In the formula (e2), R^{e4}, R^{e5}, and R^{e6} are each independently hydrogen atom or an organic group. At least one of R^{e4}, R^{e5}, and R^{e6} is an aromatic group-containing group. The aromatic ring in the aromatic ring-containing group may be an aromatic hydrocarbon ring or an aromatic heterocycle. The aromatic ring-containing group is preferably a hydrocarbon group. As the aromatic ring-containing group, an aromatic hydrocarbon group (aryl group) and an aralkyl group are preferred. Examples of the aromatic hydrocarbon group include phenyl group, naphthalen-1-yl group, and naphthalen-2-yl group. Among these aromatic hydrocarbon groups, phenyl group is preferred. Examples of the aralkyl group include benzyl group, 2-phenylethyl group, 3-phenylpropyl group, and 4-phenylbutyl group.

In the formula (e1), at least one of R^{e1}, R^{e2}, and R^{e3} is preferably a group represented by —Ar^{e1}—CH₂—. In addition, in the formula (e2), R^{e4} is preferably a group represented by Ar^{e1}—CH₂—. Ar^{e1} is an optionally substituted aromatic group. The aromatic group as Ar^{e1} may be an aromatic hydrocarbon group, or an aromatic heterocyclic group. The aromatic group as Ar^{e1} is preferably the aromatic hydrocarbon group. Examples of the aromatic hydrocarbon group include phenyl group, naphthalen-1-yl group, and naphthalen-2-yl group. Among these aromatic hydrocarbon groups, phenyl group is preferred. The substituent which the aromatic group as Ar^{e1} may have is the same as the substituent which phenyl group, naphthyl group, and heterocyclyl group may have in case that the organic group as R^{e1}, R^{e2}, R^{e3}, R^{e4}, R^{e5}, and R^{e6} is these groups.

Suitable specific examples of the amine compound represented by the formula (e1) include triphenylamine, N,N-diphenylbenzylamine, N-phenylbenzylamine, tribenzylamine, N,N-dimethylphenylamine, N-methyldiphenylamine, N,N-dimethylbenzylamine, N-methyldibenzylamine, N-methyl-N-benzylphenylamine, N,N-diethylphenylamine, N-ethyldiphenylamine, N,N-diethylbenzylamine, N-ethylbenzylamine, and N-ethyl-N-benzylamine.

Suitable specific examples of the imine compound represented by the formula (e2) include N-benzylphenylmethaneimine, N-benzyldiphenylmethaneimine, N-benzyl-1-phenylethaneimine, and N-benzylpropan-2-imine.

A content of the nitrogen-containing compound (E) is not particularly limited as long as the desired effect is not impaired. The content of the nitrogen-containing compound (E) is preferably 0.1% by mass or more and 10% by mass or less, and more preferably 0.3% by mass or more and 5% by mass or less relative to the mass of the photopolymerizable compound (A).

### <Triazine Compound (F)>

For the purpose of forming the material with higher refractive index, the composition may include a compound represented by the following formula (F1) as a triazine compound (F).

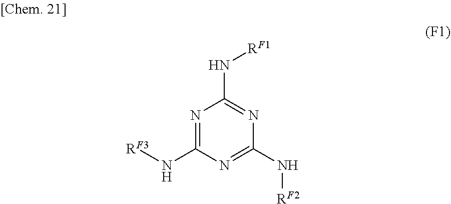

In the formula (F1), R^{F1}, R^{F2}, and R^{F3} are each independently an optionally substituted monocyclic aromatic group or an optionally substituted condensed aromatic group. Provided that, R^{F1}, R^{F2}, and R^{F3} do not include the radically polymerizable group-containing group. When the monocyclic aromatic group or the condensed aromatic group has the substituent, the substituent includes no aromatic ring. Three —NH— groups bonding to the triazine ring respectively bond to aromatic rings in R^{F1}, R^{F2}, and R^{F3}.

The monocyclic aromatic group as R^{F1}, R^{F2}, and R^{F3} may be an aromatic hydrocarbon group or an aromatic heterocyclic group. Examples of the monocyclic aromatic group include phenyl group, pyridinyl group, pyrimidinyl group, pyradinyl group, pyridazinyl group, furanyl group, thienyl group, oxazolyl group, thiazolyl group, and the like.

Examples of the substituted which the monocyclic aromatic group may have include halogen atom, hydroxy group, mercapto group, cyano group, nitro group, and a monovalent organic group. Provided that, the monovalent organic group includes no aromatic ring. Examples of the halogen atom as the substituent include fluorine atom, chlorine atom, bromine atom, and iodine atom. Examples of the monovalent organic group include an alkyl group, an alkoxy group, an alkoxyalkyl group, an aliphatic acryl group, an aliphatic acyloxy group, an alkoxycarbonyl group, an alkylthio group, an aliphatic acylthio group, and the like.

A number of carbon atoms in the monovalent organic group as the substituent is not particularly limited as long as the desired effect is not impaired. For example, the number of carbon atoms in the monovalent organic group as the substituent is preferably 1 or more and 20 or less, more preferably 1 or more and 12 or less, and further preferably 1 or more and 8 or less. In the alkoxyalkyl group, the aliphatic acyl group, the aliphatic acyloxy group, the alkoxycarbonyl group, the alkoxyalkylthio group, and the aliphatic acylthio group, lower limit of the number of carbon atoms is 2.

Suitable specific examples of the alkyl group as the substituent include methyl group, ethyl group, n-propyl group, isopropyl group, n-butyl group, isobutyl group, sec-butyl group, tert-butyl group, n-pentyl group, n-hexyl group, n-heptyl group, and n-octyl group.

Suitable specific examples of the alkoxy group as the substituent include methoxy group, ethoxy group, n-propyloxy group, isopropyl oxy group, n-butyloxy group, isobutyloxy group, sec-butyloxy group, tert-butyloxy group, n-pentyloxy group, n-hexyloxy group, n-heptyloxy group, and n-octyloxy group.

Suitable specific examples of the alkoxyalkyl group include methoxymethyl group, ethoxymethyl group, n-propyloxymethyl group, n-butyloxymethyl group, 2-methoxyethyl group, 2-ethoxyethyl group, 2-n-propyloxyethyl group, 2-n-butyloxyethyl group, 3-methoxy-n-propyl group, 3-ethoxy-n-propyl group, 3-n-propyloxy-n-propyl group, 3-n-butyloxy-n-propyl group, 4-methoxy-n-bnutyl group, 4-ethoxy-n-butyl group, 4-n-propyloxy-n-butyl group, and 4-n-butyloxy-n-butyl group.

Suitable specific examples of the aliphatic acyl group include acetyl group, propionyl group, butanoyl group, pentanoyl group, hexanoyl group, heptanoyl group, and octanoyl group.

Suitable specific examples of the aliphatic acyloxy group as the substituent include acetoxy group, propionyloxy group, butanoyloxy group, pentanoyloxy group, hexanoyloxy group, heptanoyloxy group, and octanoyloxy group.

Suitable specific examples of the alkoxycarbonyl group as the substituent include methoxycarbonyl group, ethoxycarbonyl group, n-propyloxycarbonyl group, isopropyloxycarbonyl group, n-butyloxycarbonyl group, isobutyloxycarbonyl group, sec-butyloxycarbonyl group, tert-butyloxycarbonyl group, n-pentyloxycarbonyl group, n-hexyloxycarbonyl group, n-heptyloxycarbonyl group, and n-octyloxycarbonyl group.

Suitable specific examples of the alkylthio group as the substituent include methylthio group, ethylthio group, n-propylthio group, isopropylthio group, n-butylthio group, isobutylthio group, sec-butylthio group, tert-butylthio group, n-pentylthio group, n-hexylthio group, n-heptylthio group, and n-octylthio group.

Suitable specific examples of the aliphatic acylthio group as the substituent include acetylthio group, propionylthio group, butanoylthio group, pentanoylthio group, hexanoylthio group, heptanoylthio group, and ocatnoylthio group.

When the monocyclic aromatic group has the substituent, a number of the substituent is not particularly limited as long as the desired effect is not impaired. When the monocyclic aromatic group has the substituent, the number of the substituent is preferably 1 or more and 4 or less, more preferably 1 or 2, and particularly preferably 1. When the monocyclic aromatic group has a plurality of the substituents, the plurality of the substituents may be different from each other.

Examples of the above-described optionally substituted monocyclic aromatic group include phenyl group, 4-cyanophenyl group, 3-cyanophenyl group, 2-cyanophenyl group, 2,3-dicyanophenyl group, 2,4-dicyanophenyl group, 2,5-dicyanophenyl group, 2,6-dicyanophenyl group, 3,4-dicyanophenyl group, 3,5-dicyanopohenyl group, 4-nitrophenyl group, 3-nitrophenyl group, 2-nitrophenyl group, 4-chlorophenyl group, 3-chlorophenyl group, 2-chlorophenyl group, 4-bromophenyl group, 3-bromophenyl group, 2-bromophenyl group, 4-iodophenyl group, 3-iodophenyl group, 2-iodophenyl group, 4-methoxyphenyl group, 3-methoxyphenyl group, 2-methoxyphenyl group, 4-methylphenyl group, 3-methylphenyl group, and 2-methylphenyl group.

Among these groups, phenyl group, 4-cyanophenyl group, 3-cyanophenyl group, 2-cyanophenyl group, 4-nitrophenyl group, 3-nitrophenyl group, and 2-nitrophenyl group are preferred, and phenyl group, and 4-cyanophenyl group are more preferred.

The condensed aromatic group as R^{F1}, R^{F2}, and R^{F3} is a group in which one hydrogen atom is excluded from the fused polycycle in which two or more aromatic monocycles are fused. A number of aromatic monocycles constituting the condensed aromatic group is not particularly limited. The number of aromatic monocycles constituting the condensed aromatic group is preferably 2 or 3, and more preferably 2. That is, the condensed aromatic group is preferably a bicyclic condensed aromatic group or a tricyclic condensed aromatic group, and more preferably a bicyclic condensed aromatic group. The condensed aromatic group may be an aromatic hydrocarbon group, or an aromatic heterocyclic group.

For example, examples of the bicyclic condensed aromatic group include naphthalen-1-yl group, naphthalen-2-yl group, quinolin-2-yl group, quinolin-3-yl group, quinolin-4-yl group, quinolin-5-yl group, quinolin-6-yl group, quinolin-7-yl group, quinolin-8-yl group, isoquinolin-1-yl group, isoquinolin-3-yl group, isoquinolin-4-yl group, isoquinolin-5-yl group, isoquinolin-6-yl group, isoquinolin-7-yl group, isoquinolin-8-yl group, benzoxazol-2-yl group, benzoxazol-4-yl group, benzoxazol-5-yl group, benzoxazol-6-yl group, benzoxazol-7-yl group, benzothiazol-2-yl group, benzothiazol-4-yl group, benzothiazol-5-yl group, benzothiazol-6-yl group, benzothiazol-7-yl group, and the like.

For example, examples of the tricyclic condensed aromatic group include anthracen-1-yl group, anthracen-2-yl group, anthracen-9-yl group, phenanthren-1-yl group, phenanthren-2-yl group, phenanthren-3-yl group, phenanthren-4-yl group, phenanthren-9-yl group, acridin-1-yl group, acridin-2-yl group, acridin-3-yl group, acridin-4-yl group, and acridin-9-yl group.

The substituent which the polycyclic condensed aromatic group such as the bicyclic condensed aromatic group and the tricyclic condensed aromatic group may have is the same as the substituent which monocyclic aromatic group may have.

As the above-described optionally substituted condensed aromatic group, naphthalen-1-yl group, naphthalen-2-yl group, quinolin-2-yl group, quinolin-3-yl group, quinolin-4-yl group, quinolin-5-yl group, quinolin-6-yl group, quinolin-7-yl group, quinolin-8-yl group, benzothiazol-2-yl group, and 2-mercaptobenzothiazol-6-yl group are preferred.

Among these groups, naphthalen-1-yl group, quinolin-3-yl group, quinolin-4-yl group, and 2-mercaptobenzothiazol-6-yl group are preferred, and naphthalen-1-yl group is more preferred.

Among the above-described compounds represented by the formula (F1), a compound which 1 or 2 of R^{F1}, R^{F2}, and R^{F3} is optimally substituted naphthyl group, and 1 or 2 of R^{F1}, R^{F2}, and R^{F3} is 4-cyanophenyl group or benzothiazolyl group, since refractive index, surface appearance and heat resistance of the material formed by using the composition are well balanced and excellent. As the optionally substituted naphthyl group, naphthalen-1-yl group is preferred.

Suitable examples of the compound represented by the formula (F1) include the following compounds.

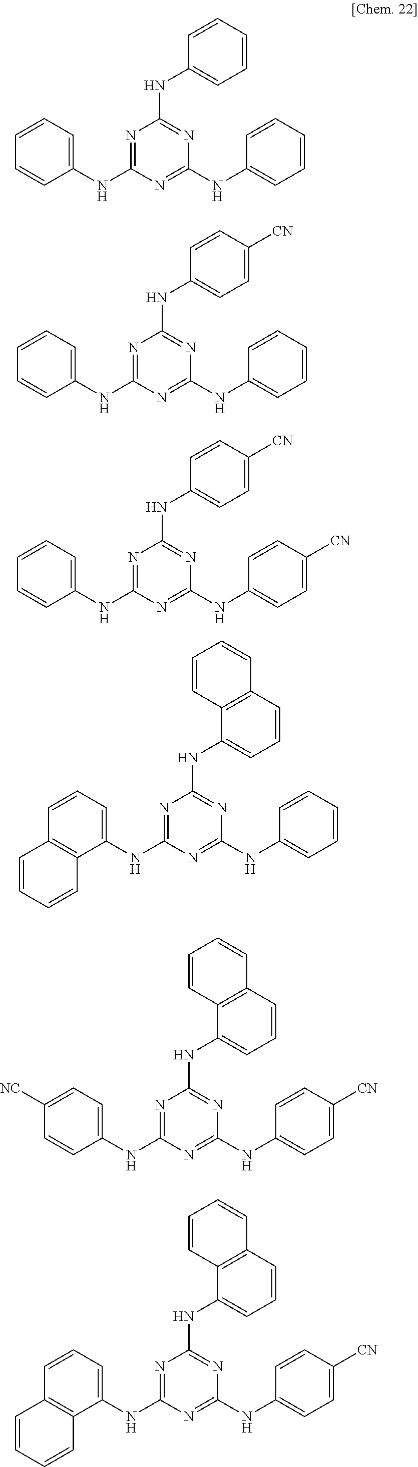

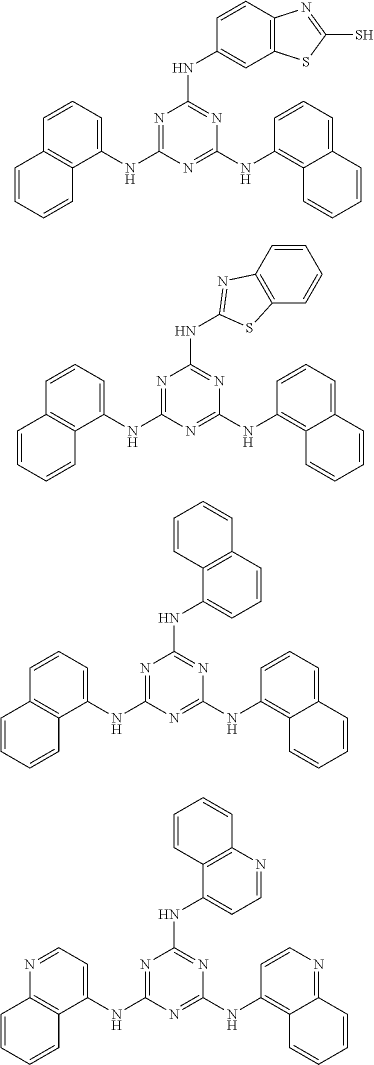

Production method of the compound represented by the formula (F1) is not particularly limited. Typically, the compound represented by the formula (F1) can be prepared by reacting cyanuric halide such as cyanuric chloride with aromatic amines represented by R^{F1}—NH₂, R^{F2}—NH₂, and R^{F3}—NH₂. These multiple amines may react with the cyanuric halide simultaneously or sequentially, and preferably sequentially react with the cyanuric halide.

The compound represented by the formula (F1) is usually synthesized in an organic solvent. This organic solvent is not particularly limited as long as the solvent is an inactive solvent which does not react with cyanuric halide, aromatic amine, radically polymerizable group, and the like. As the solvent, solvents exemplified as specific examples of the solvent (S) described below can be used. In the production of the compound represented by the formula (F1), reaction temperature is not particularly limited when cyanuric halide is reacted with aromatic amines such as aromatic amines represented by R^{F1}—NH₂, R^{F2}—NH₂, and R^{F3}—NH₂. Typically, reaction temperature is preferably 0° C. or higher and 150° C. or lower.

An amount of the triazine compound (F) in the composition is not particularly limited as long as the desired effect is impaired. The amount of the triazine compound (F) in the composition is preferably 0.1 parts by mass or more and 30 parts by mass or less, 0.3 parts by mass or more and 20 parts by mass or less, and further preferably 0.5 parts by mass or more and 15 parts by mass or less, when a mass of the composition excluding a mass of the solvent (S) described below is 100 parts by mass.

### <Solvent (S)>

The composition may include a solvent (S) for purposes of adjusting applicability and the like. Type of the solvent (S) is not particularly limited as long as the desired effect is not impaired.

For example, suitable examples of the solvent (S) include (poly)alkyleneglycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether (HO—CH₂—CH₂—CH₂—O—CH₃), propylene glycol monomethyl ether (HO—C(CH₃)HCH₂—O—CH₃ or H₃C—O—C(CH₃)HCH₂—OH), propylene glycol monoethyl ether (HO—CH₂CH₂CH₂—O—CH₂CH₃), propylene glycol monomethyl ether (HO—C(CH₃)HCH₂—O—CH₂CH₃ or H₃CH₂C—O—C(CH₃)HCH₂—OH), propylene glycol mono-n-propyl ether (HO—CH₂CH₂CH₂—O—CH₂CH₂CH₃), propylene glycol mono-n-propyl ether (HO—C(CH₃)HCH₂—O—CH₂CH₂CH or H₃CH₂CH₂C—O—C(CH₃)HCH₂—OH), propylene glycol mono-n-butyl ether (HO—CH₂CH₂CH₂—O—CH₂CH₂CH₃), propylene glycol mono-n-butyl ether (HO—C(CH₃)HCH₂—O—CH₂CH₂CH₂CH₃ or H₃CH₂CH₂CH₂C—O—C(CH₃)HCH₂—OH), dipropylene glycol monoethyl ether (HO—(CH₂CH₂CH₂—O)₂—CH₃), dipropylene glycol monomethyl ether (HO—(C(CH₃)HCH₂—O)₂—CH₃ or H₃C—O—(C(CH₃)HCH₂—O)₂—H), dipropylene glycol monoethyl ether (HO—(CH₂CH₂CH₂—O)₂—CH₂CH₃), dipropylene glycol monoethyl ether (HO—(C(CH₃)HCH₂—O)₂—C₂CH₃ or H₃CH₂C—O—(C(CH₃)HCH₂—O)₂—H), dipropylene glycol mono-n-propyl ether (HO—(CH₂CH₂CH₂—O)₂—CH₂CH₂CH₃ or H₃CH₂CH₂C—O—(CH₂—CH₂—CH₂—O)₂—H), dipropylene glycol mono-n-propyl ether (HO—(C(CH₃)HCH₂—O)₂—CH₂CH₂CH₃ or H₃CH₂CH₂C—O—(C(CH₃)HCH₂—O)₂—H), dipropylene glycol mono-n-butyl ether (HO—(CH₂CH₂CH₂—O)₂—CH₂CH₂CH₂CH₃ or H₃CH₂CH₂CH₂C—O—(CH₂CH₂CH₂—O)₂—H), dipropylene glycol mono-n-butyl ether (HO—(C(CH₃)HCH₂—O)₂—CH₂CH₂CH₂CH; or H₃CH₂CH₂CH₂C—O—(C(CH₂) HCH₂—O)₂—H), tripropylene glycol monomethyl ether (HO—(CH₂CH₂CH₂—O)₃—CH₂CH₃), tripropylene glycol monomethyl ether (HO—(C(CH₃)HCH₂—O)₃—CH₃ or H₃C—O—(C(CH₃)HCH₂—O)₃—H), tripropylene glycol monoethyl ether (HO—(CH₂CH₂CH₂—O)₃—CH₂CH₃), and tripropylene glycol monoethyl ether (HO—(C(CH₃)HCH₂—O)₃—CH₂CH₃ or H₃CH₂C—O—(C(CH₃)HCH₂—O)₃—H); (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as ethylene glycol dimethyl ether, ethylene glycol diethyl ether, ethylene glycol methyl ethyl ether, diethylene glycol dimethyl ether, diethylene glycol methyl ethyl ether, diethylene glycol diethyl ether, propylene glycol dimethyl ether, propylene glycol diethyl ether, propylene glycol methyl ethyl ether, dipropylene glycol dimethyl ether, dipropylene glycol methyl ethyl ether, dipropylene glycol diethyl ether, and tetrahydrofuran; ketones such as methyl ethyl ketone, cyclohexanone, 2-hepotanone, and 3-heptanone; lactic acid alkyl esters such as methyl 2-hydroxypropionate, and ethyl 2-hydroxypropionate; other esters such as ethyl 2-hydroxy-2-methylpropionate, methyl 3-methoxypropionate, ethyl 3-methoxypropionate, methyl-3-ethoxypropionate, ethyl 3-ethoxypropionate, ethyl ethoxyacetate, ethyl hydroxyacetate, methyl 2-hydroxy-3-methylbutanoate, 3-nethoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl formate, isopentyl acetate, n-butyl propionate, ethyl butanoate, n-propyl butanoate, isopropyl butanoate, n-butyl butanoate, methyl pyruvate, ethyl pyruvate, n-propyl pyruvate, methyl acetoacetate, ethyl acetoacetate, and ethyl 2-oxabutanoate; aromatic hydrocarbons such as toluene and xylene, amides such as N-methylpyrrolidone, N,N-dimethylformamide, and N,N-dimethylacetamide, and the (poly)alkylene glycol monoalkyl ether acetates are preferred.

From the viewpoint that application by inkjet method can be performed well, the solvent (S) preferably includes a solvent having boiling point of 140° C. or higher under atmospheric pressure, and more preferably includes a high boiling point solvent (S1) having boiling point of 170° C. or higher under atmospheric pressure.

Specific examples of the solvent having boiling point of 140° C. or higher under atmospheric pressure include ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether (HO—CH₂—CH₂CH₂—O—CH₃), propylene glycol monoethyl ether (HO—CH₂CH₂CH₂—O—CH₂CH₃), propylene glycol mono-n-propyl ether (HO—CH₂CH₂CH₂—O—CH₂CH₂CH₃), propylene glycol mono-n-propyl ether (HO—C(CH₃)HCH₂—O—CH₂CH₂CH₃ or H₃CH₂CH₂C—O—C(CH₃)HCH₂—OH), propylene glycol mono-n-butyl ether (HO—CH₂CH₂CH₂—O—CH₂CH₂CH₂CH₃), propylene glycol mono-n-butyl ether (HO—C(CH₃)HCH₂—O—CH₂CH₂CH₂CH₃ or H₃CH₂CH₂CH₂C—O—C(CH₃)HCH₂—OH), dipropylene glycol monoethyl ether (HO—(CH₂CH₂CH₂—O)₂—CH₃), dipropylene glycol monomethyl ether (HO—(C(CH₃) HCH₂—O)₂—CH₃ or H₃C—O—(C(CH₃)HCH₂—O)₂—H), dipropylene glycol monoethyl ether (HO—(CH₂CH₂CH₂—O)₂—CH₂CH₃), dipropylene glycol monoethyl ether (HO—(C(CH₃)HCH₂—O)₂—CH₂CH₃ or H₃CH₂C—O—(C(CH₃)HCH₂—O)₂—H), dipropylene glycol mono-n-propyl ether (HO—(CH₂CH₂CH₂—O)₂—CH₂CH₂CH₃ or H₃CH₂CH₂C—O—(CH₂CH₂CH₂—O)₂—H), dipropylene glycol mono-n-propyl ether (HO—(C(CH₃)HCH₂—O)₂—CH₂CH₂CH₃ or H₃CH₂CH₂C—O—(C(CH₃)HCH₂—O)₂—H), dipropylene glycol mono-n-butyl ether (HO—(CH₂CH₂CH₂—O)₂—CH₂CH₂CH₂CH₃ or H₃CH₂CH₂CH₂C—O—(CH₂—CH₂—CH₂—O)₂—H), dipropylene glycol mono-n-butyl ether (HO—(C(CH₃)HCH₂—O)₂—CH₂CH₂CH₂CH₃ or H₃CH₂CH₂CH₂—C—O—(C(CH₃)HCH₂—O)₂—H), tripropylene glycol monomethyl ether (HO—(CH₂CH₂CH₂—O)₃—CH₂CH₃), tripropylene glycol monomethyl ether (HO—(C(CH₃)HCH₂—O)₃—CH₃ or H₃C—O—(C(CHO) HCH₂—O)₃—H), tripropylene glycol monoethyl ether (HO—(CH₂CH₂CH₂—O)₃—CH₂CH₃), tripropylene glycol monoethyl ether (HO—(C(CH₃) HCH₂—O)₃—CH₂CH₃ or H₃CH₂C—O—(C(CH₂) HCH₂—O)₃—H), diethylene glycol monomethyl ether acetate, diethylene glycol monoethyl ether acetate, diethylene glycol dimethyl ether, cyclohexanone, 2-hepotanone, ethyl 2-hydroxypropionate, ethyl 2-hydroxy-2-methylpropionate, ethyl 3-methoxypropionate, ethyl 3-methoxypropionate, ethyl 3-ethoxypropionate, ethyl ethoxyacetate, 3-nethoxybutyl acetate, 3-methyl-3-methoxybutyl acetate, 3-methyl-3-methoxybutyl propionate, n-butyl butanoate, methyl acetoacetate, ethyl acetoacetate, ethyl 2-oxabutanoate, N-methylpyrrolidone, N,N-dimethylformamide, and N,N-dimethylacetamide.

Specific examples of the high boiling point solvent (S1) include ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol mono-n-butyl ether (HO—CH₂CH₂CH₂—O—CH₂CH₂CH₂CH₃), propylene glycol mono-n-butyl ether (HO—C(CH₂)HCH₂—O—CH₂CH₂CH₂CH₃ or H₃CH₂CH₂CH₂C—O—C(CH₃)HCH₂—OH), dipropylene glycol monoethyl ether (HO—(CH₂CH₂CH₂—O)₂—CH₃), dipropylene glycol monomethyl ether (HO—(C(CH₃)HCH₂—O)₂—CH₃ or H₃C—O—(C(CH₃)HCH₂—O)₂—H), dipropylene glycol monoethyl ether (HO—(CH₂CH₂CH₂—O)₂—CH₂CH₃), dipropylene glycol monoethyl ether (HO—(C(CH₃)HCH₂—O)₂—CH₂CH₃ or H₃CH₂C—O—(C(CH₃)HCH₂—O)₂—H), dipropylene glycol mono-n-propyl ether (HO—(CH₂CH₂CH₂—O)₂—CH₂CH₂CH₃ or H₃CH₂CH₂C—O—(CH₂CH₂CH₂—O)₂—H), dipropylene glycol mono-n-propyl ether (HO—(C(CH₃)HCH₂—O)₂—CH₂CH₂CH₃ or H₃CH₂CH₂C—O—(C(CH₃)HCH₂—O)₂—H), dipropylene glycol mono-n-butyl ether (HO—(CH₂CH₂CH₂—O)₂—CH₂CH₂CH₂CH₃ or H₃CH₂CH₂CH₂C—O—(CH₂CH₂CH₂—O)₂—H), dipropylene glycol mono-n-butyl ether (HO—(C(CH₃)HCH₂—O)₂—CH₂CH₂CH₂CH₃ or H₃CH₂CH₂CH₂C—O—(C(CH₃)HCH₂—O)₂—H), tripropylene glycol monomethyl ether (HO—(CH₂CH₂CH₂—O)₃—CH₂CH₃), tripropylene glycol monomethyl ether (HO—(C(CH₃)HCH₂—O)₃—CH₃ or H₃C—O—(C(CH₃)HCH₂—O)₃—H), tripropylene glycol monoethyl ether (HO—(CH₂CH₂CH₂—O)₃—CH₂CH₃), tripropylene glycol monoethyl ether (HO—(C(CH₃)HCH₂—O)₃—CH₂CH₃ or H₃CH₂C—O—(C(CH₃)HCH₂—O)₃—H), diethylene glycol monomethyl ether acetate, diethylene glycol monoethyl ether acetate, diethylene glycol methyl ethyl ether, diethylene glycol diethyl ether, dipropylene glycol dimethyl ether, dipropylene glycol methyl ethyl ether, dipropylene glycol diethyl ether, ethyl hydroxy acetate, 3-methoxybutyl acetate, 3-methyl-3-methoxybutyl acetate, 3-methyl-3-methoxybutyl propionate, methyl acetoacetate, ethyl acetoacetate, ethyl 2-oxobutanoate, and N-methyhlpyrrolidone. Among these, the solvent(S) preferably includes at least one selected from the group consisting of tripropylene glycol monomethyl ether (HO—(CH₂CH₂CH₂—O)₃—CH₂CH₃), dipropylene glycol monoethyl ether (HO—(CH₂CH₂CH₂—O)₂—CH₂CH₃), and triethylene glycol dimethyl ether.

Since desired effect can be easily obtained, a ratio of a mass of the solvent having boiling point of 140° C. or higher or the high boiling point solvent (S1) having boiling point of 170° C. or higher is preferably 20% by mass or more, more preferably 30% by mass or more, further preferably 50% by mass or more, even more preferably 70% by mass or more, particularly preferably 90% by mass or more, and most preferably 100% by mass relative to a mass of the solvent (S). In addition, a ratio of a mass of at least one selected from the group consisting of tripropylene glycol monomethyl ether (HO—(CH₂CH₂CH₂—O)₃—CH₂CH₃), dipropylene glycol monoethyl ether (HO—(CH₂CH₂CH₂)₂—CH₂CH₃), and triethylene glycol dimethyl ether is preferably 50% by mass or more, more preferably 70% by mass or more, further preferably 90% by mass or more, and particularly preferably 100% by mass relative to the mass of the high boiling point solvent (S1).

A content of the solvent(S) is in an amount such that the concentration of components other than the solvent(S) in the composition is preferably 1% by mass or more and 99% by mass or less, more preferably 5% by mass or more and 50% by mass or less, and further preferably 10% by mass or more and 30% by mass or less.

### <Other Component>

The composition may include various additives as needed, as other components other than the components described above. Examples of the additive include a sensitizer, a curing accelerator, a filler, a dispersant, an adhesion promoter such as a silane coupling agent, an antioxidant, an antiaggregant agent, a thermal polymerization inhibitor, a defoaming agent, and a surfactant. The amount of these additives used is appropriately determined in consideration of the amount of these additives usually used in the composition.

### <<Photosensitive Composition>>

A photosensitive composition includes a photopolymerizable compound (A), metal oxide particles (B), and an initiator (C). The initiator (C) is a component that cures a photopolymerizable compound. Suitable embodiments and amounts of the photopolymerizable compound (A) and the metal oxide particles (B) are respectively as described above for the above composition.

The photosensitive composition may further include at least one component described respectively above for the composition and selected from a group consisting of the plasticizer (D), the nitrogen-containing compound (E), the triazine compound (F), the solvent(S), and other component. Suitable embodiments and amounts of these components are respectively as described above for the above composition.

### <Initiator (C)>

The photosensitive composition includes the initiator (C) to cure the photopolymerizable compound (A). Since the photopolymerizable compound (A) has the radically polymerizable group, a radical polymerization initiator is used as the initiator (C). Since regioselective curing of the photosensitive composition is capable, and there is no concern about thermal degradation, volatilization, or sublimation of the components of the photosensitive composition, the photo initiator is preferred as the initiator (C). The initiator (C) is not particularly limited and various polymerization initiator conventionally known can be used.

Specific examples of the photo radical polymerization initiator suitable as the radical polymerization initiator include 1-hydroxycyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl) ketone, 2-methyl-1-[4-(methylthio)phenyl]-2-morpholinopropan-1-one, 2-benzyl-2-dimethylamino-1-(4-morpholinophenyl)-butan-1-one, 0-acetyl-1-[6-(2-methylbenzoyl)-9-ethyl-9H-carbazol-3-yl]ethanone oxime, (9-ethyl-6-nitro-9H-carbazol-3-yl) [4-(2-methoxy-1-methylethoxy)-2-methylphenyl]methanon 0-acetyloxime, 1,2-octanedione, 2-(benzoyloxyimino)-1-[4-(phenylthio)phenyl]-1-octanone, 2,4,6-trimethylbenzoyldiphenylphosphine oxide, 4-benzoyl-4′-methyldimethyl sulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethyl acetal, benzyl dimethyl ketal, 1-phenyl-1,2-propanedion-2-(O-ethoxycarbonyl) oxime, methyl o-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzil, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, dibenzosuberone, pentyl 4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(furan-2-yl)ethenyl]-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, and the like. These photo radical polymerization initiators may be used either individually or in combination of two or more.

Among photo radical polymerization initiators, an oxime ester compound is preferred from the viewpoint of sensitivity of the photosensitive composition. A compound including the partial structure represented by the formula (c1) is preferred as the oxime ester compound.

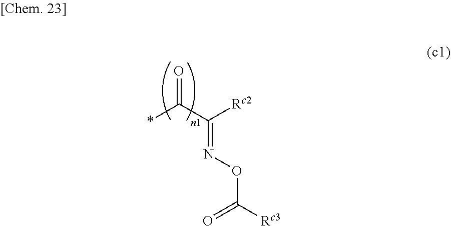

In the formula (c1), n1 is 0 or 1. R^{c2} is a monovalent organic group. R^{c3} is a hydrogen atom, an optionally substituted aliphatic hydrocarbon group having 1 or more and 20 or less carbon atoms, or an optionally substituted aryl group. * is a bond.

The compound including the partial structure represented by the formula (c1) preferably has a carbazole skeleton, a fluorene skeleton, a diphenyl ether skeleton, or a phenyl sulfide skeleton. The compound including the partial structure represented by the formula (c1) preferably has 1 or 2 partial structures represented by the formula (c1).

Examples of the compound including the partial structure represented by the formula (c1) includes a compound represented by the following formula (c2).

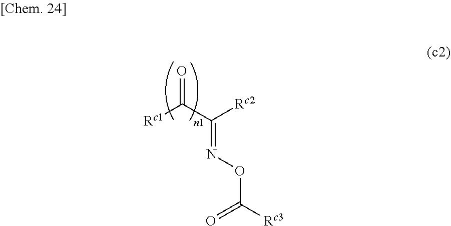

In the formula (c2), R is a group represented by following formula (c3), (c4) or (c5). n1 is 0 or 1. R^{c2} is a monovalent organic group. R^{c3} is a hydrogen atom, an optionally substituted aliphatic hydrocarbon group having 1 or more and 20 or less carbon atoms, or an optionally substituted aryl group.

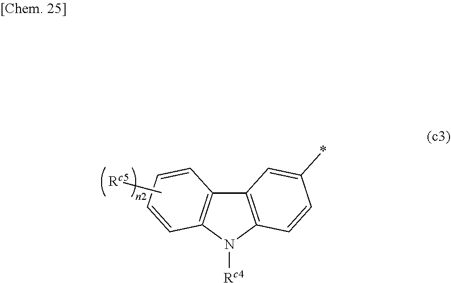

In the formula (c3), R^{c4} is a monovalent organic group. R^{c5} is a monovalent organic group, halogen atom, or nitro group.

n2 is an integer of 0 or more and 3 or less. When n2 is 2 or 3, plural R^{c5}s may be the same as or different each other, and plural R^{c5}s may be combined to each other to form a ring. * is a bond.

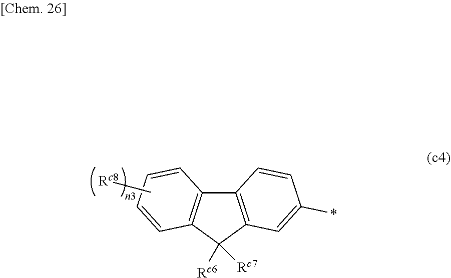

In the formula (c4), R^{c6} and R^{c7} are each independently an optionally substituted chain alkyl group, an optionally substituted chain alkoxy group, an optionally substituted cyclic organic group, or hydrogen atom. R^{c6} and R^{c7} may be combined to each other to form a ring. R^{c7} and a benzene ring in the fluorene skeleton may be combined to each other to form a ring. R^{c8} is a nitro group or a monovalent organic group.

n3 is an integer of 0 or more and 4 or less. * is a bond.

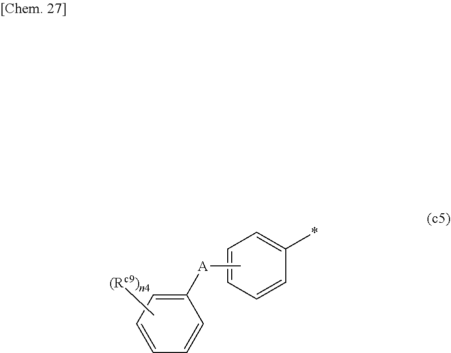

In the formula (c5), R^{c9} is a monovalent organic group, a halogen atom, nitro group, or cyano group. A is sulfur atom or oxygen atom. n4 is an integer of 0 or more and 4 or less. * is a bond.

In the formula (c3), R²⁴ is a monovalent organic group. R^{c4} can be selected from various kinds of organic groups as long as it does not interfere with the object of the present invention. As the organic group, a carbon atom-containing group is preferred, and a group consisting of one or more carbon atoms, and one or more atoms selected from the group consisting of H, O, S, Se, N, B, P, Si and a halogen atom is more preferred. The number of carbon atoms in the carbon atom-containing group is not particularly limited, and preferably 1 or more and 50 or less, and more preferably 1 or more and 20 or less. Suitable examples of R^{c4} include an optionally substituted alkyl group having 1 or more and 20 or less carbon atoms, an optionally substituted cycloalkyl group having 3 or more an 20 or less carbon atoms, an optionally substituted saturated aliphatic acyl group having 2 or more and 20 or less carbon atoms, an optionally substituted alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthoyl group, an optionally substituted naphthoxycarbonyl group, an optionally substituted naphthylalkyl group having 11 or more and 20 or less carbon atoms, an optionally substituted heterocyclyl group, an optionally substituted heterocyclylcarbonyl group, and the like.

The alkyl group having 1 or more and 20 or less carbon atoms is preferred as R^{c4}. The alkyl group may be linear or branched. The number of carbon atoms in the alkyl group as R^{c4} is preferably 2 or more, more preferably 5 or more, and particularly preferably 7 or more, from the viewpoint of good solubility of the compound represented by the formula (c3) in the photosensitive composition. From the viewpoint of good compatibility between the compound represented by the formula (c3) and other components in the photosensitive composition, the number of carbon atoms in the alkyl group as R^{c4} is preferably 15 or less, and more preferably 10 or less.

When R^{c4} has a substituent, suitable examples of the substituent is a hydroxy group, an alkyl group having 1 or more and 20 or less carbon atoms, an alkoxy group having 1 or more and 20 or less carbon atoms, an aliphatic acyl group having 2 or more and 20 or less carbon atoms, an aliphatic acyloxy group having 2 or more and 20 or less carbon atoms, a phenoxy group, a benzoyl group, a benzoyloxy group, a group represented by —PO(OR)₂ (in which, R is an alkyl group having 1 or more and 6 or less carbon atoms), a halogen atom, a cyano group, a heterocyclyl group, and the like.

When R^{c4} is a heterocyclyl group, the heterocyclyl group may be an aliphatic heterocyclic group or an aromatic heterocyclic group. When R^{c4} is the heterocyclyl group, the heterocyclyl group is a 5- or 6-membered single ring containing one or more N, S, and O, or a heterocyclyl group in which single rings are fused each other, or a single ring is fused with a benzene ring. When the heterocyclyl group is a fused ring, the number of rings constituting the fused ring is 3 or less. Examples of the heterocycle constituting the heterocyclyl group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, tetrahydrofuran, and the like. When R^{c4} is the heterocyclyl group, examples of substituent that the heterocyclyl group may have include a hydroxy group, an alkoxy group having 1 or more and 6 or less carbon atoms, a halogen atom, a cyano group, a nitro group, and the like.

Suitable examples of above described R^{c4} include methyl group, ethyl group, n-propyl group, isopropyl group, n-butyl group, isobutyl group, sec-butyl group, tert-butyl group, n-pentyl group, isopentyl group, neopentyl group, pentan-3-yl group, sec-pentyl group, tert-pentyl group, n-hexyl group, n-heptyl group, n-octyl group and 2-ethylhexyl group. Since solubility of the compound represented by the formula (c3) in the photosensitive composition is good, n-octyl group and 2-ethylhexyl group are preferred, and 2-ethylhexyl group is more preferred.

In the formula (c3), R^{c5} is a monovalent organic group, halogen atom, or nitro group. The monovalent organic group as R^{c5} can be selected from various kinds of organic groups as long as it does not interfere with the object of the present invention. As the organic group, a carbon atom-containing group is preferred, and a group consisting of one or more carbon atoms, and one or more atoms selected from the group consisting of H, O, S, Se, N, B, P, Si and a halogen atom is more preferred. The number of carbon atoms in the carbon atom-containing group is not particularly limited, and preferably 1 or more and 50 or less, and more preferably 1 or more and 20 or less. Examples of the organic group suitable for R^{c5} include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with 1 or 2 organic groups, morpholin-1-yl group, piperazin-1-yl group, cyano group, a substituent including a group represented by HX₂C— or H₂XC— (in which, X is each independently a halogen atom), and the like.

When R^{c5} is the alkyl group, a number of carbon atoms in the alkyl group is preferably 1 or more and 20 or less, and more preferably 1 or more and 6 or less. When R^{c5} is the alkyl group, the alkyl group may be linear or branched. Specific examples of the alkyl group as R^{c5} include methyl group, ethyl group, n-propyl group, isopropyl group, n-butyl group, isobutyl group, sec-butyl group, tert-butyl group, n-pentyl group, isopentyl group, sec-pentyl group, tert-pentyl group, n-hexyl group, n-heptyl group, n-octyl group, isooctyl group, sec-octyl group, tert-octyl group, n-nonyl group, isononyl group, n-decyl group, isodecyl group, and the like. When R^{c5} is alkyl group, the alkyl group may contain an ether bond (—O—) in the carbon chain. Examples of the alkyl group having an ether bond in a carbon chain include methoxyethyl group, ethoxyethyl group, methoxyethoxyethyl group, ethoxyethoxyethyl group, propyloxyethoxyethyl group, and methoxypropyl group.

When R^{c5} is the alkoxy group, the number of carbon atoms in the alkoxy group is preferably 1 or more and 20 or less, and more preferably 1 or more and 6 or less. When R^{c5} is the alkoxy group, the alkoxy group may be linear or branched. When R^{c5} is the alkoxy groups, specific examples thereof include methoxy group, ethoxy group, n-propyloxy group, isopropyloxy group, n-butyloxy group, isobutyloxy group, sec-butyloxy group, tert-butyloxy group, n-pentyloxy group, isopentyloxy group, sec-pentyloxy group, tert-pentyloxy group, n-hexyloxy group, n-heptyloxy group, n-octyloxy group, isooctyloxy group, sec-octyloxy group, tert-octyloxy group, n-nonyloxy group, isononyloxy group, n-decyloxy group, isodecyloxy group, and the like. When R^{c5} is the alkoxy groups, the alkoxy group may have an ether bond (—O—) in a carbon chain. Examples of the alkoxy group having an ether bond in a carbon chain include methoxyethoxy group, ethoxyethoxy group, methoxyethoxyethoxy group, ethoxyethoxyethoxy group, propyloxyethoxyethoxy group, methoxypropyloxy group, and the like.

When R^{c5} is the cycloalkyl group or the cycloalkoxy group, a number of carbon atoms in the cycloalkyl group or the cycloalkoxy group is preferably 3 or more and 10 or less, and more preferably 3 or more and 6 or less. Specific examples of the cycloalkyl group as R^{c5} include cyclopropyl group, cyclobutyl group, cyclopentyl group, cyclohexyl group, cycloheptyl group, cyclooctyl group, and the like. Specific examples of the cycloalkoxy group as R^{c5} include cyclopropyloxy group, cyclobutyloxy group, cyclopentyloxy group, cyclohexyloxy group, cycloheptyloxy group, cyclooctyloxy group, and the like.

When R^{c5} is a saturated aliphatic acyl group or a saturated aliphatic acyloxy group, a number of carbon atoms is preferably 2 or more and 21 or less, and more preferably 2 or more and 7 or less. When R^{c5} is a saturated aliphatic acyl group, specific examples thereof include acetyl group, propanoyl group, n-butanoyl group, 2-methylpropanoyl group, n-pentanoyl group, 2,2-dimethylpropanoyl group, n-hexanoyl group, n-heptanoyl group, n-octanoyl group, n-nonanoyl group, n-decanoyl group, n-undecanoyl group, n-dodecanoyl group, n-tridecanoyl group, n-tetradecanoyl group, n-pentadecanoyl group, n-hexadecanoyl group, and the like. When R^{c5} is a saturated aliphatic acyloxy group, specific examples thereof include acetyloxy group, propanoyloxy group, n-butanoyloxy group, 2-methylpropanoyloxy group, n-pentanoyloxy group, 2,2-dimethylpropanoyloxy group, n-hexanoyloxy group, n-heptanoyloxy group, n-octanoyloxy group, n-nonanoyloxy group, n-decanoyloxy group, n-undecanoyloxy group, n-dodecanoyloxy group, n-tridecanoyloxy group, n-tetradecanoyloxy group, n-pentadecanoyloxy group, n-hexadecanoyloxy group, and the like.

When R^{c5} is an alkoxycarbonyl group, a number of carbon atoms is preferably 2 or more and 20 or less, and preferably 2 or more and 7 or less. When R^{c5} is an alkoxycarbonyl group, specific examples thereof include methoxycarbonyl group, ethoxycarbonyl group, n-propyloxycarbonyl group, isopropyloxycarbonyl group, n-butyloxycarbonyl group, isobutyloxycarbonyl group, sec-butyloxycarbonyl group, tert-butyloxycarbonyl group, n-pentyloxycarbonyl group, isopentyloxycarbonyl group, sec-pentyloxycarbonyl group, tert-pentyloxycarbonyl group, n-hexyloxycarbonyl group, n-heptyloxycarbonyl group, n-octyloxycarbonyl group, isooctyloxycarbonyl group, sec-octyloxycarbonyl group, tert-octyloxycarbonyl group, n-nonyloxycarbonyl group, isononyloxycarbonyl group, n-decyloxycarbonyl group, and isodecyloxycarbonyl group.

When R^{c5} is a phenylalkyl group, a number of carbon atoms in the phenylalkyl group is preferably 7 or more and 20 or less, and more preferably 7 or more and 10 or less. In addition, when R^{c5} is a naphthylalkyl group, a number of carbon atoms in the naphthylalkyl group is preferably 11 or more and 20 or less, and more preferably 11 or more and 14 or less. When R^{c5} is a phenylalkyl group, specific examples thereof include benzyl group, 2-phenylethyl group, 3-phenylpropyl group, and 4-phenylbutyl group. When R^{c5} is a naphthylalkyl group, specific examples thereof include α-naphthylmethyl group, β-naphthylmethyl group, 2-(α-naphthyl)ethyl group, and 2-(β-naphthyl)ethyl group. When R^{c5} is a phenylalkyl group or a naphthylalkyl group, R^{c5} may further have a substituent on phenyl group or naphthyl group.

When R^{c5} is a heterocyclyl group, the heterocyclyl group is the same as the heterocyclyl group as R^{c4} in the formula (c3), and may further have a substituent. When R^{c5} is a heterocyclylcarbonyl group, the heterocyclyl group included in the heterocyclylcarbonyl group is the same as the heterocyclyl group as R^{c5}.

When R^{c5}s is an amino group substituted with one or two organic groups, suitable examples of the organic groups include an alkyl group having 1 or more and 20 or less carbon atoms, a cycloalkyl group having 3 or more and 10 or less carbon atoms, a saturated aliphatic acyl group having 2 or more and 21 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more and 20 or less carbon atoms, and a heterocyclyl group. Specific examples of these suitable organic group are the same as R^{c5}. Specific examples of the amino group substituted with one or two organic groups include methylamino group, ethylamino group, diethylamino group, n-propylamino group, di-n-propylamino group, isopropylamino group, n-butylamino group, di-n-butylamino group, n-pentylamino group, n-hexylamino group, n-heptylamino group, n-octylamino group, n-nonylamino group, n-decylamino group, phenylamino group, naphthylamino group, acetylamino group, propanoylamino group, n-butanoylamino group, n-pentanoylamino group, n-hexanoylamino group, n-heptanoylamino group, n-octanoylamino group, n-decanoylamino group, benzoylamino group, α-naphthoylamino group, β-naphthoylamino group, and the like.

When the phenyl group, the naphthyl group, and the heterocyclyl group included in R^{c5} further have a substituent, examples of the substituent include a substituent including a group represented by HX₂C— or H₂XC—, an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having an alkyl group having 1 or more and 6 or less carbon atoms, a dialkylamino group having alkyl groups having 1 or more and 6 or less carbon atoms, morpholin-1-yl group, piperazin-1-yl group, benzoyl group, a halogen atom, nitro group, cyano group, and the like. When the phenyl group, the naphthyl group, and the heterocyclyl group included in R^{c5} further having one or more substituents, the number of substituents is not particularly limited as long as it does not interfere with the object of the present invention, and is preferably 1 or more and 4 or less. When a phenyl group, a naphthyl group, and a heterocyclyl group included in R^{c5} have a plurality of substituents, the plurality of substituents may be the same or different.

When a benzoyl group, a naphthyl group included in R^{c5} further have a substituent, examples of the substituent include an alkyl group having 1 or more and 6 or less carbon atoms, a morpholin-1-yl group, a piperazin-1-yl group, a 2-thenoyl group (thiophen-2-ylcarbonyl group), a furan-3-ylcarbonyl group, a phenyl group, and the like.

As a halogen atom represented by X, a fluorine atom, a chlorine atom, a bromine atom, and the like are exemplified, and the fluorine atom is preferred.

As a substituent including a group represented by HX₂C— or H₂XC—, a halogenated alkoxy group including a group represented by HX₂C— or H₂XC—, a group having a halogenated alkoxy group including a group represented by HX₂C— or H₂XC—, a halogenated alkyl group including a group represented by HX₂C— or H₂XC—, a group having a halogenated alkyl group including a group represented by HX₂C— or H₂XC—, and the like are exemplified, and the halogenated alkoxy group including a group represented by HX₂C— or H₂XC— or the group having a halogenated alkoxy group including a group represented by HX₂C— or H₂XC— is preferred.

As a group having a halogenated alkyl group including a group represented by HX₂C— or H₂XC—, an aromatic group, such as phenyl group, and naphthyl group, substituted with the halogenated alkyl group including a group represented by HX₂C— or H₂XC—, a cycloalkyl group, such as cyclopentyl group, and cyclohexyl group, substituted with the halogenated alkyl group including a group represented by HX₂C— or H₂XC—, and the like are exemplified, and the aromatic group substituted with the halogenated alkyl group including a group represented by HX₂C— or H₂XC— is preferred.

As a group having a halogenated alkoxy group including a group represented by HX₂C— or H₂XC—, an aromatic group, such as phenyl group, and naphthyl group, substituted with the halogenated alkoxy group including a group represented by HX₂C— or H₂XC—, an alkyl group, such as methyl group, ethyl group, n-propyl group, and i-propyl group, substituted with the halogenated alkoxy group including a group represented by HX₂C— or H₂XC—, a cycloalkyl group, such as cyclopentyl group, and cyclohexyl group, substituted with the halogenated alkoxy group including a group represented by HX₂C— or H₂XC—, and the like are exemplified, and the aromatic group substituted with the halogenated alkoxy group including a group represented by HX₂C— or H₂XC—.

In addition, a cycloalkyl group, a phenoxyalkyl group that may have a substituent on an aromatic ring, and a phenylthioalkyl group that may have a substituent on an aromatic ring are also preferred as R^{c5}. The substituent that the phenoxyalkyl group and phenylthioalkyl group may have is the same as the substituent that the phenyl group included in R^{c5} may have.

Among the monovalent organic groups, an alkyl group, a cycloalkyl group, an optionally substituted phenyl group or cycloalkyl group, and phenylthioalkyl group that may have a substituent on an aromatic ring are preferred as R. As the alkyl group, an alkyl group having 1 or more and 20 or less carbon atoms is preferred, an alkyl group having 1 or more and 8 or less carbon atoms is more preferred, an alkyl group having 1 or more and 4 or less carbon atoms is particularly preferred, and methyl group is most preferred. Among the optionally substituted phenyl groups, methylphenyl group is preferred, and 2-methylphenyl group is more preferred. The number of carbon atoms in the cycloalkyl group included in the cycloalkylalkyl group is preferably 5 or more and 10 or less, more preferably 5 or more and 8 or less, and particularly preferably 5 or 6. The number of carbon atoms in the alkylene group included in the cycloalkylalkyl group is preferably 1 or more and 8 or less, more preferably 1 or more and 4 or less, and particularly preferably 2. Among the cycloalkylalkyl groups, cyclopentylethyl group is preferred. The number of carbon atoms in the alkylene group included in the phenylthioalkyl group that may have a substituent on the aromatic ring is preferably 1 or more and 8 or less, more preferably 1 or more and 4 or less, and particularly preferably 2. Among the phenylthioalkyl groups that may have a substituent on the aromatic ring, 2-(4-chlorophenylthio)ethyl group is preferred.

In the group represented by the formula (c3), when there is a plurality of R^{c5}s and the plurality of R^{c5}s bonds to each other to form a ring, examples of the ring formed include a hydrocarbon ring, a heterocyclic ring, and the like. As a heteroatom included in the heterocycle, for example, N, O, and S is exemplified. An aromatic ring is particularly preferred as the ring formed by combining a plurality of R^{c5}s each other. Such an aromatic ring may be an aromatic hydrocarbon ring or an aromatic heterocyclic ring. Such an aromatic ring is preferably an aromatic hydrocarbon ring. Specific examples of the group in which a benzene ring is formed by combining a plurality of R^{c5}s in the formula (3) each other are shown below.

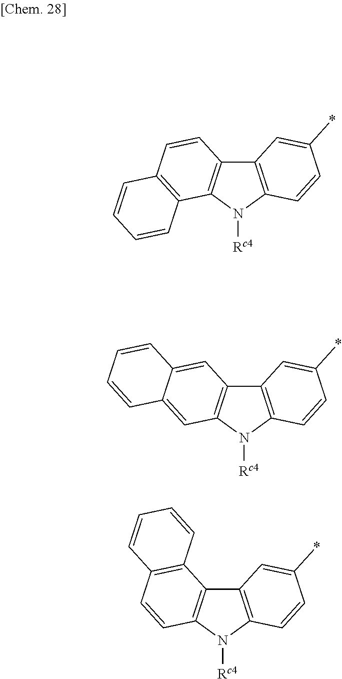

In a group represented by the formula (c4), R^{c8} is a nitro group or a monovalent organic group. R^{c8} bonds to a 6-membered aromatic ring other than an aromatic ring that bonds to a group represented by —(CO)ₙ₁— on a condensed ring in the formula (c4). In the formula (c4), the bond position of R^{c8} is not particularly limited. When a group represented by the formula (c4) has 1 or more R^{c8}s, one of 1 or more R^{c8}s preferably bonds to 7-position in a fluorene skeleton from the viewpoint that a compound having the group represented by the formula (c4) can be easily synthesized. In other words, when a group represented by the formula (c4) has 1 or more R^{c8}s, the group represented by the formula (c4) is preferably a group represented by following formula (c6). When there is a plurality of R^{c8}s, plurality of substituents may be the same or different.

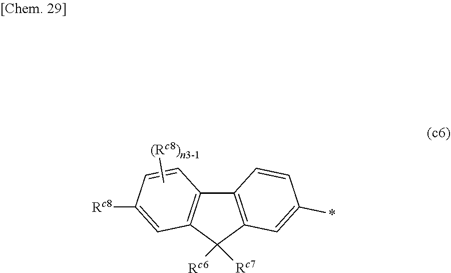

In the formula (c6), R^{c6}, R^{c7}, R^{c8}, and n3 are same as R^{c6}, R^{c7}, R^{c8}, and n3 in the formula (c4).

When R^{c8} is the monovalent organic group, R^{c8} is not particularly limited as long as it does not interfere with the object of the present invention. As the organic group, a carbon atom-containing group is preferred, and a group consisting of one or more carbon atoms, and one or more atoms selected from the group consisting of H, O, S, Se, N, B, P, Si and a halogen atom is more preferred. The number of carbon atoms in the carbon atom-containing group is not particularly limited, and preferably 1 or more and 50 or less, and more preferably 1 or more and 20 or less. Suitable examples of the monovalent organic group as R^{c8} include the same groups as the examples of the monovalent organic group as R^{c5} in the formula (c3).

In the formula (c4), R^{c6} and R^{c7} each represent an optionally substituted chain alkyl group, an optionally substituted chain alkoxy group, an optionally substituted cyclic organic group, or hydrogen atom. R^{c6} and R^{c7} may be combined to one another to form a ring. Among these groups, R^{c6} and R^{c7} are preferably the optionally substituted chain alkyl groups. When R^{c6} and R^{c7} are the optionally substituted chain alkyl groups, the chain alkyl group may be either a straight-chain alkyl group or a branched-chain alkyl group.

When R^{c6} and R^{c7} are chain alkyl groups having no substituent, the number of carbon atoms in the chain alkyl group is preferably 1 or more and 20 or less, more preferably 1 or more and 10 or less, and particularly preferably 1 or more and 6 or less. When R^{c6} and R^{c7} are chain alkyl groups, specific examples thereof include methyl group, ethyl group, n-propyl group, isopropyl group, n-butyl group, isobutyl group, sec-butyl group, tert-butyl group, n-pentyl group, isopentyl group, sec-pentyl group, tert-pentyl group, n-hexyl group, n-heptyl group, n-octyl group, isooctyl group, sec-octyl group, tert-octyl group, n-nonyl group, isononyl group, n-decyl group, isodecyl group, and the like. When R^{c6} and R^{c7} are the alkyl group, the alkyl group may have an ether bond (—O—) in a carbon chain. Examples of the alkyl group having an ether bond in a carbon chain include methoxyethyl group, ethoxyethyl group, methoxyethoxyethyl group, ethoxyethoxyethyl group, propyloxyethoxyethyl group, and methoxypropyl group.

When R^{c6} and R^{c7} are chain alkyl group having a substituent, the number of carbon atoms in the chain alkyl group is preferably 1 or more and 20 or less, more preferably 1 or more and 10 or less, and particularly preferably 1 or more and 6 or less. In this case, the number of carbon atoms in the substituent is not included in the number of carbon atoms in the chain alkyl group. The chain alkyl group having a substituent is preferably a straight-chain group.

The substituent, with which the alkyl group is optionally substituted, is not particularly limited as long as it does not interfere with the object of the present invention. Suitable examples of the substituent include an alkoxy group, cyano group, a halogen atom, a halogenated alkyl group, a cyclic organic group, and an alkoxycarbonyl group. Examples of the halogen atom include fluorine atom, chlorine atom, bromine atom, and iodine atom. Among these, fluorine atom, chlorine atom, and bromine atom are preferred. Examples of the cyclic organic group include a cycloalkyl group, an aromatic hydrocarbon group, and a heterocyclyl group. Specific examples of the cycloalkyl group are the same as suitable examples in case R^{c8} is a cycloalkyl group. Specific examples of the aromatic hydrocarbon group include phenyl group, naphthyl group, biphenylyl group, anthryl group, phenanthryl group, and the like. Specific examples of the heterocyclyl group are the same as suitable examples in case R^{c8} is a heterocyclyl group. When R^{c8} is an alkoxycarbonyl group, an alkoxy group included in the alkoxycarbonyl group may be straight or branched, and preferably straight. The number of carbon atoms in an alkoxy group included in the alkoxycarbonyl group is preferably 1 or more and 10 or less, and more preferably 1 or more and 6 or less.

When the chain alkyl group has a substituent, the number of substituents is not particularly limited. The number of substituents preferably varies depending on the number of carbon atoms in the chain alkyl group. The number of substituents is typically 1 or more and 20 or less, preferably 1 or more and 10 or less, and more preferably 1 or more and 6 or less.

When R^{c6} and R^{c7} are unsubstituted chain alkoxy group, the number of carbon atoms in the chain alkoxy group is preferably 1 or more and 20 or less, more preferably 1 or more and 10 or less, and particularly preferably 1 or more and 6 or less. When R^{c6} and R^{c7} are chain alkoxy group, specific examples thereof include methoxy group, ethoxy group, n-propyloxy group, isopropyloxy group, n-butyloxy group, isobutyloxy group, sec-butyloxy group, tert-butyloxy group, n-pentyloxy group, isopentyloxy group, sec-pentyloxy group, tert-pentyloxy group, n-hexyloxy group, n-heptyloxy group, n-octyloxy group, isooctyloxy group, sec-octyloxy group, tert-octyloxy group, n-nonyloxy group, isononyloxy group, n-decyloxy group, isodecyloxy group, and the like. In addition, when R^{c6} and R^{c7} are alkoxy group, the alkoxy group may include an ether bond (—O—) in the carbon chain. Examples of the alkoxy group having an ether bond in a carbon chain include methoxyethoxy group, ethoxyethoxy group, methoxyethoxyethoxy group, ethoxyethoxyethoxy group, propyloxyethoxyethoxy group, methoxypropyloxy group, and the like.

When R^{c6} and R^{c7} are chain alkoxy groups having a substituent, the substituent that the alkoxy group may have is the same as the substituent that the chain alkyl group as R^{c6} and R^{c7} may have.

When R^{c6} and R^{c7} are cyclic organic group, the cyclic organic group may be an alicyclic group or an aromatic group. Examples of the cyclic organic group include an aliphatic cyclic hydrocarbon group, an aromatic hydrocarbon group, and a heterocyclyl group. When R^{c6} and R^{c7} are cyclic organic group, the substituent, with which the cyclic organic group is optionally substituted, is the same as in the case where R^{c6} and R^{c7} are chain alkyl groups.

When R^{c6} and R^{c7} are aromatic hydrocarbon groups, the aromatic hydrocarbon group is preferably a phenyl group, or a group formed by bonding a plurality of benzene rings through a carbon-carbon bond, or a group formed by condensing a plurality of benzene rings. When the aromatic hydrocarbon group is a phenyl group, or a group formed by bonding or condensing a plurality of benzene rings, the number of benzene rings included in the aromatic hydrocarbon group is not particularly limited, and is preferably 3 or less, more preferably 2 or less, and particularly preferably 1. Suitable specific examples of the aromatic hydrocarbon group include phenyl group, naphthyl group, biphenylyl group, anthryl group, and phenanthryl group.

When R^{c6} and R^{c7} are aliphatic cyclic hydrocarbon groups, the aliphatic cyclic hydrocarbon group may be a monocyclic or polycyclic group. The number of carbon atoms in the aliphatic cyclic hydrocarbon group is not particularly limited, and is preferably 3 or more and 20 or less, and more preferably 3 or more and 10 or less. Examples of the monocyclic cyclic hydrocarbon group include cyclopropyl group, cyclobutyl group, cyclopentyl group, cyclohexyl group, cycloheptyl group, cyclooctyl group, norbornyl group, isobornyl group, tricyclononyl group, tricyclodecyl group, tetracyclododecyl group, and adamantyl group.

When R^{c6} and R^{c7} are heterocyclyl groups, the same groups as the heterocyclyl groups as R^{c5} in the formula (c3) are exemplified.

R^{c6} and R^{c7} may be combined to one another to form a ring. The group composed of the ring formed by R^{c6} and R^{c7} is preferably a cycloalkylidene group. When R^{c6} and R^{c7} are combined to form a cycloalkylidene group, the ring constituting the cycloalkylidene group is preferably a 5- to 6-membered ring, and more preferably a 5-membered ring.

When R^{c7} and a benzene ring in fluorene skeleton are combined to form a ring, the ring may be an aromatic ring or an aliphatic ring.

When the group formed by combining R^{c6} and R^{c7} is a cycloalkylidene group, the cycloalkylidene group may be condensed with one or more other rings. Examples of the ring which may be condensed with the cycloalkylidene group include benzene ring, naphthalene ring, cyclobutane ring, cyclopentane ring, cyclohexane ring, cycloheptane ring, cyclooctane ring, furan ring, thiophene ring, pyrrole ring, pyridine ring, pyrazine ring, pyrimidine ring, and the like.

Examples of a suitable group among R^{c6} and R^{c7} described above include a group represented by the formula: -A¹-A². In the formula, A¹ is a linear alkylene group. A² is an alkoxy group, a cyano group, a halogen atom, a halogenated alkyl group, a cyclic organic group, or an alkoxycarbonyl group.

The number of carbon atoms in the linear alkylene group for A¹ is preferably 1 or more and 10 or less, and more preferably 1 or more and 6 or less. When A² is an alkoxy group, the alkoxy group may be a linear or branched alkoxy group, and preferably a linear alkoxy group. The number of carbon atoms in the alkoxy group is preferably 1 or more and 10 or less, and more preferably 1 or more and 6 or less. When A² is a halogen atom, fluorine atom, chlorine atom, bromine atom, or iodine atom is preferred, and fluorine atom, chlorine atom, or bromine atom is more preferred. When A² is a halogenated alkyl group, a halogen atom included in the halogenated alkyl group is preferably fluorine atom, chlorine atom, bromine atom, or iodine atom, and more preferably is fluorine atom, chlorine atom, or bromine atom. The halogenated alkyl group may be a linear or branched halogenated alkyl group, preferably a linear halogenated alkyl group. When A² is a cyclic organic group, examples of the cyclic organic group are the same as the cyclic organic group possessed by R^{c6} and R^{c7} as a substituent. When A² is an alkoxycarbonyl group, examples of the alkoxycarbonyl group are the same as the alkoxycarbonyl group possessed by R^{c6} and R^{c7} as a substituent.

Suitable specific examples of R^{c6} and R^{c7} include alkyl groups such as ethyl group, n-propyl group, n-butyl group, n-hexyl group, n-heptyl group, and n-octyl group; alkoxyalkyl groups such as 2-methoxyethyl group, 3-methoxy-n-propyl group, 4-methoxy-n-butyl group, 5-methoxy-n-pentyl group, 6-methoxy-n-hexyl group, 7-methoxy-n-heptyl group, 8-methoxy-n-octyl group, 2-ethoxyethyl group, 3-ethoxy-n-propyl group, 4-ethoxy-n-butyl group, 5-ethoxy-n-pentyl group, 6-ethoxy-n-hexyl group, 7-ethoxy-n-heptyl group, and 8-ethoxy-n-octyl group; cyanoalkyl groups such as 2-cyanoethyl group, 3-cyano-n-propyl group, 4-cyano-n-butyl group, 5-cyano-n-pentyl group, 6-cyano-n-hexyl group, 7-cyano-n-heptyl group, and 8-cyano-n-octyl group; phenylalkyl groups such as 2-phenylethyl group, 3-phenyl-n-propyl group, 4-phenyl-n-butyl group, 5-phenyl-n-pentyl group, 6-phenyl-n-hexyl group, 7-phenyl-n-heptyl group, and 8-phenyl-n-octyl group; cycloalkylalkyl groups such as 2-cyclohexylethyl group, 3-cyclohexyl-n-propyl group, 4-cyclohexyl-n-butyl group, 5-cyclohexyl-n-pentyl group, 6-cyclohexyl-n-hexyl group, 7-cyclohexyl-n-heptyl group, 8-cyclohexyl-n-octyl group, 2-cyclopentylethyl group, 3-cyclopentyl-n-propyl group, 4-cyclopentyl-n-butyl group, 5-cyclopentyl-n-pentyl group, 6-cyclopentyl-n-hexyl group, 7-cyclopentyl-n-heptyl group, and 8-cyclopentyl-n-octyl group; alkoxycarbonylalkyl groups such as 2-methoxycarbonylethyl group, 3-methoxycarbonyl-n-propyl group, 4-methoxycarbonyl-n-butyl group, 5-methoxycarbonyl-n-pentyl group, 6-methoxycarbonyl-n-hexyl group, 7-methoxycarbonyl-n-heptyl group, 8-methoxycarbonyl-n-octyl group, 2-ethoxycarbonylethyl group, 3-ethoxycarbonyl-n-propyl group, 4-ethoxycarbonyl-n-butyl group, 5-ethoxycarbonyl-n-pentyl group, 6-ethoxycarbonyl-n-hexyl group, 7-ethoxycarbonyl-n-heptyl group, and 8-ethoxycarbonyl-n-octyl group; and halogenated alkyl groups such as 2-chloroethyl group, 3-chloro-n-propyl group, 4-chloro-n-butyl group, 5-chloro-n-pentyl group, 6-chloro-n-hexyl group, a 7-chloro-n-heptyl group, 8-chloro-n-octyl group, 2-bromoethyl group, 3-bromo-n-propyl group, 4-bromo-n-butyl group, 5-bromo-n-pentyl group, 6-bromo-n-hexyl group, 7-bromo-n-heptyl group, 8-bromo-n-octyl group, 3,3,3-trifluoropropyl group, and 3,3,4,4,5,5,5-heptafluoro-n-pentyl group.

Among groups mentioned above, Suitable groups as R^{c6} and R^{c7} are ethyl group, n-propyl group, n-butyl group, n-pentyl group, 2-methoxyethyl group, 2-cyanoethyl group, 2-phenylethyl group, 2-cyclohexylethyl group, 2-methoxycarbonylethyl group, 2-chloroethyl group, 2-bromoethyl group, 3,3,3-trifluoropropyl group, and 3,3,4,4,5,5,5-heptafluoro-n-pentyl group.

From the view point that a highly sensitive photopolymerization polymerization initiator is likely to be easily obtained, A is preferably S.

In the formula (c5), R^{c9} is a monovalent organic group, a halogen atom, nitro group, or cyano group. When R^{c9} in the formula (c5) is the monovalent organic group, the monovalent organic group can be selected from various organic groups as long as it does not interfere with the object of the present invention. As the organic group, a carbon atom-containing group is preferred, and a group consisting of one or more carbon atoms, and one or more atoms selected from the group consisting of H, O, S, Se, N, B, P, Si and a halogen atom is more preferred. The number of carbon atoms in the carbon atom-containing group is not particularly limited, and preferably 1 or more and 50 or less, and more preferably 1 or more and 20 or less. Suitable examples of the organic group as R^{c9} in the formula (c5) are the same groups as the monovalent organic groups as R^{c5} in the formula (c5).

Among R^{c9}, benzoyl group; naphthoyl group; benzoyl groups substituted with a group selected from the group consisting of an alkyl group having 1 or more and 6 or less carbon atoms, morpholin-1-yl group, piperazin-1-yl group, and a phenyl group; nitro group; optionally substituted benzofuranylcarbonyl group are preferred, and benzoyl group; naphthoyl group; 2-methylphenylcarbonyl group; 4-(piperazin-1-yl)phenylcarbonyl group; and 4-(phenyl)phenylcarbonyl group are more preferred.

In addition, in the formula (c5), n4 is preferably an integer of 0 or more and 3 or less, more preferably an integer of 0 or more and 2 or less, and particularly preferably 0 or 1. When n4 is 1, the position at which R^{c9} bonds is preferably the para-position relative to the bonding through which the phenyl group (to which R^{c9} bonds) bonds to an oxygen atom or a sulfur atom.

In the formula (c1) and the formula (c2), the monovalent organic group as R^{c2} is not particularly limited as long as it does not interfere with the object of the present invention. As the organic group, a carbon atom-containing group is preferred, and a group consisting of one or more carbon atoms, and one or more atoms selected from the group consisting of H, O, S, Se, N, B, P, Si and a halogen atom is more preferred. The number of carbon atoms in the carbon atom-containing group is not particularly limited, and preferably 1 or more and 50 or less, and more preferably 1 or more and 20 or less. Suitable examples of the monovalent organic group as R^{c2} are the same groups as the monovalent organic groups as R^{c5} in the formula (c3). Specific examples of these groups are the same as the groups described for R^{c5} in the formula (c3). In addition, a cycloalkyl group, a phenoxyalkyl group that may have a substituent on an aromatic ring, and a phenylthioalkyl group that may have a substituent on an aromatic ring are also preferred as R^{c2}. The substituent that the phenoxyalkyl group and phenylthioalkyl group may have is the same as the substituent that the phenyl group, the naphthyl group, and the heterocyclyl group included in R^{c5} in the formula (c3) may have.

Among substituents, a substituent including the group represented by HX₂C— or H₂XC— described above, an alkyl group, a cycloalkyl group, an optionally substituted phenyl group, an optionally substituted cycloalkyl group, and a phenylthioalkyl group that may have a substituent on an aromatic ring are preferred. The alkyl group, the optionally substituted alkyl group, the number of carbon atoms in the cycloalkyl group included in the cycloalkylalkyl group, the cycloalkylalkyl group, the number of carbon atoms in the alkylene group included in the phenylthioalkyl group that may have a substituent on an aromatic ring, and the phenylthioalkyl group that may have a substituent on an aromatic ring are the same as these about R^{c5} in the formula (c3).

A group represented by -A³-CO—O-A⁴ is also preferred as R^{c2}. A³ is a divalent organic group, preferably a divalent hydrocarbon group, and more preferably an alkylene group. A⁴ is a monovalent organic group, and preferably a monovalent hydrocarbon group.

When A³ is the alkylene group, the alkylene group may be straight or branched, and is preferably straight. When A³ is the alkylene group, the number of carbon atoms in the alkylene group is preferably 1 or more and 10 or less, more preferably 1 or more and 6 or less, and particularly preferably 1 or more and 4 or less.

Suitable examples of A⁴ include an alkyl group having 1 or more and 10 or less carbon atoms, an aralkyl group having 7 or more and 20 or less carbon atoms, and an aromatic hydrocarbon group having 6 or more and 20 or less carbon atoms. Suitable specific examples of A⁴ include methyl group, ethyl group, n-propyl group, isopropyl group, n-butyl group, isobutyl group, sec-butyl group, tert-butyl group, n-pentyl group, n-hexyl group, phenyl group, naphthyl group, benzyl group, phenethyl group, α-naphthylmethyl group, β-naphthylmethyl group, and the like.

Specific examples of a suitable group represented by -A³-CO—O-A4 include 2-methoxycarbonylethyl group, 2-ethoxycarbonylethyl group, 2-n-propyloxycarbonylethyl group, 2-n-butyloxycarbonylethyl group, 2-n-pentyloxycarbonylethyl group, 2-n-hexyloxycarbonylethyl group, 2-benzyloxycarbonylethyl group, 2-phenoxycarbonylethyl group, 3-methoxycarbonyl-n-propyl group, 3-ethoxycarbonyl-n-propyl group, n-propyloxycarbonyl-n-propyl group, 3-n-butyloxycarbonyl-n-propyl group, 3-n-pentyloxycarbonyl-n-propyl group, 3-n-hexyloxycarbonyl-n-propyl group, 3-benzyloxycarbonyl-n-propyl group, 3-phenoxycarbonyl-n-propyl group, and the like.

A group represented by the following formula (c7) or the following formula (c8) is also preferred as R^{c2}.

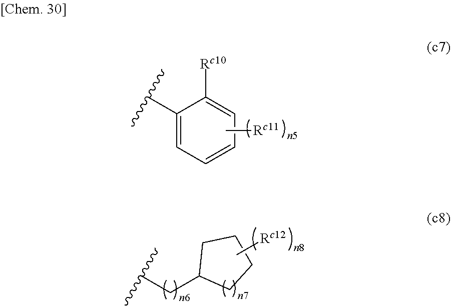

In the formulas (c7) and (c8), R^{c10} and R^{c11} are each independently a monovalent organic group. n5 is an integer of 0 or more and 4 or less. when R^{c10} and R^{c11} are adjacent to each other on the benzene ring, R^{c10} and R^{c11} may be combined to each other to form a ring. R^{c12} is a monovalent organic group. n6 is an integer of 1 or more and 8 or less. n7 is an integer of 1 or more and 5 or less. n8 is an integer of 0 or more and (n7+3) or less.

The organic group as R^{c10} and R^{c11} in the formula (c7) is the same as R^{c8} in the formula (c4). As R^{c10}, a halogenated alkoxy group including a group represented by HX₂C— or H₂XC—, a halogenated alkyl group including a group represented by HX₂C— or H₂XC—, an alkyl group, or a phenyl group is preferred. When R^{c10} and R^{c11} are combined to each other to form a ring, the ring may be an aromatic ring or an aliphatic ring. Suitable examples of the group represented by the formula (c7) in which R^{c10} and R^{c11} form a ring include naphthalen-1-yl group, 1,2,3,4-tetrahydronaphthalen-5-yl group, and the like. In the formula (c7), n5 is an integer of 0 or more and 5 or less, preferably 0 or 1, and more preferably 0.

In the above formula (c8), R^{c12} is an organic group. As the organic group, the same group as the organic group described above as R^{c6} in the formula (c4) is exemplified. Among the organic groups, an alkyl group is preferred. The alkyl group may be straight or branched. The number of carbon atoms in the alkyl group is preferably 1 or more and 10 or less, more preferably 1 or more and 5 or less, and particularly preferably 1 or more and 3 or less. Methyl group, ethyl group, propyl group, isopropyl group, butyl group, and the like are preferably exemplified as R^{c12}. Among these, methyl group is preferred.

In the above formula (c8), n7 is an integer of 1 or more and 5 or less, preferably an integer of 1 or more and 3 or less, and more preferably 1 or 2. In the above formula (c8), n8 is 0 or more and (n7+3) or less, preferably an integer of 0 or more and 3 or less, more preferably an integer of 0 or more and 2 or less, and particularly preferably 0. In the above formula (c8), n6 is an integer of 1 or more and 8 or less, preferably an integer of 1 or more and 5 or less, further preferably an integer of 1 or more and 3 or less, and particularly preferably 1 or 2.

In the formula (c2), R^{c3} is hydrogen atom, an optionally substituted aliphatic hydrocarbon group having 1 or more and 20 or less carbon atoms, or an optionally substituted aryl group. When R^{c3} is the aliphatic hydrocarbon group, preferable examples of the substituent which may be possessed by the aliphatic hydrocarbon group includes phenyl group, naphthyl group and the like.

In the formula (c1) and (c2), suitable examples of R^{c3} include hydrogen atom, methyl group, ethyl group, n-propyl group, isopropyl group, n-butyl group, 2-cyclopentylethyl group, 2-cyclobutylethyl group, cyclohexylmethyl group, phenyl group, benzyl group, methylphenyl group, naphthyl group, and the like. Among these, methyl group or phenyl group is more preferred.

Preferable specific examples of the compound represented by the formula (c2) and having the group represented by the formula (c3) as R^{c1} include the following compounds.

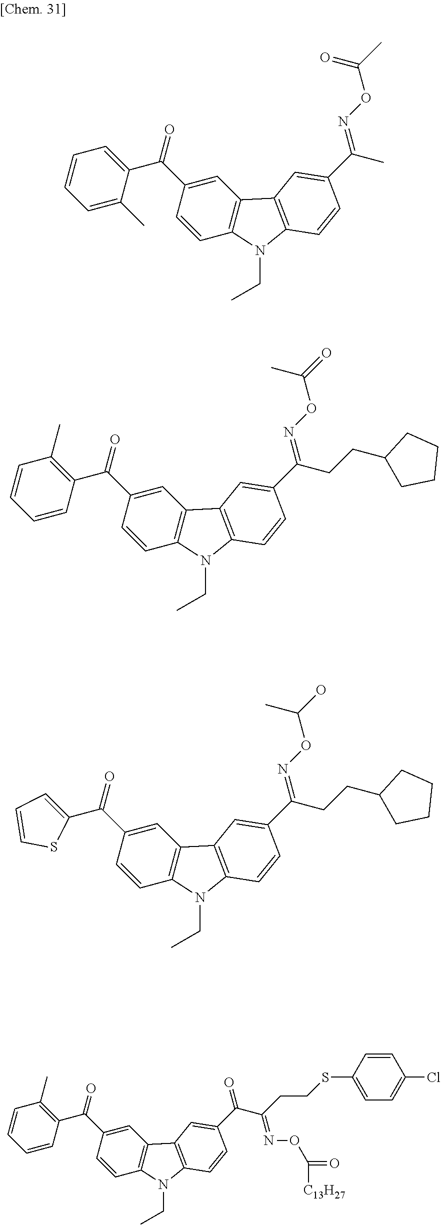

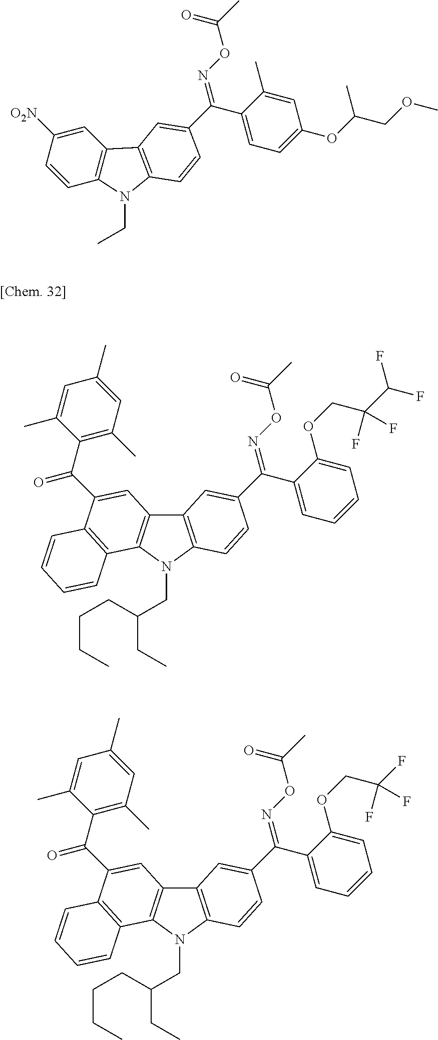

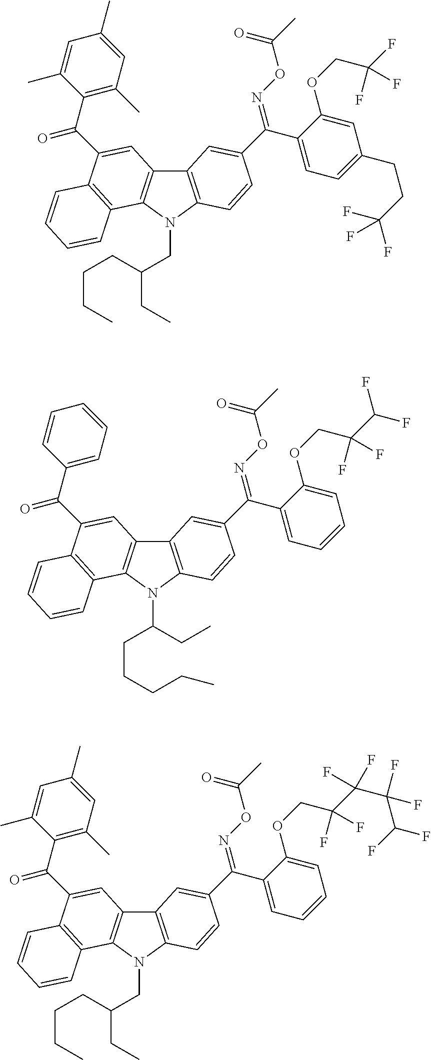 [SMILES: CCCCC(CC)Cn1c2ccc(/C(=N/OC(C)=O)c3ccc(CCC(F)(F)F)cc3OCC(F)(F)F)cc2c2cc(C(=O)c3c(C)cc(C)cc3C)c3ccccc3c21 ; CCCCCC(CC)n1c2ccc(/C(=N/OC(C)=O)c3ccccc3OCC(F)(F)C(F)F)cc2c2cc(C(=O)c3ccccc3)c3ccccc3c21 ; CCCCC(CC)Cn1c2ccc(/C(=N/OC(C)=O)c3ccccc3OCC(F)(F)C(F)(F)C(F)(F)C(F)F)cc2c2cc(C(=O)c3c(C)cc(C)cc3C)c3ccccc3c21]

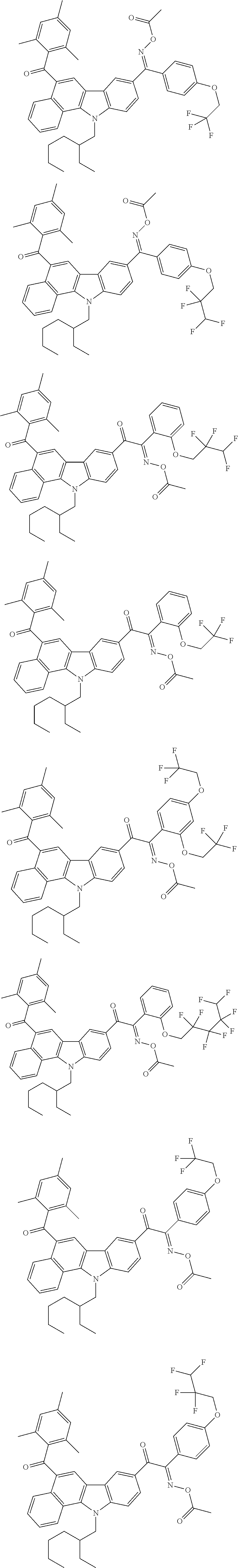

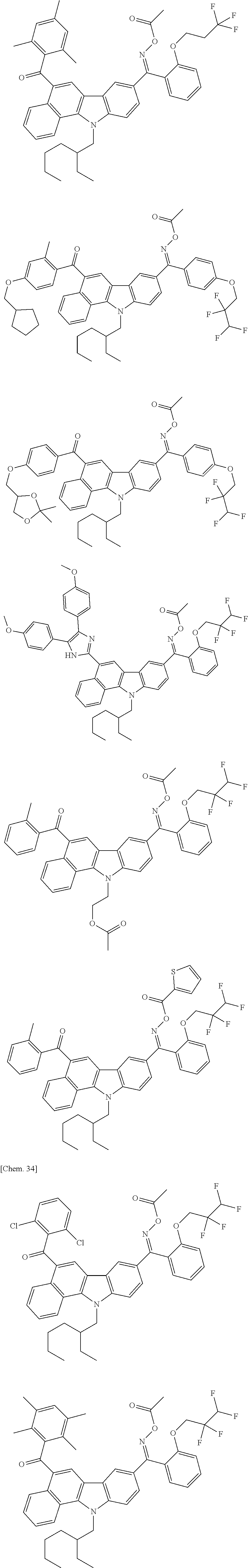

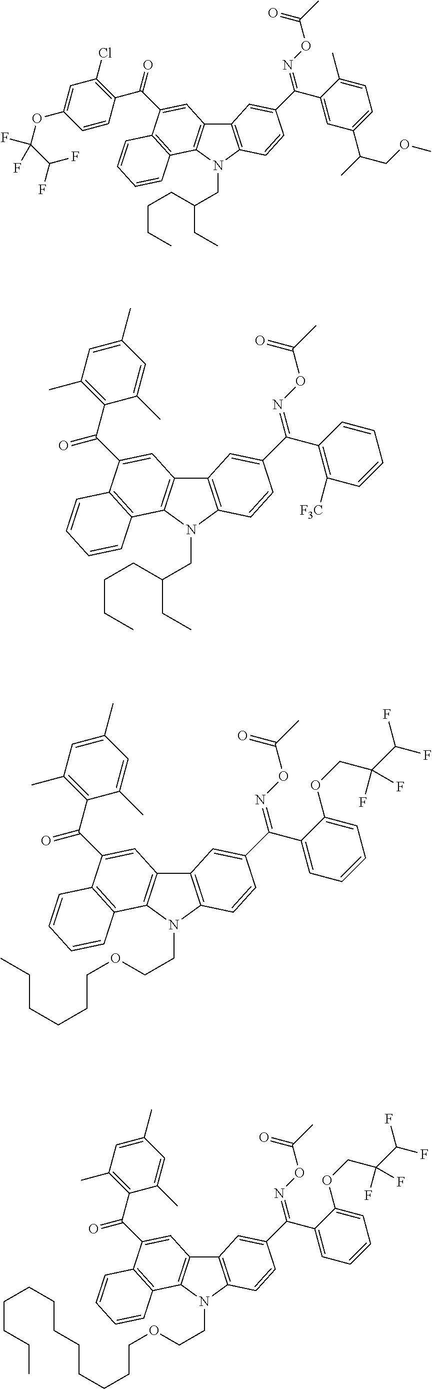

Preferable specific examples of the compound represented by the formula (c2) and having the group represented by the formula (c4) as R^{c1} include the following compounds.

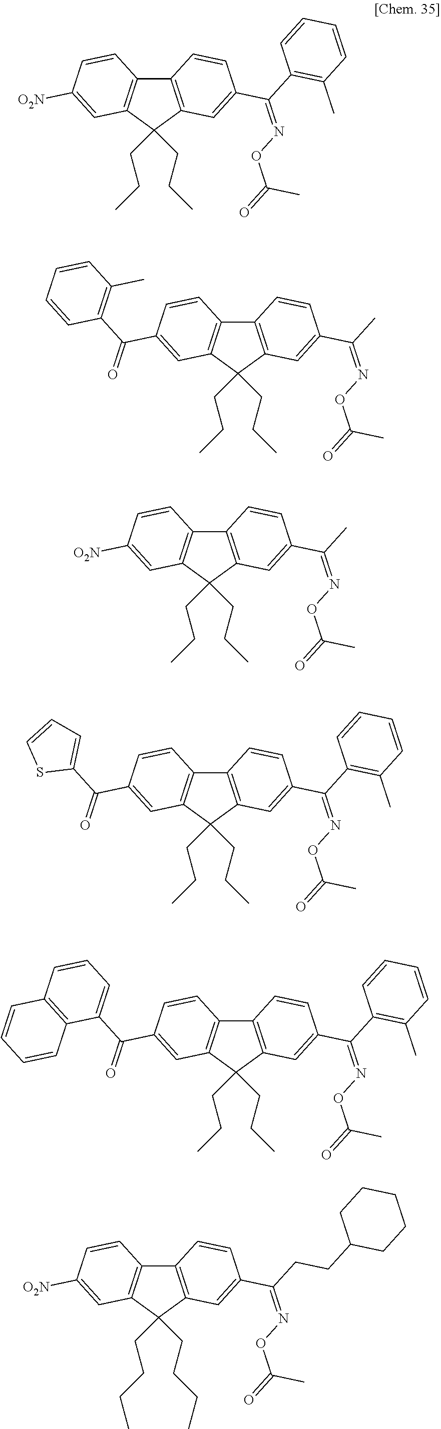 [SMILES: CCCC1(CCC)c2cc(/C(=N\OC(C)=O)c3ccccc3C)ccc2-c2ccc([N+](=O)[O-])cc21 ; CCCC1(CCC)c2cc(C(=O)c3ccccc3C)ccc2-c2ccc(/C(C)=N\OC(C)=O)cc21 ; CCCC1(CCC)c2cc(/C(C)=N\OC(C)=O)ccc2-c2ccc([N+](=O)[O-])cc21 ; CCCC1(CCC)c2cc(C(=O)c3cccs3)ccc2-c2ccc(/C(=N\OC(C)=O)c3ccccc3C)cc21 ; CCCC1(CCC)c2cc(C(=O)c3cccc4ccccc34)ccc2-c2ccc(/C(=N\OC(C)=O)c3ccccc3C)cc21 ; CCCCC1(CCCC)c2cc(/C(CCC3CCCCC3)=N\OC(C)=O)ccc2-c2ccc([N+](=O)[O-])cc21]

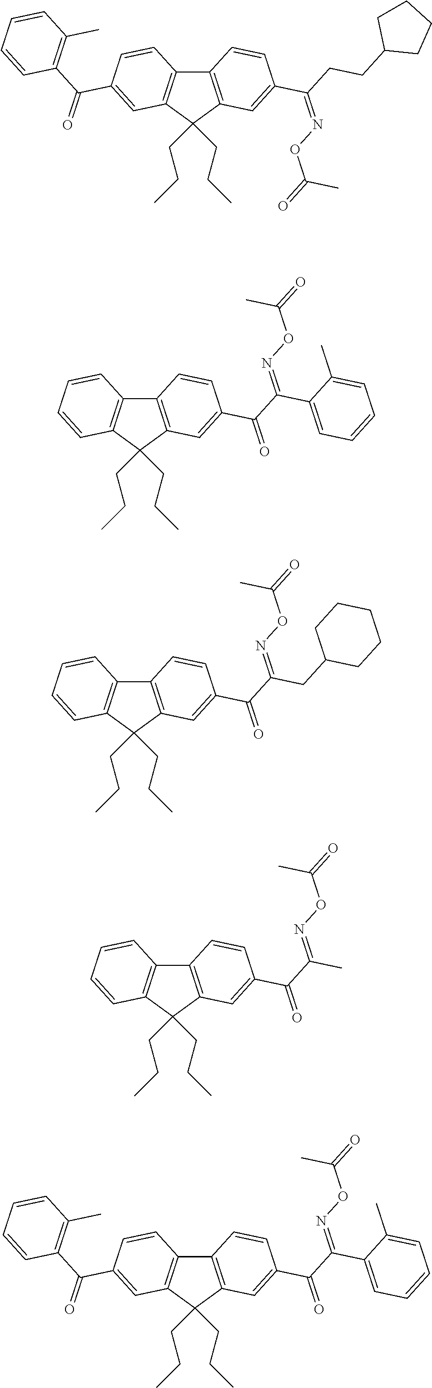 [SMILES: CCCC1(CCC)c2cc(C(=O)c3ccccc3C)ccc2-c2ccc(/C(CCC3CCCC3)=N\OC(C)=O)cc21 ; CCCC1(CCC)c2ccccc2-c2ccc(C(=O)/C(=N/OC(C)=O)c3ccccc3C)cc21 ; CCCC1(CCC)c2ccccc2-c2ccc(C(=O)/C(CC3CCCCC3)=N/OC(C)=O)cc21 ; CCCC1(CCC)c2ccccc2-c2ccc(C(=O)/C(C)=N/OC(C)=O)cc21 ; CCCC1(CCC)c2cc(C(=O)/C(=N/OC(C)=O)c3ccccc3C)ccc2-c2ccc(C(=O)c3ccccc3C)cc21]

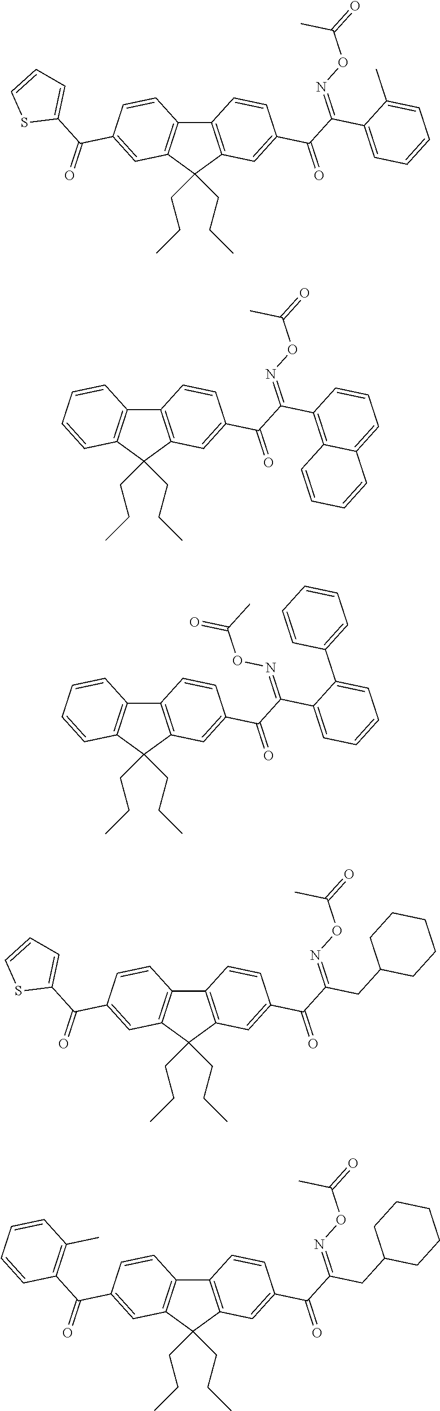 [SMILES: CCCC1(CCC)c2cc(C(=O)/C(=N/OC(C)=O)c3ccccc3C)ccc2-c2ccc(C(=O)c3cccs3)cc21 ; CCCC1(CCC)c2ccccc2-c2ccc(C(=O)/C(=N/OC(C)=O)c3cccc4ccccc34)cc21 ; CCCC1(CCC)c2ccccc2-c2ccc(C(=O)/C(=N\OC(C)=O)c3ccccc3-c3ccccc3)cc21 ; CCCC1(CCC)c2cc(C(=O)/C(CC3CCCCC3)=N/OC(C)=O)ccc2-c2ccc(C(=O)c3cccs3)cc21 ; CCCC1(CCC)c2cc(C(=O)/C(CC3CCCCC3)=N/OC(C)=O)ccc2-c2ccc(C(=O)c3ccccc3C)cc21]

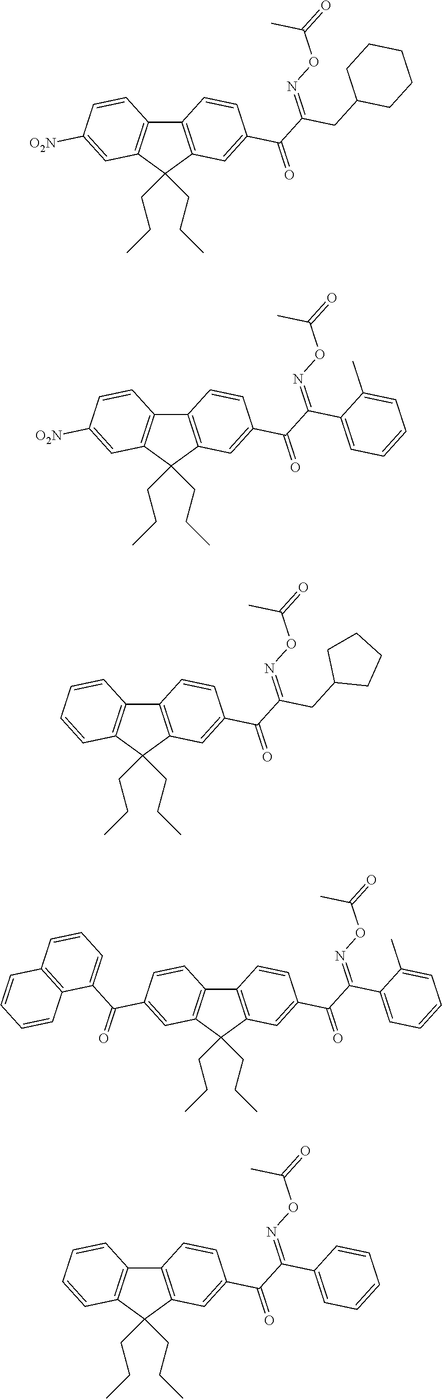 [SMILES: CCCC1(CCC)c2cc(C(=O)/C(CC3CCCCC3)=N/OC(C)=O)ccc2-c2ccc([N+](=O)[O-])cc21 ; CCCC1(CCC)c2cc(C(=O)/C(=N/OC(C)=O)c3ccccc3C)ccc2-c2ccc([N+](=O)[O-])cc21 ; CCCC1(CCC)c2ccccc2-c2ccc(C(=O)/C(CC3CCCC3)=N/OC(C)=O)cc21 ; CCCC1(CCC)c2cc(C(=O)/C(=N/OC(C)=O)c3ccccc3C)ccc2-c2ccc(C(=O)c3cccc4ccccc34)cc21 ; CCCC1(CCC)c2ccccc2-c2ccc(C(=O)/C(=N/OC(C)=O)c3ccccc3)cc21]

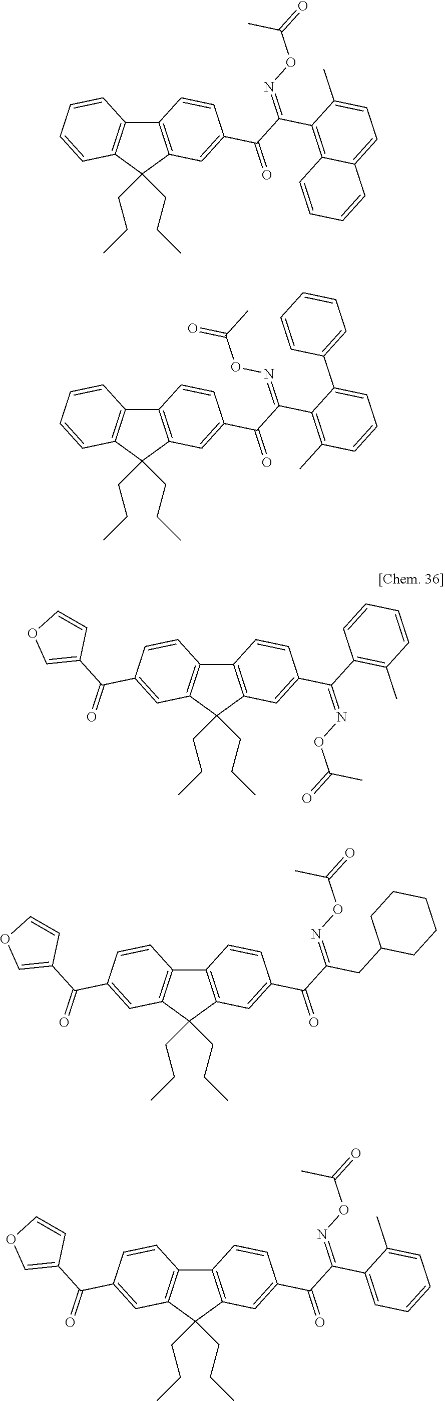 [SMILES: CCCC1(CCC)c2ccccc2-c2ccc(C(=O)/C(=N/OC(C)=O)c3c(C)ccc4ccccc34)cc21 ; CCCC1(CCC)c2ccccc2-c2ccc(C(=O)/C(=N\OC(C)=O)c3c(C)cccc3-c3ccccc3)cc21 ; CCCC1(CCC)c2cc(C(=O)c3ccoc3)ccc2-c2ccc(/C(=N\OC(C)=O)c3ccccc3C)cc21 ; CCCC1(CCC)c2cc(C(=O)/C(CC3CCCCC3)=N/OC(C)=O)ccc2-c2ccc(C(=O)c3ccoc3)cc21 ; CCCC1(CCC)c2cc(C(=O)/C(=N/OC(C)=O)c3ccccc3C)ccc2-c2ccc(C(=O)c3ccoc3)cc21]

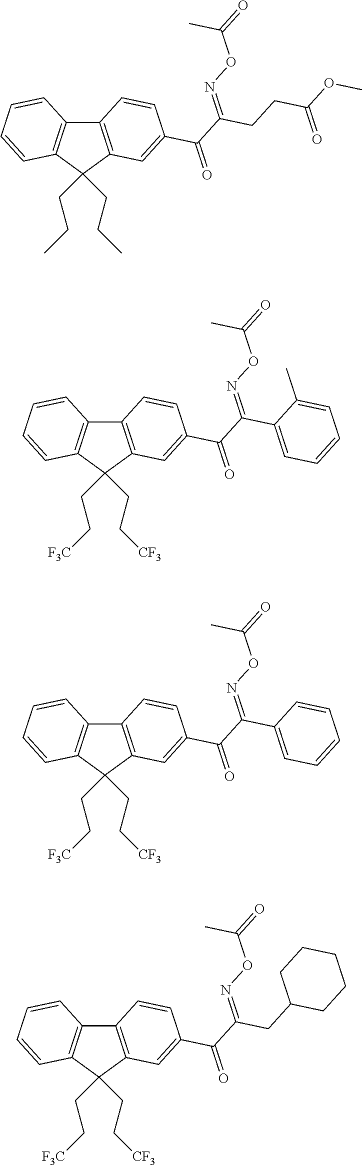 [SMILES: CCCC1(CCC)c2ccccc2-c2ccc(C(=O)/C(CCC(=O)OC)=N/OC(C)=O)cc21 ; CC(=O)O/N=C(/C(=O)c1ccc2c(c1)C(CCC(F)(F)F)(CCC(F)(F)F)c1ccccc1-2)c1ccccc1C ; CC(=O)O/N=C(/C(=O)c1ccc2c(c1)C(CCC(F)(F)F)(CCC(F)(F)F)c1ccccc1-2)c1ccccc1 ; CC(=O)O/N=C(\CC1CCCCC1)C(=O)c1ccc2c(c1)C(CCC(F)(F)F)(CCC(F)(F)F)c1ccccc1-2]

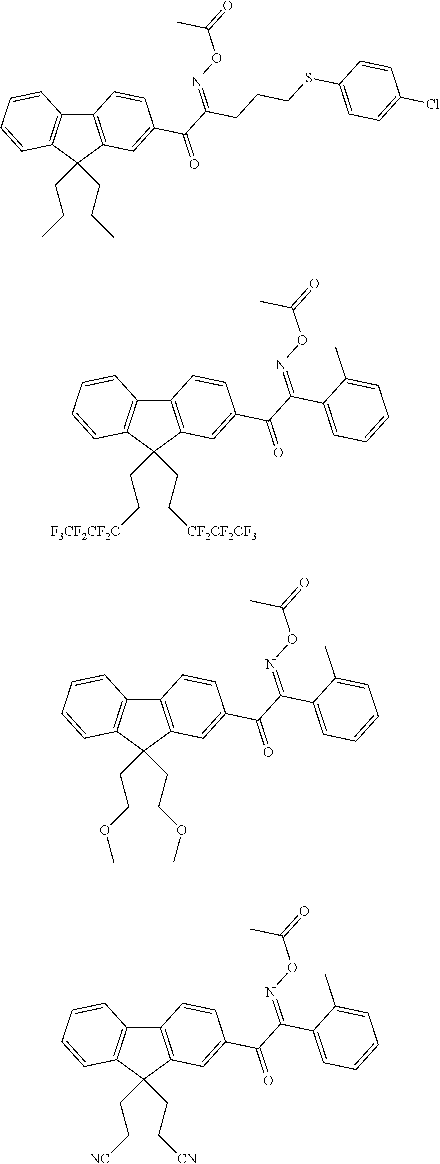

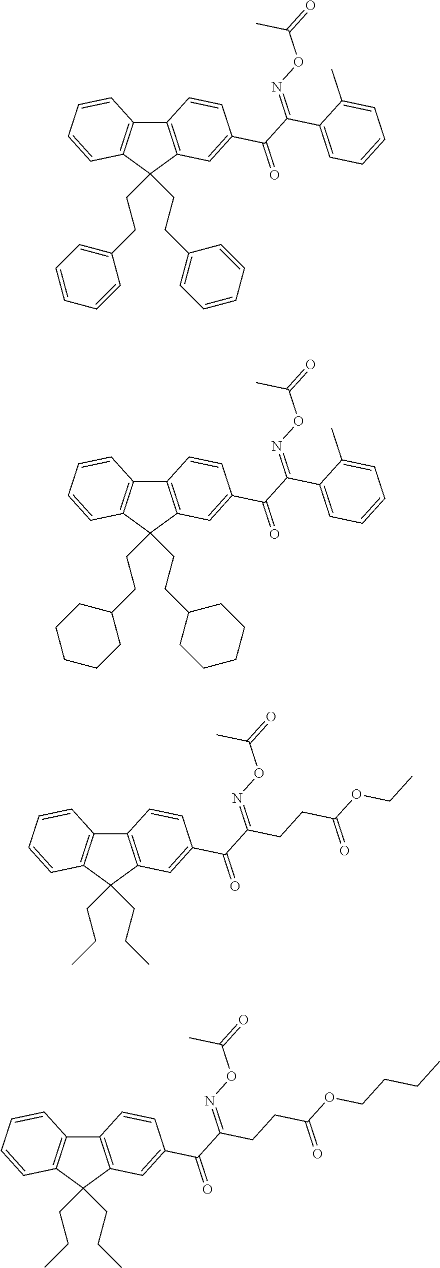 [SMILES: CC(=O)O/N=C(/C(=O)c1ccc2c(c1)C(CCc1ccccc1)(CCc1ccccc1)c1ccccc1-2)c1ccccc1C ; CC(=O)O/N=C(/C(=O)c1ccc2c(c1)C(CCC1CCCCC1)(CCC1CCCCC1)c1ccccc1-2)c1ccccc1C ; CCCC1(CCC)c2ccccc2-c2ccc(C(=O)/C(CCC(=O)OCC)=N/OC(C)=O)cc21 ; CCCCOC(=O)CC/C(=N\OC(C)=O)C(=O)c1ccc2c(c1)C(CCC)(CCC)c1ccccc1-2]

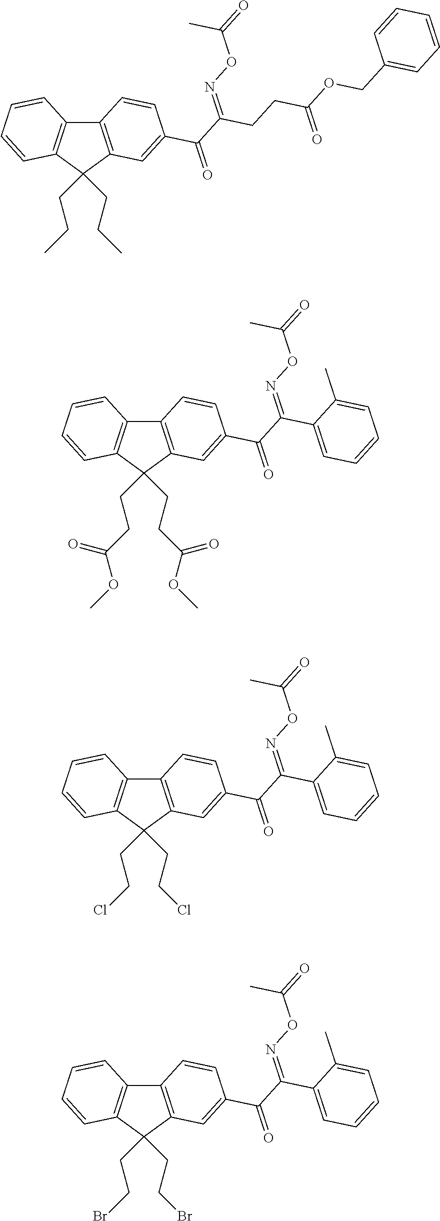 [SMILES: CCCC1(CCC)c2ccccc2-c2ccc(C(=O)/C(CCC(=O)OCc3ccccc3)=N/OC(C)=O)cc21 ; COC(=O)CCC1(CCC(=O)OC)c2ccccc2-c2ccc(C(=O)/C(=N/OC(C)=O)c3ccccc3C)cc21 ; CC(=O)O/N=C(/C(=O)c1ccc2c(c1)C(CCCl)(CCCl)c1ccccc1-2)c1ccccc1C ; CC(=O)O/N=C(/C(=O)c1ccc2c(c1)C(CCBr)(CCBr)c1ccccc1-2)c1ccccc1C]

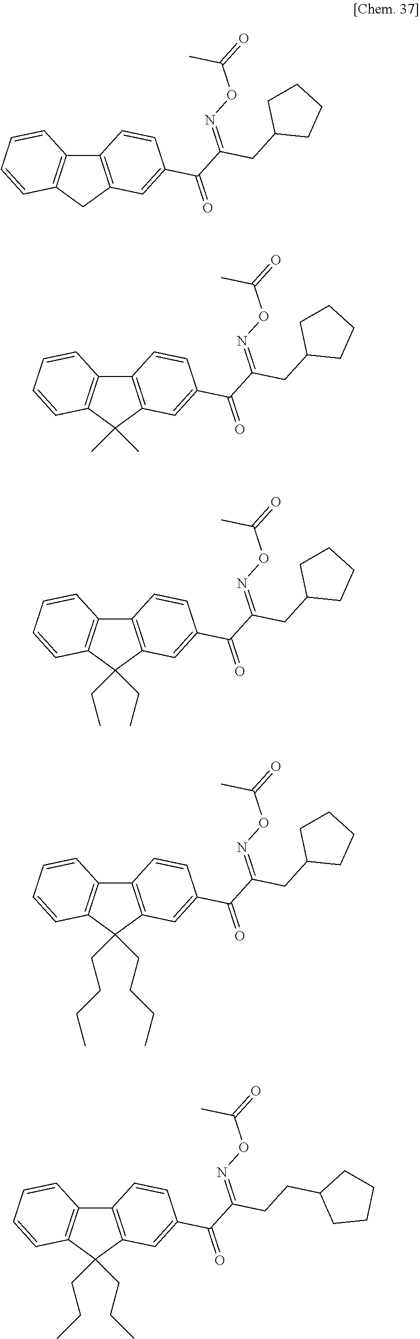 [SMILES: CC(=O)O/N=C(\CC1CCCC1)C(=O)c1ccc2c(c1)Cc1ccccc1-2 ; CC(=O)O/N=C(\CC1CCCC1)C(=O)c1ccc2c(c1)C(C)(C)c1ccccc1-2 ; CCC1(CC)c2ccccc2-c2ccc(C(=O)/C(CC3CCCC3)=N/OC(C)=O)cc21 ; CCCCC1(CCCC)c2ccccc2-c2ccc(C(=O)/C(CC3CCCC3)=N/OC(C)=O)cc21 ; CCCC1(CCC)c2ccccc2-c2ccc(C(=O)/C(CCC3CCCC3)=N/OC(C)=O)cc21]

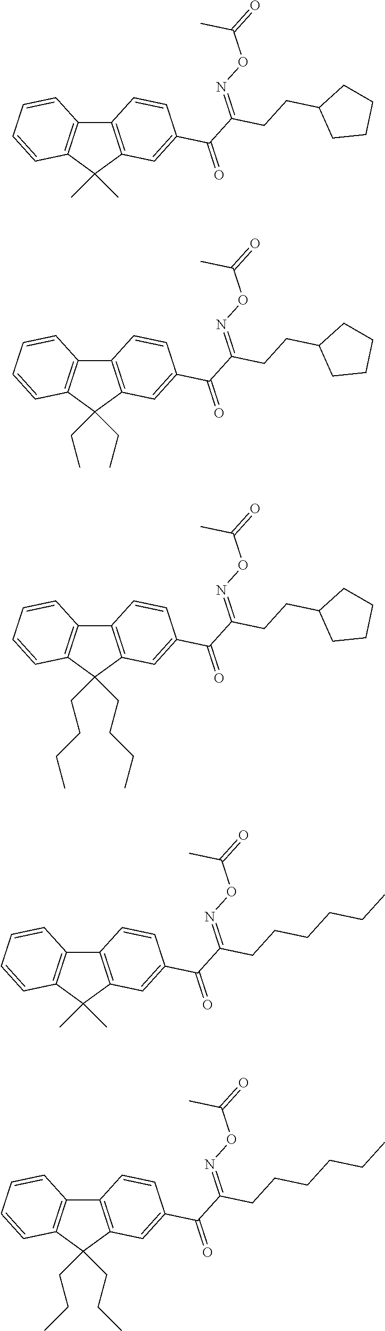 [SMILES: CC(=O)O/N=C(\CCC1CCCC1)C(=O)c1ccc2c(c1)C(C)(C)c1ccccc1-2 ; CCC1(CC)c2ccccc2-c2ccc(C(=O)/C(CCC3CCCC3)=N/OC(C)=O)cc21 ; CCCCC1(CCCC)c2ccccc2-c2ccc(C(=O)/C(CCC3CCCC3)=N/OC(C)=O)cc21 ; CCCCCC/C(=N\OC(C)=O)C(=O)c1ccc2c(c1)C(C)(C)c1ccccc1-2 ; CCCCCC/C(=N\OC(C)=O)C(=O)c1ccc2c(c1)C(CCC)(CCC)c1ccccc1-2]

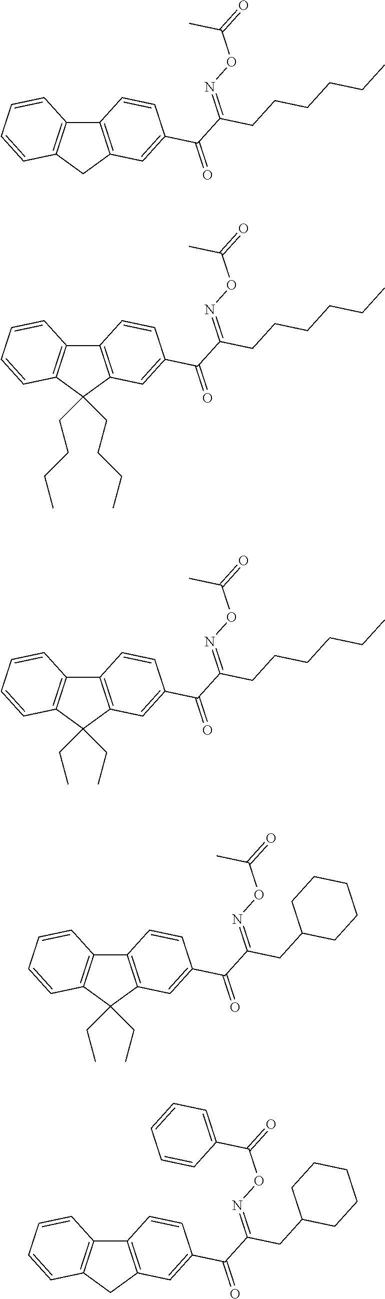 [SMILES: CCCCCC/C(=N\OC(C)=O)C(=O)c1ccc2c(c1)Cc1ccccc1-2 ; CCCCCC/C(=N\OC(C)=O)C(=O)c1ccc2c(c1)C(CCCC)(CCCC)c1ccccc1-2 ; CCCCCC/C(=N\OC(C)=O)C(=O)c1ccc2c(c1)C(CC)(CC)c1ccccc1-2 ; CCC1(CC)c2ccccc2-c2ccc(C(=O)/C(CC3CCCCC3)=N/OC(C)=O)cc21 ; O=C(O/N=C(\CC1CCCCC1)C(=O)c1ccc2c(c1)Cc1ccccc1-2)c1ccccc1]

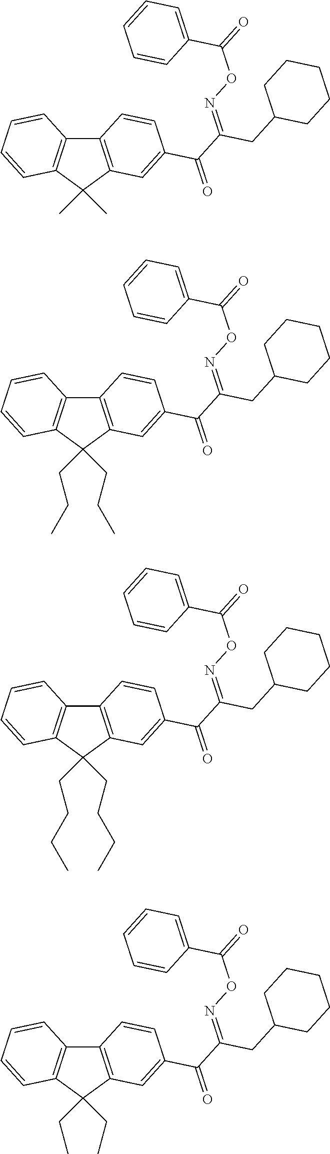

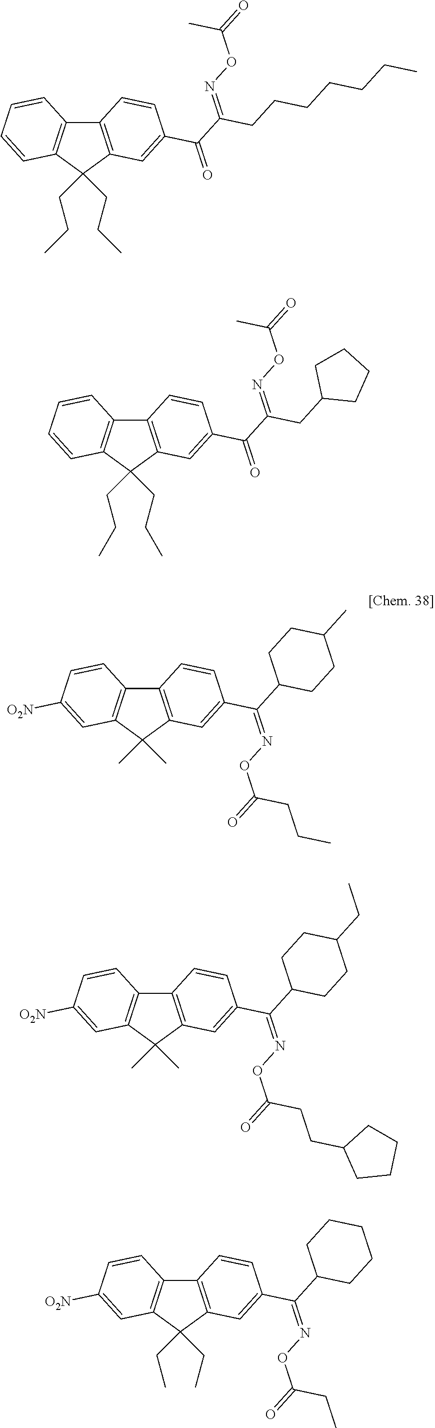

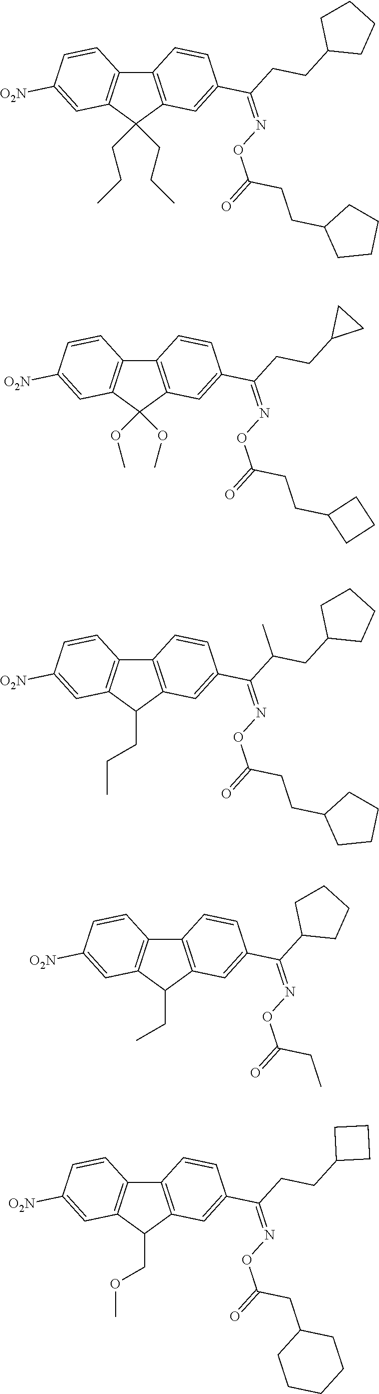

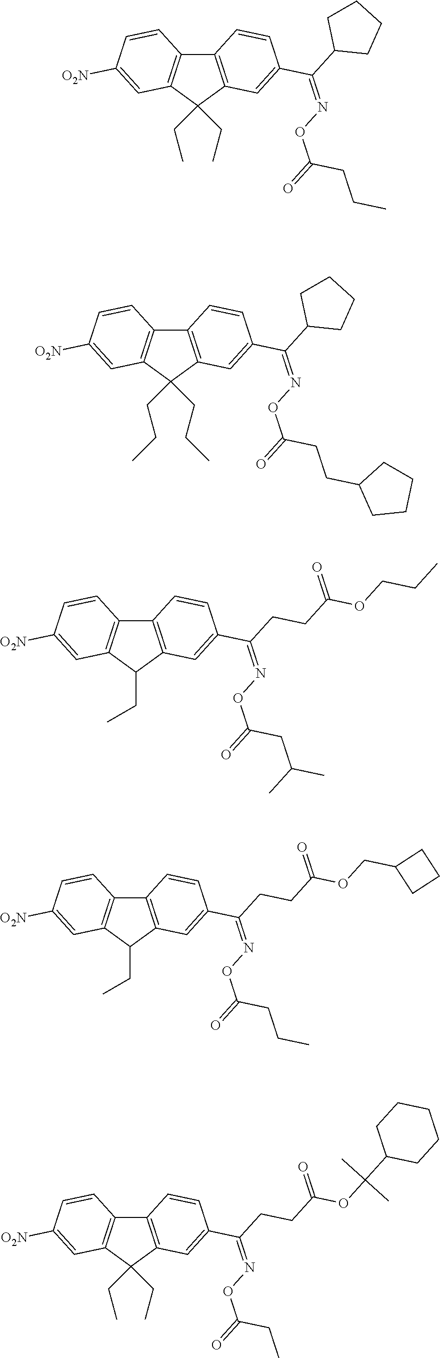 [SMILES: CCCC(=O)O/N=C(\c1ccc2c(c1)C(CC)(CC)c1cc([N+](=O)[O-])ccc1-2)C1CCCC1 ; CCCC1(CCC)c2cc(/C(=N\OC(=O)CCC3CCCC3)C3CCCC3)ccc2-c2ccc([N+](=O)[O-])cc21 ; CCCOC(=O)CC/C(=N/OC(=O)CC(C)C)c1ccc2c(c1)C(CC)c1cc([N+](=O)[O-])ccc1-2 ; CCCC(=O)O/N=C(/CCC(=O)OCC1CCC1)c1ccc2c(c1)C(CC)c1cc([N+](=O)[O-])ccc1-2 ; CCC(=O)O/N=C(/CCC(=O)OC(C)(C)C1CCCCC1)c1ccc2c(c1)C(CC)(CC)c1cc([N+](=O)[O-])ccc1-2]

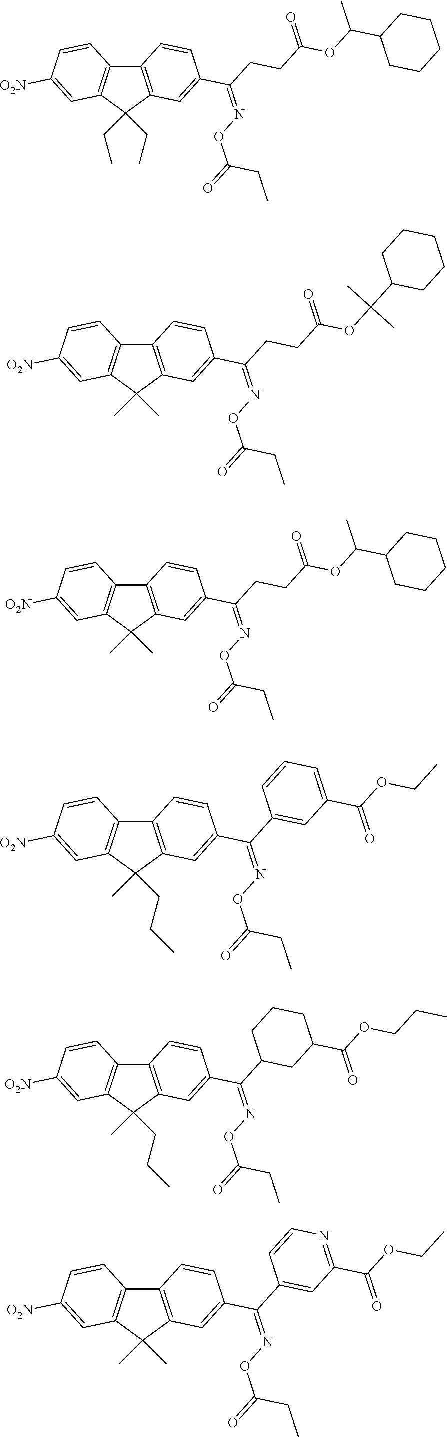

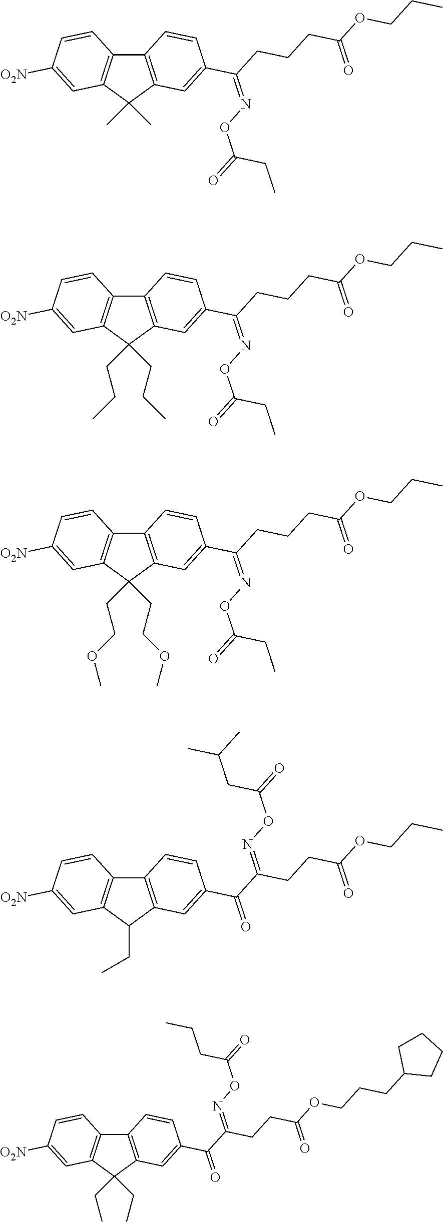 [SMILES: CCCOC(=O)CCC/C(=N/OC(=O)CC)c1ccc2c(c1)C(C)(C)c1cc([N+](=O)[O-])ccc1-2 ; CCCOC(=O)CCC/C(=N/OC(=O)CC)c1ccc2c(c1)C(CCC)(CCC)c1cc([N+](=O)[O-])ccc1-2 ; CCCOC(=O)CCC/C(=N/OC(=O)CC)c1ccc2c(c1)C(CCOC)(CCOC)c1cc([N+](=O)[O-])ccc1-2 ; CCCOC(=O)CC/C(=N\OC(=O)CC(C)C)C(=O)c1ccc2c(c1)C(CC)c1cc([N+](=O)[O-])ccc1-2 ; CCCC(=O)O/N=C(\CCC(=O)OCCCC1CCCC1)C(=O)c1ccc2c(c1)C(CC)(CC)c1cc([N+](=O)[O-])ccc1-2]

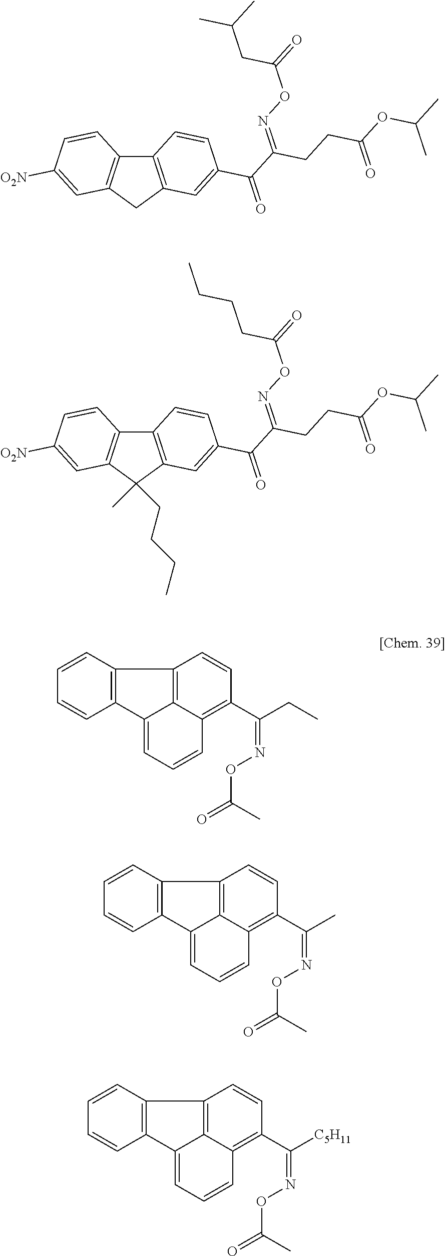

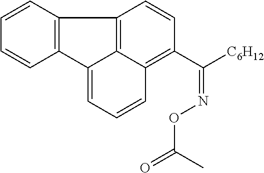

Preferable specific examples of the compound represented by the formula (c2) and having the group represented by the formula (c5) as R^{c1} include following compounds.

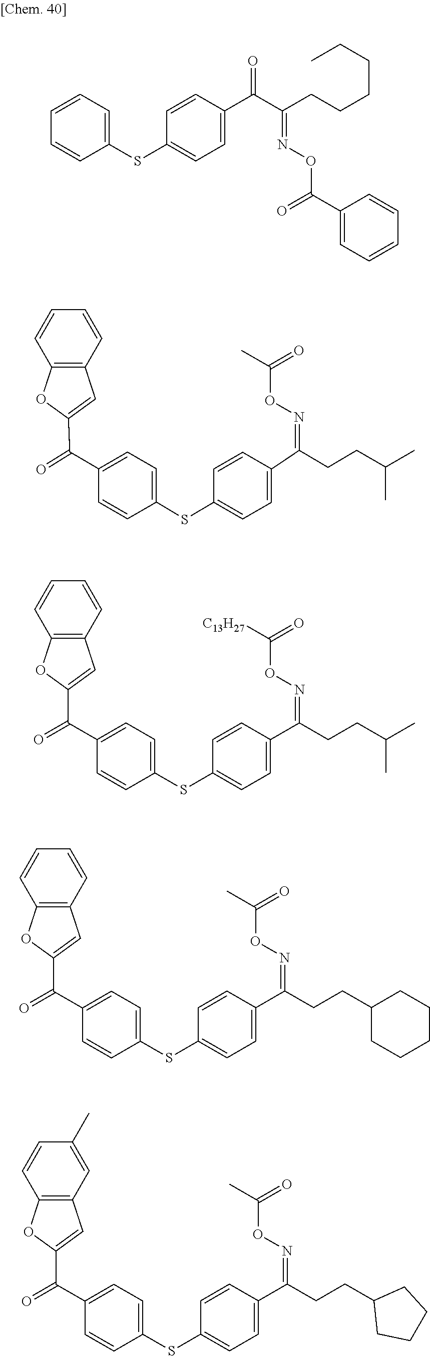

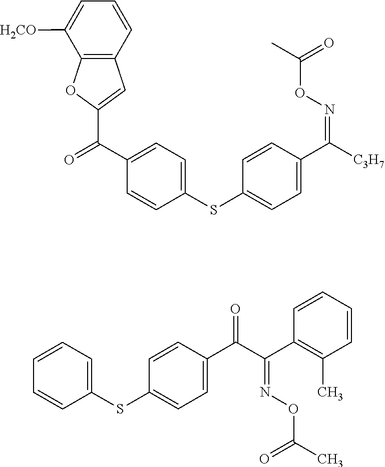

As the radical polymerization initiator (C), in view of good deeply curing property of the photosensitive composition, a phosphine oxide compound is also preferred. As the phosphine oxide compound, a phosphine oxide compound having a partial structure represented by the following formula (c9) is preferred.

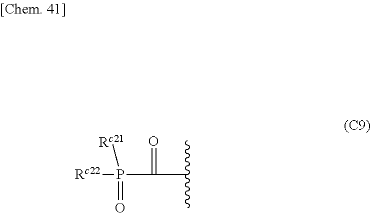

In the formula (c9), R^{c21} and R^{c22} are each independently an alkyl group, a cycloalkyl group, an aryl group, an aliphatic acyl group having 2 or more and 20 or less carbon atoms, or an aromatic acyl group having 7 or more and 20 or less carbon atoms. Provided that, both of R^{c21} and R^{c22} are the aliphatic acyl group or the aromatic aryl group.

A number of carbon atoms in the alkyl group as R^{c21} and R^{c22} is preferably 1 or more and 12 or less, more preferably 1 or more and 8 or less, and further preferably 1 or more and 4 or less. The alkyl group as R^{c21} and R^{c22} may be linear or branched. Specific examples of the alkyl group include methyl group, ethyl group, n-propyl group, isopropyl group, n-butyl group, isobutyl group, sec-butyl group, tert-butyl group, n-pentyl group, isopentyl group, tert-pentyl group, n-hexyl group, n-heptyl group, n-octyl group, 2,4,4-trimethylpentyl group, 2-ethylhexyl group, n-nonyl group, n-decyl group, n-undecyl group, and n-dodecyl group.

A number of carbon atoms in the cycloalkyl group as R^{c21} and R^{c22} is preferably 5 or more and 12 or less. Specific examples of the cycloalkyl group include cyclopentyl group, cyclohexyl group, cycloheptyl group, cyclooctyl group, cyclononyl group, cyclodecyl group, cycloundecyl group, and cyclododecyl group.

A number of carbon atoms in the aryl group as R^{c21} and R^{c22} is preferably 6 or more and 12 or less. The aryl group may have a substituent. Examples of the substituent include a halogen atom, an alkyl group having 1 or more and 4 or less carbon atoms, an alkoxy group having 1 or more and 4 or less carbon atoms, and the like. Specific examples of the aryl group include phenyl group and naphthyl group.

A number of carbon atoms in the aliphatic acyl group as R^{c21} and R^{c22} is 2 or more and 20 or less, preferably 2 or more and 12 or less, more preferably 2 or more and 8 or less, and further preferably 2 or more and 6 or less. The aliphatic acyl group may be linear or branched. Specific examples of the aliphatic acyl group include acetyl group, propionyl group, butanoyl group, pentanoyl group, hexanoyl group, heptanoyl group, octanoyl group, nonanoyl group, decanoyl group, undecanoyl group, dodecanoyl group, tridecanoyl group, tetradecanoyl group, pentadecenoyl group, hexadecanoyl group, heptadecanonyl group, octadecanoyl group, nonadecanonyl group, and icosanoyl group.

A number of carbon atoms in the aromatic acyl group as R^{c21} and R^{c22} is 7 or more and 20 or less. The aromatic acyl group may have a substituent. Examples of the substituent include a halogen atom, an alkyl group having 1 or more and 4 or less carbon atoms, an alkoxy group having 1 or more and 4 or less carbon atoms, and the like. Specific examples of the aromatic acyl group include benzoyl group, o-tolyl group, m-tolyl group, p-tolyl group, 2,6-dimethylbenzoyl group, 2,6-dimethoxybenzoyl group, 2,4,6-trimethylbenzoyl group, α-naphthoyl group, and β-naphthoyl group.

Suitable specific examples of the phosphine oxide compound having the partial structure represented by the formula (c9) include 2,4,6-trimethylbenzoyldiphenylphosphineoxide, bis(2,4,6-trimethylbenzoyl)-phenylphosphineoxide, bis(2,6-dimethoxybenzoyl)-2,4,4-trimethyl-pentylphosphineoxide, and the like. In view of deeply curing property of the photosensitive composition, it is also preferred that the phosphine oxide compound having the partial structure represented by the formula (c9) is used with α-hydroxyalkylphenone type initiator such as 2-hydroxy-2-methylpropiophenone. When the phosphine oxide compound having the partial structure represented by the formula (c9) is used with α-hydroxyalkylphenone type initiator such as 2-hydroxy-2-methylpropiophenone, a ratio of a mass of the phosphine oxide compound having the partial structure represented by the formula (c9) is preferably 20% by mass or more and 80% by mass or less, more preferably 30% by mass or more and 70% by mass or less, and further preferably 40% by mass or more and 60% by mass or less relative to a sum of the mass of both.

The content of the initiator (C) in the photosensitive composition is not particularly limited. The content of the initiator (C) is appropriately determined depending on the type of radically polymerizable group, or the type of the initiator (C). The content of the initiator (C) in the photosensitive composition is preferably 0.01 parts by mass or more and 20 parts by mass or less, more preferably 0.1 parts by mass or more and 15 parts by mass or less, and even more preferably 1 part by mass or more and 10 parts by mass or less relative to 100 parts by mass of the mass of the photosensitive composition excluding the mass of the solvent (S) described later.

The photosensitive composition can be obtained by uniformly, mixing and dispersing the desired amount of each of the photopolymerisable compound (A), metal oxide particles (B), initiator (C) and optional components added as needed.

### <<Production Method of Cured Product>>

A cured product can be produced by shaping the photosensitive composition described above into a desired shape and then subjecting the photosensitive composition to curing by exposing the photosensitive composition in accordance with the types of the initiator (C).

The shaping method of the photosensitive composition is not particularly limited. The shaping method is appropriately selected depending on the shape of the cured product. Examples of the shaping method include coating and casting into a mold. Hereinafter, a production method of a cured film will be described as a representative example of the production method of the cured product.

First, the photosensitive composition is coated on a desired substrate to form a coating film. Then, as needed, the solvent (S) is at least partially removed from the coating film to form a coating film.

The method of coating the photosensitive composition on the substrate is not particularly limited. The coating film can be formed by coating the photosensitive composition on the substrate such that a desired film thickness is achieved, using a contact transfer-type applicator such as a roll coater, a reverse coater, a bar coater, or a slit coater, or a non-contact type applicator such as a spinner (a rotary applicator) or a curtain flow coater, for example. In addition, printing methods such as screen printing and inkjet printing can also be applied to form the coating film. As described above, the aforementioned photosensitive composition is not likely to dry rapidly, and thicken or solidify in the inkjet head. Therefore, by using the aforementioned photosensitive composition, applying by inkjet printing method can be performed well.

After applying the photosensitive composition on the substrate, as needed, the solvent (S) is preferably removed at least partially from the coating film by baking the coating film. The baking temperature is appropriately determined in consideration of the boiling point of the solvent (S) and the like. The baking may be carried out at a low temperature under reduced pressure conditions.

The method of baking is not particularly limited. Examples of the method of baking include a method in which the coating film is dried using a hot plate at a temperature of 80° C. or higher and 150° C. or lower and preferably 85° C. or higher and 120° C. or lower, for 60 seconds or longer and 500 seconds or shorter.

The film thickness of the coating film formed as described above is not particularly limited. The film thickness of the coating film is appropriately determined depending on the applications of the cured film. The film thickness of the coating film is typically appropriately adjusted such that a cured film to be formed has a film thickness of preferably 0.1 μm or more and 10 μm or less and more preferably 0.2 μm or more and 5 μm or less.

After a coating film is formed by the above method, the coating film is subjected to light exposure to thereby enable a cured film to be obtained.

A condition for light exposure to the coating film is not particularly limited as long as curing proceeds well. Light exposure is carried out by irradiation with, for example, active energy rays such as ultraviolet rays and excimer laser light. The dose of energy used in the irradiation is not particularly limited, and examples thereof include a dose of 30 mJ/cm² or more and 5000 mJ/cm² or less. After the light exposure, the coating film subjected to light exposure may be baked in the same manner as the heating after coating.

As described above, following (1) to (10) are provided by present inventors.

(1) A photosensitive composition including a photopolymerizable compound (A) and metal oxide particles (B), in which the photopolymerizable compound (A) includes a compound represented by following formula (A1):

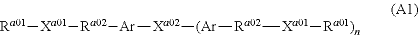

in which, in the formula (A1), R^{a01}s are each independently a radically polymerizable group-containing group,
R^{a02}s are each independently an alkylene group having 1 or more and 3 or less carbon atoms,
X^{a01}s are each independently oxygen atom or sulfur atom,
X^{a02} is an organic group having 1 or more and 3 or less carbon atoms and a valence of n+1, oxygen atom, or sulfur atom,
Ars are each independently an optionally substituted aromatic hydrocarbon group having 6 or more and 12 or less carbon atoms,
n is 1 or 2, and
when X^{a02} is oxygen atom or sulfur atom, n is 1.
   (2) The composition according to (1), in which the radically polymerizable group-containing group is (meth)acryloyl group.
   (3) The composition according to (1) or (2), in which n is 1, and X^{a02} is —CH₂—, oxygen atom, or sulfur atom.
   (4) The composition according to any one of (1) to (3), in which Ar is a phenylene group.
   (5) The composition according to (4), in which the phenylene group is p-phenylene group.
   (6) The composition according to any one of (1) to (5), in which the photopolymerizable compound (A) includes the compound represented by the formula (A1), and other photopolymerizable compound (A2) other than the compound represented by the formula (A1).
   (7) The composition according to any one of (1) to (6), in which the metal oxide particles (B) are at least one selected from a group consisting of titanium dioxide particles, zirconium dioxide particles, and niobium pentoxide.
   (8) The composition according to any one of (1) to (7), including a solvent (S),
in which the solvent (S) includes a high boiling point solvent (S1) having boiling point of 170° C. or higher under atmospheric pressure.
   (9) A photosensitive composition including a photopolymerizable compound (A), metal oxide particles (B), and an initiator (C),
in which the photopolymerizable compound (A) includes a compound represented by following formula (A1):

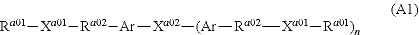

in which, in the formula (A1), R^{a01}s are each independently a radically polymerizable group-containing group,
R^{a02}s are each independently an alkylene group having 1 or more and 3 or less carbon atoms,
X^{a02}s are each independently oxygen atom or sulfur atom,
X^{a02} is an organic group having 1 or more and 3 or less carbon atoms and a valence of n+1, oxygen atom, or sulfur atom,
Ars are each independently an optionally substituted aromatic hydrocarbon group having 6 or more and 12 or less carbon atoms,
n is 1 or 2, and
when X^{a02} is oxygen atom or sulfur atom, n is 1.
   (10) A cured product of the photosensitive composition according to (9).

### EXAMPLES

Hereinafter, the present invention is described in more detail by way of Examples, but the present invention is not limited to these Examples.

Hereinafter, in the Examples and Comparative Examples, following compound corresponding to the compound represented by the formula (A1). In addition, following A2 to A6 were used as other photopolymerizable compound (A2).

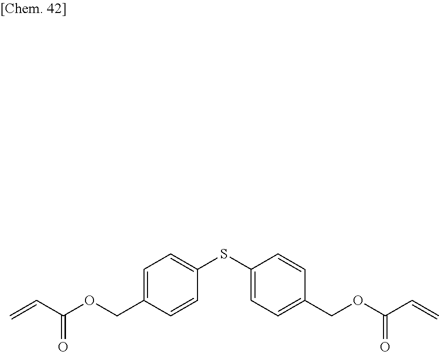 [SMILES: C=CC(=O)OCc1ccc(Sc2ccc(COC(=O)C=C)cc2)cc1]

A2: Dipentaerythritol hexaacrylate
A3: Dipentaerythritol pentaacrylate
A4 Diallyl phthalate
A5 Diallyl isophthalate
A6: 4,4′-di(meth)acryloylthio diphenylsulfide

As the inorganic microparticles (B), surface-treated titanium dioxide microparticles having an average diameter of 10 nm, and surface-treated zirconium dioxide microparticles having an average diameter of 10 nm were used. As the solvent (S), following S1, S2, and S3 were used. S-1: Propyleneglycol monomethyl ether acetate
S-2: Mixed solvent consisting of equal amount (mass) of tripropylene glycol monomethyl ether and dipropylene glycol monomethyl ether
S-3: Dipropylene glycol monomethyl ether

### Examples 1 to 40, Comparative Example 1, and Comparative Example 2

The photosensitive compositions of Examples and Comparative Examples were obtained by dissolving and dispersing the photopolymerizable compound (A) (component (A)) of the type and in an amount shown in Table 1, metal oxide particles (B) (component (B) of the type and in an amount shown in Table 1, and 1 part of bis(2,4,6-trimethylbenzoyl)-phenylphosphineoxide as the initiator (C) (component (C)) in the solvent (S) of the type shown in Table 1, so that a ratio of sum of a mass of the component (A), a mass of the component (B), and a mass of the component (C) is 10% by mass relative to a mass of the photosensitive.

Preparation of cured film, and evaluation of curing rate were carried out by using the obtained photosensitive composition. Evaluation results of the curing rate was shown in Table 1.

### <Evaluation of Curing Rate>

The photosensitive composition was applied onto a silicon substrate, thereafter a film consisting of the photosensitive composition was heated at 100° C. for 2 minutes to form a coating film having a film thickness of 0.2 μm. The formed coating film was exposed at exposure amount of 5 J/cm². LED exposure device (exposure wavelength: 365 nm) was used for exposure. Reaction rates of carbon-carbon unsaturated double bonds before and after exposure were calculated based on the rate of decrease of the peak corresponding to C═C (1408 cm⁻¹) in the FT-IR analysis. Curing rate was evaluated based on calculated ratio of decrease according to following criteria. A: Rate of decrease is 90% or more. B: Rate of decrease is 85% or more and less than 90%. C: Rate of decrease is 80% or more and less than 85%. D: Rate of decrease is less than 80%.

TABLE 1

| | Photopolymerizable compound (A) | | | | | | | |
|---|---|---|---|---|---|---|---|---|
| | | | Other | | | | | |
| | | | photopolymerizable | | Metal oxide | | | |
| | Compound (A1) | | compound (A2) | | particles (B) | | Solvent | |
| | | Parts | | Parts | | Parts | (S) | Curing |
| | Type | By mass | Type | By mass | Type | By mass | Type | rate |
| Example 1 | A1 | 24 | — | — | TiO₂ | 75 | S1 | B |
| Example 2 | A1 | 29 | — | — | TiO₂ | 70 | S1 | B |
| Example 3 | A1 | 24 | — | — | TiO₂ | 75 | S2 | B |
| Example 4 | A1 | 29 | — | — | TiO₂ | 70 | S2 | B |
| Example 5 | A1 | 12 | A2 | 12 | TiO₂ | 75 | S1 | A |
| Example 6 | A1 | 14.5 | A2 | 14.5 | TiO₂ | 70 | S1 | A |
| Example 7 | A1 | 12 | A2 | 12 | TiO₂ | 75 | S2 | A |
| Example 8 | A1 | 14.5 | A2 | 14.5 | TiO₂ | 70 | S2 | A |
| Example 9 | A1 | 12 | A3 | 12 | TiO₂ | 75 | S1 | A |
| Example 10 | A1 | 14.5 | A3 | 14.5 | TiO₂ | 70 | S1 | A |
| Example 11 | A1 | 12 | A3 | 12 | TiO₂ | 75 | S2 | A |
| Example 12 | A1 | 14.5 | A3 | 14.5 | TiO₂ | 70 | S2 | A |
| Example 13 | A1 | 12 | A4 | 12 | TiO₂ | 75 | S1 | A |
| Example 14 | A1 | 14.5 | A4 | 14.5 | TiO₂ | 70 | S1 | A |
| Example 15 | A1 | 12 | A4 | 12 | TiO₂ | 75 | S2 | A |
| Example 16 | A1 | 14.5 | A4 | 14.5 | TiO₂ | 70 | S2 | A |
| Example 17 | A1 | 12 | A5 | 12 | TiO₂ | 75 | S1 | A |
| Example 18 | A1 | 14.5 | A5 | 14.5 | TiO₂ | 70 | S1 | A |
| Example 19 | A1 | 12 | A5 | 12 | TiO₂ | 75 | S2 | A |
| Example 20 | A1 | 14.5 | A5 | 14.5 | TiO₂ | 70 | S2 | A |
| Example 21 | A1 | 24 | — | — | ZrO₂ | 75 | S3 | B |
| Example 22 | A1 | 29 | — | — | ZrO₂ | 70 | S3 | B |
| Example 23 | A1 | 24 | — | — | ZrO₂ | 75 | S2 | B |
| Example 24 | A1 | 29 | — | — | ZrO₂ | 70 | S2 | B |
| Example 25 | A1 | 12 | A2 | 12 | ZrO₂ | 75 | S3 | A |
| Example 26 | A1 | 14.5 | A2 | 14.5 | ZrO₂ | 70 | S3 | A |
| Example 27 | A1 | 12 | A2 | 12 | ZrO₂ | 75 | S2 | A |
| Example 28 | A1 | 14.5 | A2 | 14.5 | ZrO₂ | 70 | S2 | A |
| Example 29 | A1 | 12 | A3 | 12 | ZrO₂ | 75 | S3 | A |
| Example 30 | A1 | 14.5 | A3 | 14.5 | ZrO₂ | 70 | S3 | A |
| Example 31 | A1 | 12 | A3 | 12 | ZrO₂ | 75 | S2 | A |
| Example 32 | A1 | 14.5 | A3 | 14.5 | ZrO₂ | 70 | S2 | A |
| Example 33 | A1 | 12 | A4 | 12 | ZrO₂ | 75 | S3 | A |
| Example 34 | A1 | 14.5 | A4 | 14.5 | ZrO₂ | 70 | S3 | A |
| Example 35 | A1 | 12 | A4 | 12 | ZrO₂ | 75 | S2 | A |
| Example 36 | A1 | 14.5 | A4 | 14.5 | ZrO₂ | 70 | S2 | A |
| Example 37 | A1 | 12 | A5 | 12 | ZrO₂ | 75 | S3 | A |
| Example 38 | A1 | 14.5 | A5 | 14.5 | ZrO₂ | 70 | S3 | A |
| Example 39 | A1 | 12 | A5 | 12 | ZrO₂ | 75 | S2 | A |
| Example 40 | A1 | 14.5 | A5 | 14.5 | ZrO₂ | 70 | S2 | A |
| Comprarative | — | — | A6 | 24 | TiO₂ | 75 | S1 | D |
| Example 1 | | | | | | | | |
| Comprarative | — | — | A6 | 24 | ZrO₂ | 75 | S1 | D |
| Example 2 | | | | | | | | |

Comparison of Examples 1 to 40 with Comparative Example 1 and Comparative Example 2 shows that the photosensitive compositions of Examples including the compound (A1) which is the radically polymerizable compound (A) having a structure encompassed in the structure of the above formula (A1), and metal oxide particles (B) cure well. On the other hand, it is found that the photosensitive compositions of Comparative Examples not including the compound (A1) having a structure encompassed in the structure of the above formula (A1) are less likely to cure well.

Refractive indexes of the cured films formed by using the photosensitive compositions of Example 5, Example 9, Example 13, and Example 17 which have the same composition except for difference of types of other photopolymerizable compound (A2) were compared with each other. In addition, refractive indexes of the cured film formed by using the photosensitive compositions of Example 25, Example 33, and Example 37 which have the same composition except for difference of types of other photopolymerizable compound (A2) were compared with each other. Cured film was formed by the same method as for the measurement of the curing rate. Value of the refractive index of the resulting cured film was determined at a wavelength of 550 nm using a prism coupler manufactured by Metricon Inc. Measurement results of the refractive indexes were shown in Table 2.

TABLE 2

| | Other | |
|---|---|---|
| | photopolymerizable | Refractiv |
| | compound (A2) | index |
| Example 5 | A2 | 1.86 |
| Example 9 | A3 | 1.86 |
| Example 13 | A4 | 1.92 |
| Example 17 | A5 | 1.92 |
| Example 25 | A2 | 1.71 |
| Example 29 | A3 | 1.71 |
| Example 33 | A4 | 1.76 |
| Example 37 | A5 | 1.76 |

According to Table 2, it is found that refractive indexes of the cured films formed by using the photosensitive compositions including A4 or A5 which is diallyl ester of benzene dicarboxylic acid such as phthalic acid and isophthalic acid are significantly high.

1. A composition comprising a photopolymerizable compound (A), and metal oxide particles (B),
wherein the photopolymerizable compound (A) comprises a compound represented by following formula (A1): 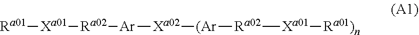
wherein, in the formula (A1), R^{a01}s are each independently a radically polymerizable group-containing group,
R^{a02}s are each independently an alkylene group having 1 or more and 3 or less carbon atoms,
X^{a01}s are each independently oxygen atom or sulfur atom,
X^{a02} is an organic group having 1 or more and 3 or less carbon atoms and a valence of n+1, oxygen atom, or sulfur atm,
Ars are each independently an optionally substituted aromatic hydrocarbon group having 6 or more and 12 or less carbon atoms,
n is 1 or 2, and
when X^{a02} is oxygen atom or sulfur atom, n is 1.

2. The composition according to claim 1, wherein the radically polymerizable group-containing group is (meth)acryloyl group.

3. The composition according to claim 1, wherein n is 1, and X^{a02} is —CH₂—, oxygen atom, or sulfur atom.

4. The composition according to claim 1, wherein Ar is a phenylene group.

5. The composition according to claim 4, wherein the phenylene group is p-phenylene group.

6. The composition according to claim 1, wherein the photopolymerizable compound (A) comprises the compound represented by the formula (A1), and other photopolymerizable compound (A2) other than the compound represented by the formula (A1).

7. The composition according to claim 1, wherein the metal oxide particles (B) are at least one selected from a group consisting of titanium dioxide particles, zirconium dioxide particles, and niobium pentoxide.

8. The composition according to claim 1, comprising a solvent (S), wherein the solvent (S) comprises a high boiling point solvent (S1) having boiling point of 170° C. or higher under atmospheric pressure.

9. A photosensitive composition comprising a photopolymerizable compound (A), metal oxide particles (B), and an initiator (C),
wherein the photopolymerizable compound (A) comprises a compound represented by following formula (A1): 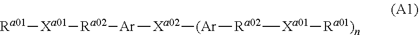
wherein, in the formula (A1), R^{a01}s are each independently a radically polymerizable group-containing group,
R^{a02}s are each independently an alkylene group having 1 or more and 3 or less carbon atoms,
X^{a01}s are each independently oxygen atom or sulfur atom,
X^{a02} is an organic group having 1 or more and 3 or less carbon atoms and a valence of n+1, oxygen atom, or sulfur tom,
Ars are each independently an optionally substituted aromatic hydrocarbon group having 6 or more and 12 or less carbon atoms,
n is 1 or 2, and
when X^{a02} is oxygen atom or sulfur atom, n is 1.

10. A cured product of the photosensitive composition according to claim 9.
